(19) United States
(12) Patent Application Publication
(10) Pub. No.: US 2014/0212797 A1
(43) Pub. Date: Jul. 31, 2014

(54) ACTINIC RAY-SENSITIVE OR RADIATION-SENSITIVE RESIN COMPOSITION, RESIST FILM AND PATTERN FORMING METHOD EACH USING THE COMPOSITION, MANUFACTURING METHOD OF SEMICONDUCTOR DEVICE, SEMICONDUCTOR DEVICE AND PRODUCTION METHOD OF RESIN

(71) Applicant: FUJIFILM CORPORATION, Tokyo (JP)

(72) Inventors: Takeshi KAWABATA, Haibara-gun (JP); Hideaki TSUBAKI, Haibara-gun (JP)

(73) Assignee: FUJIFILM CORPORATION, Tokyo (JP)

(21) Appl. No.: 14/228,486

(22) Filed: Mar. 28, 2014

Related U.S. Application Data
(63) Continuation of application No. PCT/JP2012/075734, filed on Sep. 27, 2012.

(30) Foreign Application Priority Data
Sep. 29, 2011 (JP) 2011-215625

(51) Int. Cl. C08F 28/06; C08F 28/02; G03F 7/038

(52) U.S. Cl. CPC C08F 28/06; G03F 7/0388; C08F 28/02
USPC 430/9; 430/325; 430/296; 526/287; 526/243; 526/256; 526/282

(57) ABSTRACT

An actinic ray-sensitive or radiation-sensitive resin composition includes: (P) a resin that contains (A) a repeating unit capable of decomposing upon irradiation with an actinic ray or radiation to generate an acid in a side chain of the resin (P) and (C) a repeating unit represented by the following formula (I) as defined in the specification, wherein a polydispersity of the resin (P) is 1.20 or less.

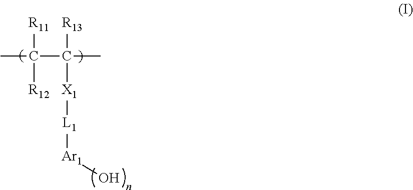

### CROSS REFERENCE TO RELATED APPLICATION

This is a continuation of International Application No. PCT/JP2012/075734 filed on Sep. 27, 2012, and claims priority from Japanese Patent Application No. 2011-215625 filed on Sep. 29, 2011, the entire disclosures of which are incorporated therein by reference.

### TECHNICAL FIELD

The present invention relates to an actinic ray-sensitive or radiation-sensitive resin composition suitably used in the ultramicrolithography process such as production of VLSI or a high-capacity microchip or in other photofabrication processes, a resist film and a pattern forming method each using the same, a manufacturing method of a semiconductor device, a semiconductor device, and a production method of a resin.

### BACKGROUND ART

In the process of producing a semiconductor device such as IC and LSI, microfabrication by lithography using a photoresist composition has been conventionally performed. Recently, with increase in the integration degree of an integrated circuit, formation of an ultrafine pattern in the sub-micron or quarter-micron region is required. To cope with this requirement, the exposure wavelength also tends to become shorter, for example, from g line to i line or further to KrF excimer laser light. Furthermore, other than the excimer laser light, development of lithography using electron beam, X-ray or EUV light is proceeding at present.

In particular, the electron beam lithography is positioned as a next-generation or next-next-generation pattern formation technology, and a high-sensitivity and high-resolution positive resist is being demanded. Among others, elevation of the sensitivity is a very important task so as shorten the wafer processing time but in the positive resist for electron beam, when elevation of the sensitivity is sought for, not only reduction in the resolution but also worsening of the line edge roughness are involved, and development of a resist satisfying these properties at the same time is strongly demanded. The line edge roughness as used herein means that the edge at the interface between the resist pattern and the substrate irregularly fluctuates in the direction perpendicular to the line direction due to resist property and when the pattern is viewed from right above, the edge gives an uneven appearance. This unevenness is transferred by the etching step using the resist as a mask and causes deterioration of electric characteristics, leading to a decrease in the yield. Above all, in an ultrafine region with a line width of 0.25 μm or less, the improvement of line edge roughness is a very important task. Furthermore, when an undissolved residue (scum) exists in the exposed portion after performing development and rinsing steps, this gives rise to deterioration of electric characteristics and therefore, reduction of scum in the exposed area is also an important problem to be improved. In addition, high sensitivity is in a trade-off relationship with high resolution, good pattern profile, improved line edge roughness and scum reduction, and it is very important how satisfy these properties all at the same time.

Also in the lithography using X-ray or EUV light, it is similarly an important task to satisfy high sensitivity, high resolution, good pattern profile, improved line edge roughness and scum reduction all at the same time, and this task needs to be solved.

Furthermore, in the case of using a light source that emits EUV light, the wavelength of light belongs to an extreme-ultraviolet region and since the light has high energy, unlike conventional light sources, the outgas problem that a compound in the resist film is destroyed by fragmentation and volatizes as a low molecular component during exposure to contaminate the environment in the exposure machine, is prominent.

As one of methods to solve this problem, use of a resin having a photoacid generator in the main or side chain of the polymer is being studied (JP-A-9-325497 (the term “JP-A” as used herein means an “unexamined published Japanese patent application”), JP-A-10-221852, JP-A-2006-178317, JP-A-2007-197718, International Publication No. 06/121096 pamphlet, U.S. Patent Application Publication No. 2006/121390, International Publication No. 08/056796 pamphlet and JP-A-2010-250290).

### SUMMARY OF INVENTION

However, in JP-A-9-325497, a mixture system of a resin having a photoacid generator and a dissolution inhibiting compound capable of increasing the solubility in an alkali developer by acid decomposition is employed and because of non-uniform mixing of these materials, it is difficult to obtain a good pattern profile or improved line edge roughness.

In JP-A-10-221852, JP-A-2006-178317, JP-A-2007-197718, International Publication No. 06/121096 pamphlet, U.S. Patent Application Publication No. 2006/121390, International Publication No. 08/056796 pamphlet and JP-A-2010-250290, a resin having in the same molecule a photoacid generating group and a group capable of increasing the solubility in an alkali developer by acid decomposition is disclosed, but this resin can be hardly said to have adequate sensitivity to electron beam, X-ray or EUV light.

As in the techniques described in JP-A-9-325497, JP-A-10-221852, JP-A-2006-178317, JP-A-2007-197718, International Publication No. 06/121096 pamphlet, U.S. Patent Application Publication No. 2006/121390, International Publication No. 08/056796 pamphlet and JP-A-2010-250290, when an acid-generating moiety corresponding to an acid generator is incorporated into a resin, this tends to reduce the problem that the resolution is impaired due to, for example, insufficient miscibility of the acid generator for the resin or diffusion of an acid generated from the acid generator upon exposure into an unintended region (e.g., unexposed area). Furthermore, thanks to the absence of a low molecular acid generator, even in the case of irradiation, for example, with EUV light, generation of an outgas derived from a low molecular component is liable to be more reduced. However, also in these techniques, there is room for more improvements particularly in the sensitivity to electron beam, X-ray or EUV light.

Particularly, in the lithography using electron beam, X-ray or EUV light, the fact is that more improvements are required in the resolution and outgas characteristics and at the same time, higher performance in terms of sensitivity, line edge roughness, scum and pattern profile is demanded.

An object of the present invention is to provide an actinic ray-sensitive or radiation-sensitive resin composition not only satisfying, at a high level, all of high sensitivity, high resolution, good pattern profile, scum reduction and improved line edge roughness at the same time but also exhibiting sufficiently high performance in terms of outgas during exposure.

Another object of the present invention is to provide a resist film and a pattern forming method each using the composition, a manufacturing method of a semiconductor device, a semiconductor device and a production method of a resin.

The present invention is, for example, as follows.

[1] An actinic ray-sensitive or radiation-sensitive resin composition, comprising:

(P) a resin that contains (A) a repeating unit capable of decomposing upon irradiation with an actinic ray or radiation to generate an acid in a side chain of the resin (P) and (C) a repeating unit represented by the following formula (I), wherein a polydispersity of the resin (P) is 1.20 or less:

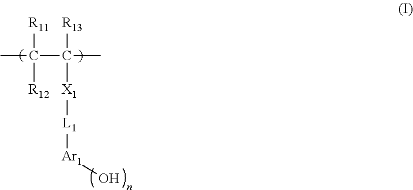

wherein in formula (I), each of R₁₁, R₁₂ and R₁₃ independently represents a hydrogen atom, an alkyl group, a cycloalkyl group, a halogen atom, a cyano group or an alkoxycarbonyl group, R₁₂ may combine with Ar₁ to form a ring, and in this case, R₁₂ represents an alkylene group;

X₁ represents a single bond, —COO— or —CONR₁₄—, and R₁₄ represents a hydrogen atom or an alkyl group;

L₁ represents a single bond or an alkylene group;

Ar₁ represents an (n+1)-valent aromatic ring group, provided that when Ar₁ combines with R₁₂, Ar₁ represents an (n+2)-valent aromatic ring group; and

n represents an integer of 1 or more.

[2] The actinic ray-sensitive or radiation-sensitive resin composition as described in [1] above,

wherein the repeating unit (C) is represented by the following formula (II):

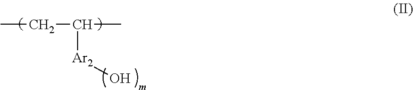

wherein Ar₂ represents an (m+1)-valent aromatic ring group; and

m represents an integer of 1 or more.

[3] The actinic ray-sensitive or radiation-sensitive resin composition as described in [1] or [2] above,

wherein the resin (P) further contains (B) a repeating unit capable of decomposing by an action of an acid to generate an alkali-soluble group.

[4] The actinic ray-sensitive or radiation-sensitive resin composition as described in [3] above,

wherein the repeating unit (B) is represented by the following formula (III):

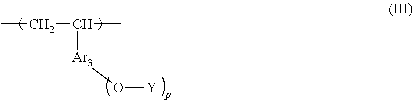

wherein Ar₃ represents a (p+1)-valent aromatic ring group;

Y represents a hydrogen atom or a group capable of leaving by an action of an acid, and when a plurality of Y's are present, each Y may be the same as or different from every other Y, provided that at least one Y represents a group capable of leaving by an action of an acid; and

p represents an integer of 1 or more.

[5] The actinic ray-sensitive or radiation-sensitive resin composition as described in any one of [1] to [4] above,

wherein the repeating unit (A) is represented by the following formula (IV):

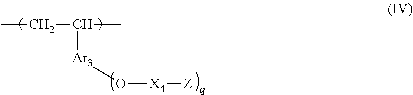

wherein Ar₄ represents a (q+1)-valent aromatic ring group;

X₄ represents a divalent linking group;

Z represents a moiety working out to a sulfonic acid group, an imide acid group or a methide acid group upon irradiation with an actinic ray or radiation; and

q represents an integer of 1 or more.

[6] The actinic ray-sensitive or radiation-sensitive resin composition as described in [5] above,

wherein in formula (IV), X₄ represents an aromatic ring group, —CO— or a group formed by a combination thereof.

[7] The actinic ray-sensitive or radiation-sensitive resin composition as described in any one of [1] to [6] above,

wherein the resin (P) is synthesized from poly(hydroxystyrene)s.

[8] The actinic ray-sensitive or radiation-sensitive resin composition as described in any one of [1] to [7] above, which is exposed to an electron beam, an X-ray or a soft X-ray.

[9]A resist film, which is formed using the actinic ray-sensitive or radiation-sensitive resin composition as described in any one of [1] to [8] above.

[10]A pattern forming method, comprising:

exposing and developing the resist film as described in [9] above.

[11] The pattern forming method as described in [10] above,

wherein the exposing of the resist film is performed using an electron beam, an X-ray or a soft X-ray.

[12]A manufacturing method of a semiconductor device, comprising:

the pattern forming method as described in [10] or [11] above.

[13]A semiconductor device, which is manufactured by the manufacturing method of a semiconductor device as described in [12] above.

[14]A production method of (P) a resin, comprising:

synthesizing (P) a resin that contains (A) a repeating unit capable of decomposing upon irradiation with an actinic ray or radiation to generate an acid in a side chain of the resin (P) and (C) a repeating unit represented by the following formula (I) and has a polydispersity of 1.20 or less, from poly(hydroxystyrene)s:

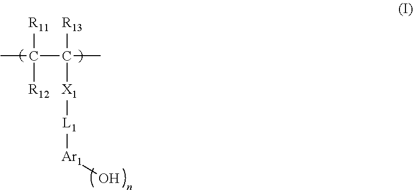

wherein in formula (I), each of R₁₁, R₁₂ and R₁₃ independently represents a hydrogen atom, an alkyl group, a cycloalkyl group, a halogen atom, a cyano group or an alkoxycarbonyl group, R₁₂ may combine with Ar₁ to form a ring, and in this case, R₁₂ represents an alkylene group;

X₁ represents a single bond, —COO— or —CONR₁₄—, and R₁₄ represents a hydrogen atom or an alkyl group;

L₁ represents a single bond or an alkylene group;

Ar₁ represents an (n+1)-valent aromatic ring group, provided that when Ar₁ combines with R₁₂, Ar₁ represents an (n+2)-valent aromatic ring group; and

n represents an integer of 1 or more.

### DESCRIPTION OF EMBODIMENTS

The mode for carrying out the present invention is described in detail below.

Incidentally, when a group or atomic group is recited herein without specifying whether substituted or unsubstituted, the group encompasses both a group having no substituent and a group having a substituent. For example, “an alkyl group” recited without specifying whether substituted or unsubstituted encompasses not only an alkyl group having no substituent (unsubstituted alkyl group) but also an alkyl group having a substituent (substituted alkyl group).

Also, the term “actinic ray” or “radiation” as used herein indicates, for example, a bright line spectrum of mercury lamp, a far ultraviolet ray typified by excimer laser, an X-ray, a soft X-ray such as extreme-ultraviolet (EUV) ray, or an electron beam (EB). The “light” means an actinic ray or radiation. Unless otherwise indicated, the “exposure” means not only light irradiation by a mercury lamp, a far ultraviolet ray, an X-ray, EUV light or the like but also lithography with a particle beam such as electron beam and ion beam.

The actinic ray-sensitive or radiation-sensitive resin composition of the present invention contains the below-described resin (P). When such a configuration is employed, it becomes possible to not only satisfy, at a high level, all of high sensitivity, high resolution, good pattern profile, scum reduction and improved line edge roughness at the same time but also achieve a sufficiently high performance in terms of outgas. It is presumed that the resin (P) contains (A) a repeating unit capable of decomposing upon irradiation with an actinic ray or radiation to generate an acid in the side chain of the resin, whereby the diffusion or volatilization of the acid generated can be reduced and the resolution and outgas performance can be enhanced, and the polydispersity of the resin (P) is a specific value or less, whereby the dissolution uniformity of the resin (P) can be enhanced and all of high sensitivity, good pattern profile and improved line edge roughness can be satisfied. Furthermore, the polydispersity of the resin (P) is 1.20 or less, whereby a high-molecular-weight component exhibiting bad solubility for an alkali developer can be eliminated and the scum reduction can be also achieved.

The composition of the present invention is, for example, a positive composition and is typically a positive resist composition.

The composition of the present invention is preferably exposed to an electron beam, an X-ray or a soft X-ray (that is, a composition for an electron beam, an X-ray or a soft X-ray).

### [1] Resin (P)

The resin (P) contains (A) a repeating unit capable of decomposing upon irradiation with an actinic ray or radiation to generate an acid in the side chain of the resin and (C) a repeating unit represented by formula (I) having an aromatic hydroxyl group. The resin (P) may further contain a repeating unit other than these repeating units. The polydispersity of the resin (P) is 1.20 or less.

### [Repeating Unit (A)]

The repeating unit (A) is a repeating unit capable of decomposing upon irradiation with an actinic ray or radiation to generate an acid in the side chain of the resin.

More specifically, the repeating unit (A) is preferably a repeating unit represented by the following formula (IV):

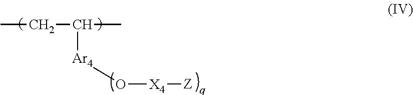

In formula (IV), Ar₄ represents a (q+1)-valent aromatic ring group.

X₄ represents a divalent linking group.

Z represents a moiety working out to a sulfonic acid group, an imide acid group or a methide acid group upon irradiation with an actinic ray or radiation.

q represents an integer of 1 or more.

The (q+1)-valent aromatic ring group represented by Ar₄ in formula (IV) may have a substituent. Preferred examples of the (q+1)-valent aromatic ring group represented by Ar₄ include, when q is 1, an arylene group having a carbon number of 6 to 18, such as phenylene group, tolylene group and naphthylene group, and a divalent aromatic ring group containing a heterocyclic ring such as thiophene, furan, pyrrole, benzothiophene, benzofuran, benzopyrrole, triazine, imidazole, benzimidazole, triazole, thiadiazole and thiazole.

Preferred examples of the substituent on the (q+1)-valent aromatic ring group represented by Ar₄ include a hydroxyl group, a halogen atom (e.g., a fluorine atom, a chlorine atom, a bromine atom, an iodine atom), a nitro group, a cyano group, an amido group, a sulfonamido group, the alkyl group having a carbon number of 20 or less, such as methyl group, ethyl group, propyl group, isopropyl group, n-butyl group, sec-butyl group, hexyl group, 2-ethylhexyl group, octyl group and dodecyl group, a cycloalkyl group having a carbon number of 3 to 17, such as cyclopentyl group, cyclohexyl group, norbornyl group and adamantyl group, an alkoxy group such as methoxy group, ethoxy group, hydroxyethoxy group, propoxy group, hydroxypropoxy group and butoxy group, an alkoxycarbonyl group such as methoxycarbonyl group and ethoxycarbonyl group, an acyl group such as formyl group, acetyl group and benzoyl group, an acyloxy group such as acetoxy group and butyryloxy group, and a carboxy group.

When q is 1, Ar₄ is preferably an arylene group having a carbon number of 6 to 18, which may have a substituent, more preferably a phenylene group, a naphthylene group, a biphenylene group or a phenylene group substituted with a phenyl group, still more preferably a phenylene group.

When q is an integer of 2 or more, specific examples of the (q+1)-valent aromatic ring group represented by Ar₄ include a group formed by removing arbitrary (q−1) hydrogen atoms from the divalent aromatic ring group.

Examples of the divalent linking group represented by X₄ include an alkylene group, a cycloalkylene group, an alkenylene group, an aromatic ring group, —COO—, —CO—, —SO—, —SO₂—, —CONH—, —O—, —S— and a group (preferably having a carbon number of 1 to 30, more preferably a carbon number of 1 to 15) formed by combining two or more of these groups, and the groups above may be further substituted with a substituent such as fluorine atom.

The alkylene group for X₄ is preferably a linear or branched alkylene group having a carbon number of 1 to 20, more preferably a carbon number of 1 to 10, and examples thereof include a methylene group, an ethylene group and a propylene group.

The cycloalkylene group for X₄ is preferably a cycloalkylene group having a carbon number of 3 to 20, more preferably a carbon number of 3 to 10, and examples thereof include a 1,4-cyclohexylene group. The cycloalkylene group for X₄ may be a cycloalkylene group formed by replacing a part of carbon atoms constituting the ring by a heteroatom such as nitrogen atom.

The alkenylene group includes a group having a double bond at an arbitrary position of the alkylene group described for X₄ above.

Examples of the aromatic ring group for X₄ are the same as those of the divalent aromatic ring group described for Ar₄, and the preferred range is also the same.

In the alkylene group, cycloalkylene group, alkenylene group and aromatic ring group for X₄, a part or all of hydrogen atoms bonded to a carbon atom may be replaced by a substituent.

Examples of the substituent which may be substituted on the alkylene group, cycloalkylene group, alkenylene group and aromatic ring group for X₄ are the same as those of the substituent described in Ar₄.

X₄ is preferably an alkylene group, an aromatic ring group, —COO—, —CO—, —SO₂—, —CONH—, —O— or a group formed by combining two or more thereof, more preferably an alkylene group, an aromatic ring group, —COO—, —CO—, —SO₂—, —O— or a group formed by combining two or more thereof, still more preferably an aromatic ring group, —CO— or a group formed by combining them. The carbon number of the group formed by combining these groups or bonds is the same as in the range above.

q represents an integer of 1 or more. q preferably represents an integer of 1 to 5, more preferably 1 or 2, and most preferably 1.

In the repeating unit represented by formula (IV), when Ar₄ is a phenylene group, the bonding position of the group represented by —O—X₄—Z to the benzene ring of Ar₄ may be a para-position, a meta-position or an ortho-position with respect to the bonding position of the benzene ring to the polymer main chain but is preferably a para-position or a meta-position, and most preferably a para-position.

Z represents a moiety working out to a sulfonic acid group, an imide acid group or a methide acid group upon irradiation with an actinic ray or radiation. The moiety represented by Z is preferably an onium salt, and the onium salt is preferably a sulfonium salt or an iodonium salt, more preferably a structure represented by any one of the following formulae (ZI) to (ZIII):

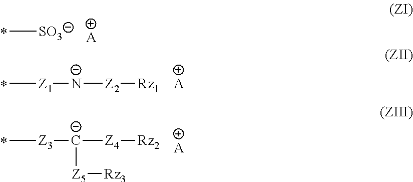

In formulae (ZII) and (ZIII), each of Z₁, Z₂, Z₃, Z₄ and Z₅ independently represents —CO— or —SO₂—, preferably —SO₂—.

Each of Rz₁, Rz₂ and Rz₃ independently represents an alkyl group, a monovalent aliphatic hydrocarbon ring group, an aryl group or an aralkyl group. An embodiment where a part or all of hydrogen atoms of the group above are replaced by a fluorine atom or a fluoroalkyl group (more preferably a perfluoroalkyl group) is preferred, and an embodiment where 30 to 100% by number of hydrogen atoms are replaced by a fluorine atom is more preferred.

* represents the bonding position to X₄ in formula (IV).

The alkyl group may be linear or branched, and preferred examples thereof include an alkyl group having a carbon number of 1 to 8, such as methyl group, ethyl group, propyl group, butyl group, hexyl group and octyl group. An alkyl group having a carbon number of 1 to 6 is more preferred, and an alkyl group having a carbon number of 1 to 4 is still more preferred.

The monovalent aliphatic hydrocarbon ring group is preferably a cycloalkyl group and is, for example, more preferably a monovalent cycloalkyl group having a carbon number of 3 to 10, such as cyclobutyl group, cyclopentyl group and cyclohexyl group, still more preferably a cycloalkyl group having a carbon number of 3 to 6.

The aryl group is preferably an aryl group having a carbon number of 6 to 18, more preferably an aryl group having a carbon number of 6 to 10, still more preferably a phenyl group.

Preferred examples of the aralkyl group include an aralkyl group formed by combining an alkylene group having a carbon number of 1 to 8 and the above-described aryl group. An aralkyl group formed by combining an alkylene group having a carbon number of 1 to 6 and the above-described aryl group is more preferred, and an aralkyl group formed by combining an alkylene group having a carbon number of 1 to 4 and the above-described aryl group is still more preferred.

Each of Rz₁, Rz₂ and Rz₃ is preferably an alkyl group with a part or all of hydrogen atoms being replaced by a fluorine atom or a fluoroalkyl group (more preferably a perfluoroalkyl group), more preferably an alkyl group with from 30 to 100% by number of hydrogen atoms being replaced by a fluorine atom.

In formulae (ZI) to (ZIII), A⁺ represents a sulfonium cation or an iodonium cation and is preferably a structure represented by the following formula (ZA-1) or (ZA-2):

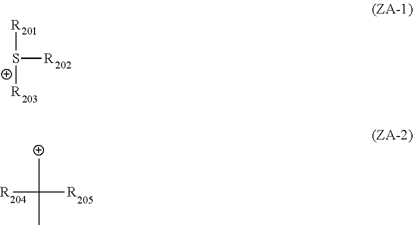

In formula (ZA-1), each of R₂₀₁, R₂₀₂ and R₂₀₃ independently represents an organic group. The carbon number of the organic group as R₂₀₁, R₂₀₂ and R₂₀₃ is generally from 1 to 30, preferably from 1 to 20.

Two members out of R₂₀₁ to R₂₀₃ may combine to form a ring structure (including a condensed ring), and the ring may further contain an oxygen atom, a sulfur atom, an ester bond, an amido bond or a carbonyl group other than the sulfur atom shown in the formula. Examples of the group formed by combining two members out of R₂₀₁ to R₂₀₃ include an alkylene group (e.g., butylene, pentylene).

The organic group as R₂₀₁, R₂₀₂ and R₂₀₃ includes, for example, corresponding groups in the groups represented by (ZA-1-1), (ZA-1-2) and (ZA-1-3) which are described below as preferred groups of the group represented by formula (ZA-1). Above all, corresponding groups in the groups represented by (ZA-1-1) and (ZA-1-3) are preferred.

The (ZA-1-1) group is described below.

The (ZA-1-1) group is a group having an arylsulfonium as the cation, where at least one of R₂₀₁ to R₂₀₃ in formula (ZA-1) is an aryl group.

All of R₂₀₁ to R₂₀₃ may be an aryl group, or a part of R₂₀₁ to R₂₀₃ may be an aryl group with the remaining being an alkyl group or a monovalent aliphatic hydrocarbon ring group.

Examples of the group include groups corresponding to triarylsulfonium, diarylalkylsulfonium, aryldialkylsulfonium, diarylcycloalkylsulfonium and aryldicycloalkylsulfonium.

The aryl group in the arylsulfonium is preferably a phenyl group or a naphthyl group. The aryl group may be an aryl group having a heterocyclic structure containing an oxygen atom, a nitrogen atom, a sulfur atom or the like. The heterocyclic structure includes structures such as pyrrole, furan, thiophene, indole, benzofuran and benzothiophene.

In the case where the arylsulfonium has two or more aryl groups, each of two or more aryl groups may be the same as or different from every other aryl groups.

The alkyl group or monovalent aliphatic hydrocarbon ring group which is present, if desired, in the arylsulfonium is preferably a linear or branched alkyl group having a carbon number of 1 to 15 or a monovalent aliphatic hydrocarbon ring group having a carbon number of 3 to 15, and examples thereof include a methyl group, an ethyl group, a propyl group, an n-butyl group, a sec-butyl group, a tert-butyl group, a cyclopropyl group, a cyclobutyl group and a cyclohexyl group. The monovalent aliphatic hydrocarbon ring group is preferably a cycloalkyl group.

The aryl group, alkyl group and monovalent aliphatic hydrocarbon ring group of R₂₀₁ to R₂₀₃ may have, as a substituent, an alkyl group (for example, having a carbon number of 1 to 15), a monovalent aliphatic hydrocarbon ring group (for example, having a carbon number of 3 to 15; preferably a cycloalkyl group having a carbon number of 3 to 15), an aryl group (for example, having a carbon number of 6 to 14), an alkoxy group (for example, having a carbon number of 1 to 15), a halogen atom, a hydroxyl group or a phenylthio group. The substituent is preferably a linear or branched alkyl group having a carbon number of 1 to 12, a monovalent aliphatic hydrocarbon ring group having a carbon number of 3 to 12 (preferably a cycloalkyl group having a carbon number of 3 to 12), or a linear, branched or cyclic alkoxy group having a carbon number of 1 to 12, more preferably an alkyl group having a carbon number of 1 to 4, or an alkoxy group having a carbon number of 1 to 4. The substituent may be substituted on any one of three members R₂₀₁ to R₂₀₃ or may be substituted on all of these three members. In the case where R₂₀₁ to R₂₀₃ are an aryl group, the substituent is preferably substituted on the p-position of the aryl group.

The group represented by (ZA-1-1) is more preferably a triarylsulfonium or a structure represented by the following formula (ZA-1-1A) or (ZA-1-1B):

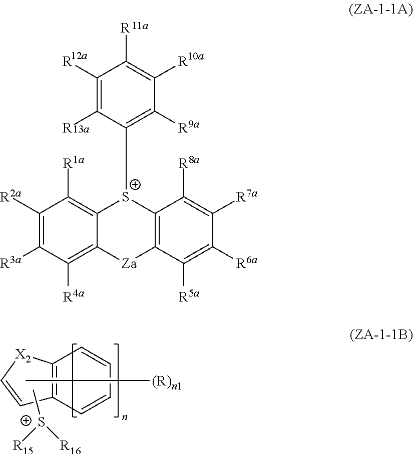

In formula (ZA-1-1A), each of R^{1a} to R^{13a} independently represents a hydrogen atom or a substituent, and at least one of R^{1a} to R^{13a} is preferably an alcoholic hydroxyl group-containing substituent.

Za represents a single bond or a divalent linking group.

The term “alcoholic hydroxyl group” as used in the present invention indicates a hydroxyl group bonded to a carbon atom of a chain or cyclic alkyl group.

In the case where R^{1a} to R^{13a} are an alcoholic hydroxyl group-containing substituent, R^{1a} to R^{13a} are represented by —W—Y, wherein Y is a chain or cyclic alkyl group substituted with a hydroxyl group and W is a single bond or a divalent linking group.

Examples of the chain or cyclic alkyl group of Y include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, a cyclopropyl group, a cyclopentyl group, a cyclohexyl group, an adamantyl group, a norbornyl group, and a boronyl group. Among these, an ethyl group, a propyl group, an isopropyl group, an n-butyl group, an isobutyl group and a sec-butyl group are preferred, and an ethyl group, a propyl group and an isopropyl group are more preferred. In particular, Y preferably contains a —CH₂CH₂OH structure.

W is preferably a single bond or a divalent group formed by substituting a single bond for an arbitrary hydrogen atom in an alkoxy group, an acyloxy group, an acylamino group, an alkylsulfonylamino group, an arylsulfonylamino group, an alkylthio group, an alkylsulfonyl group, an acyl group, an alkoxycarbonyl group or a carbamoyl group, more preferably a single bond or a divalent group formed by substituting a single bond for an arbitrary hydrogen atom in an acyloxy group, an alkylsulfonyl group, an acyl group or an alkoxycarbonyl group.

In the case where R^{1a} to R^{13a} are an alcoholic hydroxyl group-containing substituent, the number of carbons contained therein is preferably from 2 to 10, more preferably from 2 to 6, still more preferably from 2 to 4.

The alcoholic hydroxyl group-containing substituent as R^{1a} to R^{13a} may have two or more alcoholic hydroxyl groups. The number of alcoholic hydroxyl groups in the alcoholic hydroxyl group-containing substituent as R^{1a} to R^{13a} is from 1 to 6, preferably from 1 to 3, more preferably 1.

The number of alcoholic hydroxyl groups contained in the compound represented by formula (ZI-1A) is, in total of all of R^{1a} to R^{13a}, preferably from 1 to 10, more preferably from 1 to 6, still more preferably from 1 to 3.

In the case where R^{1a} to R^{13a} contain no alcoholic hydroxyl group, each of R^{1a} to R^{13a} is preferably a hydrogen atom, a halogen atom, an alkyl group, a monovalent aliphatic hydrocarbon ring group (preferably a cycloalkyl group), an alkenyl group (including a cycloalkenyl group and a bicycloalkenyl group), an alkynyl group, an aryl group, a cyano group, a carboxyl group, an alkoxy group, an aryloxy group, an acyloxy group, a carbamoyloxy group, an acylamino group, an aminocarbonylamino group, an alkoxycarbonylamino group, an aryloxycarbonylamino group, a sulfamoylamino group, an alkylsulfonylamino group, an arylsulfonylamino group, an alkylthio group, an arylthio group, a sulfamoyl group, an alkylsulfonyl group, an arylsulfonyl group, an aryloxycarbonyl group, an alkoxycarbonyl group, a carbamoyl group, an imido group, a silyl group or a ureido group.

In the case where R^{1a} to R^{13a} contain no alcoholic hydroxyl group, each of R^{1a} to R^{13a} is more preferably a hydrogen atom, a halogen atom, an alkyl group, a monovalent aliphatic hydrocarbon ring group (preferably a cycloalkyl group), a cyano group, an alkoxy group, an acyloxy group, an acylamino group, an aminocarbonylamino group, an alkoxycarbonylamino group, an alkylsulfonylamino group, an arylsulfonylamino group, an alkylthio group, a sulfamoyl group, an alkylsulfonyl group, an arylsulfonyl group, an alkoxycarbonyl group or a carbamoyl group.

Furthermore, in the case where R^{1a} to R^{13a} contain no alcoholic hydroxyl group, each of R^{1a} to R^{13a} is still more preferably a hydrogen atom, an alkyl group, a monovalent aliphatic hydrocarbon ring group (preferably a cycloalkyl group), a halogen atom or an alkoxy group.

Two adjacent members of R^{1a} to R^{13a} may cooperate to form a ring (an aromatic or non-aromatic hydrocarbon ring or a heterocyclic ring; the rings may further combine to form a polycyclic condensed ring; examples of the ring include a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophne ring, an isobenzofuran ring, a quinolidine ring, a quinoline ring, a phthalazine ring, a naphthylidine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiine ring, a phenothiazine ring and a phenazine ring).

In formula (ZA-1-1A), at least one of R^{1a} to R^{13a} contains an alcoholic hydroxyl group, and preferably, at least one of R^{9a} to R^{13a} contains an alcoholic hydroxyl group.

Za represents a single bond or a divalent linking group, and examples of the divalent linking group include an alkylene group, an arylene group, a carbonyl group, a sulfonyl group, a carbonyloxy group, a carbonylamino group, a sulfonylamido group, an ether group, a thioether group, an amino group, a disulfide group, an acyl group, an alkylsulfonyl group, —CH═CH—, —C≡C—, an aminocarbonylamino group, and an aminosulfonylamino group. These groups may have a substituent. Examples of the substituent thereon are the same as those of the substituent described for R^{1a} to R^{13a} above. Za is preferably a single bond or a substituent having no electron withdrawing group, such as alkylene group, arylene group, ether group, thioether group, amino group, —CH═CH—, —C≡C—, aminocarbonylamino group and aminosulfonylamino group, more preferably a single bond, an ether group or a thioether group, still more preferably a single bond.

Formula (ZA-1-1 B) is described below.

In formula (ZA-1-1B), each R₁₅ independently represents an alkyl group, a monovalent aliphatic hydrocarbon ring group (preferably a cycloalkyl group) or an aryl group. Two R₁₅s may combine with each other to form a ring.

X₂ represents any one of —CR₂₁═CR₂₂—, —NR₂₃—, —S— and —O—, wherein each of R₂₁ and R₂₂ independently represents a hydrogen atom, an alkyl group, a monovalent aliphatic hydrocarbon ring group (preferably a cycloalkyl group) or an aryl group and RZ₁ represents a hydrogen atom, an alkyl group, a monovalent aliphatic hydrocarbon ring group (preferably a cycloalkyl group), an aryl group or an acyl group.

R represents, when a plurality of R's are present, each independently represents, a substituent. The substituent as R includes, for example, corresponding groups in formulae (ZI-1) to (ZI-3) which are described below as preferred embodiments of formula (ZA-1-1B).

n represents an integer of 0 to 3.

n1 represents an integer of 0 to 11.

The alkyl group in R₁₅ and R₂₁ to R₂₃ may have a substituent and is preferably a linear or branched alkyl group having a carbon number of 1 to 20, and the alkyl chain may contain an oxygen atom, a sulfur atom or a nitrogen atom.

The alkyl group having a substituent includes particularly a group where a monovalent aliphatic hydrocarbon ring group (preferably a cycloalkyl group) is substituted on a linear or branched alkyl group (for example, an adamantylmethyl group, an adamantylethyl group, a cyclohexylethyl group and a camphor residue).

The monovalent aliphatic hydrocarbon ring group in R₁₅ and R₂₁ to R₂₃ may have a substituent and is preferably a cycloalkyl group, more preferably a cycloalkyl group having a carbon number of 3 to 20, and the ring may contain an oxygen atom.

The aryl group in R₁₅ and R₂₁ to R₂₃ may have a substituent and is preferably an aryl group having a carbon number of 6 to 14.

Specific examples and preferred range of the alkyl group in the acyl group of R₂₃ are the same as those of the alkyl group described above.

Examples of the substituent which may be substituted on each of these groups include a halogen atom, a hydroxyl group, a nitro group, a cyano group, a carboxy group, a carbonyl group, an alkyl group (preferably having a carbon number of 1 to 10), a monovalent aliphatic hydrocarbon ring group (preferably having a carbon number of 3 to 10, more preferably a cycloalkyl group having a carbon number of 3 to 10), an aryl group (preferably having a carbon number of 6 to 14), an alkoxy group (preferably having a carbon number of 1 to 10), an aryloxy group (preferably having a carbon number of 6 to 14), an acyl group (preferably having a carbon number of 2 to 20), an acyloxy group (preferably having a carbon number of 2 to 10), an alkoxycarbonyl group (preferably having a carbon number of 2 to 20), an aminoacyl group (preferably having a carbon number of 2 to 20), an alkylthio group (preferably having a carbon number of 1 to 10), and an arylthio group (preferably having a carbon number of 6 to 14). The cyclic structure in the aryl group, monovalent aliphatic hydrocarbon ring group or the like and the aminoacyl group may further have an alkyl group (preferably having a carbon number of 1 to 20) as a substituent.

The ring which may be formed by combining two R₁₅ with each other is a ring structure formed together with —S⁺ shown in formula (ZA-1-1B) and is preferably a 5-membered ring containing one sulfur atom or a condensed ring containing the ring. In the case of a condensed ring, a ring containing one sulfur atom and 18 or less carbon atoms is preferred, and a ring structure represented by the following formulae (IV-1) to (IV-3) is more preferred.

In the formulae, * represents a bond. R represents an arbitrary substituent and examples thereof are the same as those of the substituent which may be substituted on each of the groups in R₁₅ and R₂₁ to R₂₃. n represents an integer of 0 to 4, and n represents an integer of 0 to 3.

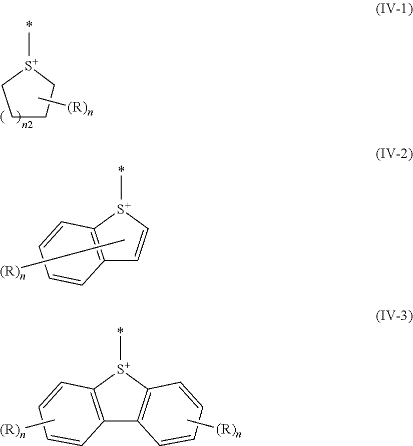

Out of the compounds represented by formulae (ZA-1-1B), preferred cation structures include the following cation structures (ZI-1) to (ZI-3).

The cation structure (ZI-1) is a structure represented by the following formula (ZI-1):

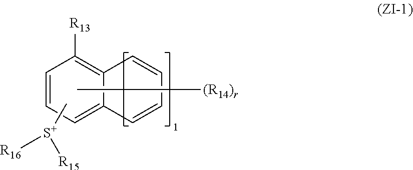

In formula (ZI-1), R₁₃ represents a hydrogen atom, a fluorine atom, a hydroxyl group, an alkyl group, a monovalent aliphatic hydrocarbon ring group, an alkoxy group, an alkoxycarbonyl group, or a group having a monocyclic or polycyclic cycloalkyl skeleton.

R₁₄ represents, when a plurality of R₁₄'s are present, each independently represents an alkyl group, a monovalent aliphatic hydrocarbon ring group, an alkoxy group, an alkylsulfonyl group, a cycloalkylsulfonyl group, a hydroxyl group, or a group having a monocyclic or polycyclic cycloalkyl skeleton.

Each R₁₅ independently represents an alkyl group, a monovalent aliphatic hydrocarbon ring group, or an aryl group. Two R₁₅'s may combine with each other to form a ring.

1 represents an integer of 0 to 2.

r represents an integer of 0 to 8.

In formula (ZI-1), the alkyl group of R₁₃, R₁₄ and R₁₅ is linear or branched and is preferably an alkyl group having a carbon number of 1 to 10, and examples thereof include a methyl group, an ethyl group, an n-propyl group, an i-propyl group, an n-butyl group, a 2-methylpropyl group, a 1-methylpropyl group, a tert-butyl group, an n-pentyl group, a neopentyl group, an n-hexyl group, an n-heptyl group, an n-octyl group, a 2-ethylhexyl group, an n-nonyl group, and an n-decyl group. Among these alkyl groups, a methyl group, an ethyl group, an n-butyl group, and a tert-butyl group are more preferred.

The monovalent aliphatic hydrocarbon ring group of R₁₃, R₁₄ and R₁₅ may be monocyclic or polycyclic and is preferably a monovalent aliphatic hydrocarbon ring group having a carbon number of 3 to 12, and examples thereof include cyclopropyl, cyclobutyl, cyclopentyl, cyclohexyl, cycloheptyl, cyclooctyl, cyclododecanyl, cyclopentenyl, cyclohexenyl, cyclooctadienyl, bicycloheptyl (norbornyl), and adamantyl, with cyclopropyl, cyclopentyl, cyclohexyl and cyclooctyl being more preferred. The monovalent aliphatic hydrocarbon ring group is preferably a cycloalkyl group.

The aryl group of R₁₅ is preferably an aryl group having a carbon number of 6 to 14, more preferably a phenyl group or a naphthyl group.

The alkoxy group of R₁₃ and R₁₄ is linear or branched and is preferably an alkoxy group having a carbon number of 1 to 10, and examples thereof include a methoxy group, an ethoxy group, an n-propoxy group, an i-propoxy group, an n-butoxy group, a 2-methylpropoxy group, a 1-methylpropoxy group, a tert-butoxy group, an n-pentyloxy group, a neopentyloxy group, an n-hexyloxy group, an n-heptyloxy group, an n-octyloxy group, a 2-ethylhexyloxy group, an n-nonyloxy group, and an n-decyloxy group. Among these alkoxy groups, a methoxy group, an ethoxy group, an n-propoxy group and an n-butoxy group are preferred.

The alkoxycarbonyl group of R₁₃, which is linear or branched, is preferably an alkoxycarbonyl group having a carbon number of 2 to 11 and includes, for example, those where the alkyl group in R₁₃, R₁₄, and R₁₅ is substituted on a carbonyl group. Examples thereof include a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a tert-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, and an n-decyloxycarbonyl group. Among these alkoxycarbonyl groups, a methoxycarbonyl group, an ethoxycarbonyl group, and an n-butoxycarbonyl group are preferred.

The group having a monocyclic or polycyclic cycloalkyl skeleton of R₁₃ and R₁₄ includes, for example, a monocyclic or polycyclic cycloalkyloxy group, and an alkoxy group having a monocyclic or polycyclic cycloalkyl group. These groups may further have a substituent.

The monocyclic or polycyclic cycloalkyloxy group of R₁₃ and R₁₄ preferably has a total carbon number of 7 or more, more preferably a total carbon number of 7 to 15, and also, preferably has a monocyclic cycloalkyl skeleton. The monocyclic cycloalkyloxy group having a total carbon number of 7 or more is a monocyclic cycloalkyloxy group where a cycloalkyloxy group such as cyclopropyloxy group, cyclobutyloxy group, cyclopentyloxy group, cyclohexyloxy group, cycloheptyloxy group, cyclooctyloxy group and cyclododecanyloxy group has arbitrarily a substituent such as alkyl group (e.g., methyl, ethyl, propyl, butyl, pentyl, hexyl, heptyl, octyl, dodecyl, 2-ethylhexyl, isopropyl, sec-butyl, tert-butyl, isoamyl group), hydroxyl group, halogen atom (fluorine, chlorine, bromine or iodine), nitro group, cyano group, amido group, sulfonamido group, alkoxy group (e.g., methoxy, ethoxy, hydroxyethoxy, propoxy, hydroxypropoxy, butoxy), alkoxycarbonyl group (e.g., methoxycarbonyl, ethoxycarbonyl), acyl group (e.g., formyl, acetyl, benzoyl), acyloxy group (e.g., acetoxy, butyryloxy) and carboxy group and where the total carbon number including the arbitrary substituent on the cycloalkyl group is 7 or more.

Examples of the polycyclic cycloalkyloxy group having a total carbon number of 7 or more include a norbornyloxy group, a tricyclodecanyloxy group, a tetracyclodecanyloxy group, and an adamantyloxy group.

The alkoxy group having a monocyclic or polycyclic cycloalkyl skeleton of R₁₃ and R₁₄ preferably has a total carbon number of 7 or more, more preferably a total carbon number of 7 to 15, and also, is preferably an alkoxy group having a monocyclic cycloalkyl skeleton. The alkoxy group having a total carbon number of 7 or more and having a monocyclic cycloalkyl skeleton indicates an alkoxy group where the above-described monocyclic cycloalkyl group which may have a substituent is substituted on an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, tert-butoxy and isoamyloxy and where the total carbon number including the substituent is 7 or more. Examples thereof include a cyclohexylmethoxy group, a cyclopentylethoxy group, and a cyclohexylethoxy group, with a cyclohexylmethoxy group being preferred.

Examples of the alkoxy group having a total carbon number of 7 or more and having a polycyclic cycloalkyl skeleton include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, and an adamantylethoxy group, with a norbornylmethoxy group and a norbornylethoxy group being preferred.

The alkylsulfonyl group and cycloalkylsulfonyl group of R₁₄ are a linear, branched or cyclic alkylsulfonyl group preferably having a carbon number of 1 to 10 and includes, for example, those where the alkyl group in R₁₃, R₁₄ and R₁₅ is substituted on a sulfonyl group, and examples thereof include a methanesulfonyl group, an ethanesulfonyl group, an n-propanesulfonyl group, an n-butanesulfonyl group, a tert-butanesulfinyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, and a cyclohexanesulfonyl group. Among these alkylsulfonyl groups and cycloalkylsulfonyl groups, a methanesulfonyl group, an ethanesulfonyl group, an n-propanesulfonyl group, an n-butanesulfonyl group, a cyclopentanesulfonyl group and a cyclohexanesulfonyl group are more preferred.

1 is preferably 0 or 1, more preferably 1.

r is preferably 0 to 2.

Each of the groups of R₁₃, R₁₄ and R₁₅ may further have a substituent, and examples of the substituent which may be substituted on the groups include an alkyl group such as methyl group, ethyl group, propyl group, butyl group, pentyl group, hexyl group, heptyl group, octyl group, dodecyl group, 2-ethylhexyl group, isopropyl group, sec-butyl group, tert-butyl group and isoamyl group, a monovalent aliphatic hydrocarbon ring group (may be monocyclic or polycyclic; preferably having a carbon number of 3 to 20, more preferably a carbon number of 5 to 8), a hydroxyl group, a halogen atom (fluorine, chlorine, bromine or iodine), a nitro group, a cyano group, an amido group, a sulfonamido group, an alkoxy group, an alkoxyalkyl group, an alkoxycarbonyl group, an alkoxycarbonyloxy group, an acyl group such as formyl group, acetyl group and benzoyl group, an acyloxy group such as acetoxy group and butyryloxy group, and a carboxy group.

Examples of the alkoxy group include a linear, branched or cyclic alkoxy group having a carbon number of 1 to 20, such as methoxy group, ethoxy group, n-propoxy group, i-propoxy group, n-butoxy group, 2-methylpropoxy group, 1-methylpropoxy group, tert-butoxy group, cyclopentyloxy group and cyclohexyloxy group.

Examples of the alkoxyalkyl group include a linear, branched or cyclic alkoxyalkyl group having a carbon number of 2 to 21, such as methoxymethyl group, ethoxymethyl group, 1-methoxyethyl group, 2-methoxyethyl group, 1-ethoxyethyl group and 2-ethoxyethyl group.

Examples of the alkoxycarbonyl group include a linear, branched or cyclic alkoxycarbonyl group having a carbon number of 2 to 21, such as methoxycarbonyl group, ethoxycarbonyl group, n-propoxycarbonyl group, i-propoxycarbonyl group, n-butoxycarbonyl group, 2-methylpropoxycarbonyl group, 1-methylpropoxycarbonyl group, tert-butoxycarbonyl group, cyclopentyloxycarbonyl group and cyclohexyloxycarbonyl group.

Examples of the alkoxycarbonyloxy group include a linear, branched or cyclic alkoxycarbonyloxy group having a carbon number of 2 to 21, such as methoxycarbonyloxy group, ethoxycarbonyloxy group, n-propoxycarbonyloxy group, i-propoxycarbonyloxy group, n-butoxycarbonyloxy group, tert-butoxycarbonyloxy group, cyclopentyloxycarbonyloxy group and cyclohexyloxycarbonyloxy group.

The ring structure which may be formed by combining two R₁₅'s with each other is preferably a 5- or 6-membered ring formed by a divalent group that is formed by combining two R₁₅'s, together with the sulfur atom in formula (ZI-1), more preferably a 5-membered ring (that is, a tetrahydrothiophene ring), and the ring may be fused with an aryl group or an aliphatic hydrocarbon ring group (preferably a cycloalkyl group). The divalent group above may have a substituent, and examples of the substituent include an alkyl group, a cycloalkyl group, a hydroxyl group, a carboxyl group, a cyano group, a nitro group, an alkoxy group, an alkoxyalkyl group, an alkoxycarbonyl group, and an alkoxycarbonyloxy group.

R₁₅ in formula (ZI-1) is preferably, for example, a methyl group, an ethyl group, a naphthyl group, or a divalent group in the case where two R₁₅'s are combined to form a tetrahydrothiophene ring structure together with the sulfur atom.

The alkyl group, monovalent aliphatic hydrocarbon ring group, alkoxy group and alkoxycarbonyl group of R₁₃ and the alkyl group, monovalent aliphatic hydrocarbon ring group, alkoxy group, alkylsulfonyl group and cycloalkylsulfonyl group of R₁₄ may be substituted as described above, and the substituent is preferably a hydroxyl group, an alkoxy group, an alkoxycarbonyl group or a halogen atom (particularly fluorine atom).

Specific preferred examples of the cation structure represented by formula (ZI-1) are illustrated below.

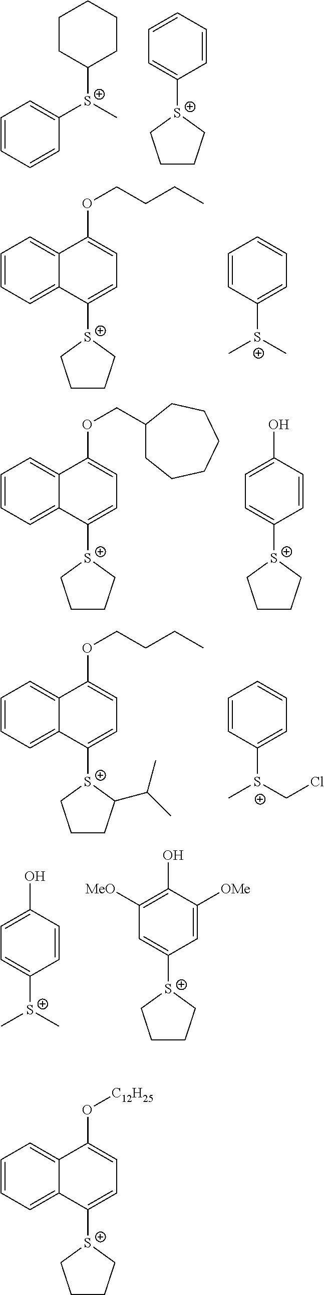

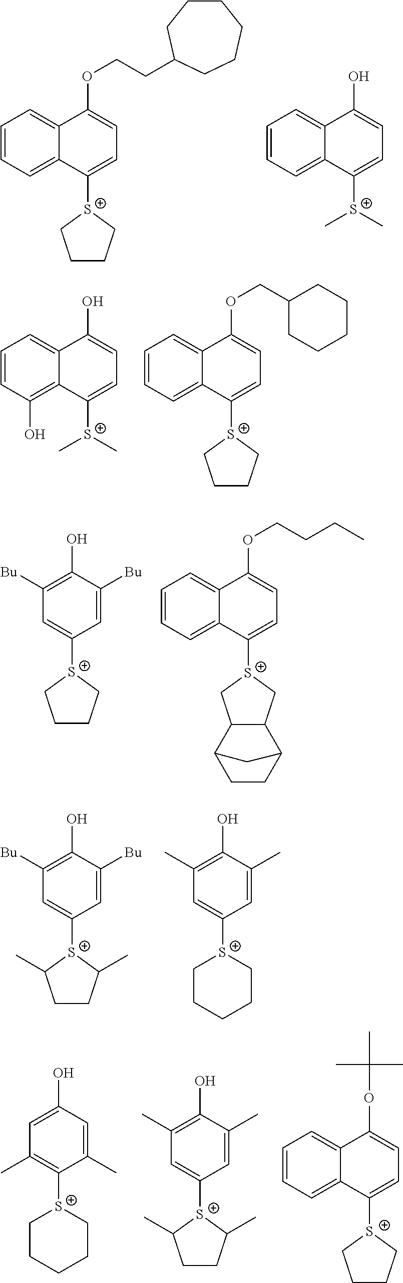

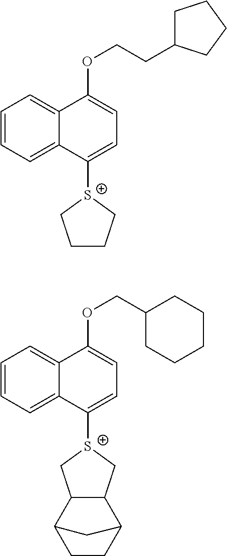 [SMILES: c1ccc2c([S+]3CCCC3)ccc(OCCC3CCCC3)c2c1 ; c1ccc2c([S+]3CC4C5CCC(C5)C4C3)ccc(OCC3CCCCC3)c2c1]

The cation structure (ZI-2) is a structure represented by the following formula (ZI-2):

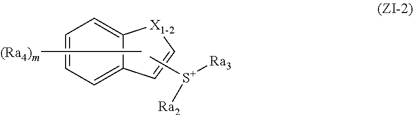

In formula (ZI-2), X₁₋₂ represents an oxygen atom, a sulfur atom, or a —NRa₁— group, where in Ra₁ represents a hydrogen atom, an alkyl group, a monovalent aliphatic hydrocarbon ring group, an aryl group or an acyl group.

Each of Ra₂ and Ra₃ independently represents an alkyl group, a monovalent aliphatic hydrocarbon ring group, an alkenyl group or an aryl group. Ra₂ and Ra₃ may combine with each other to form a ring.

Ra₄ represents, when a plurality of Rags are present, each independently represents, a monovalent group.

m represents an integer of 0 to 3.

The alkyl group of Ra₁ to Ra₃ is preferably a linear or branched alkyl group having a carbon number of 1 to 20, and examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group and an eicosyl group.

The monovalent aliphatic hydrocarbon ring group of Ra₁ to Ra₃ is preferably a monovalent aliphatic hydrocarbon ring group having a carbon number of 3 to 20, and examples thereof include a cyclopropyl group, a cyclobutyl group, a cyclopentyl group, a cyclohexyl group, a cyclooctyl group, an adamantyl group, a norbornyl group, an isoboronyl group, a camphanyl group, a dicyclopentyl group, an α-pinel group, a tricyclodecanyl group, a tetracyclododecyl group and an androstanyl group. The monovalent aliphatic hydrocarbon ring group is preferably a cycloalkyl group.

The aryl group of Ra₁ to Ra₃ is preferably an aryl group having a carbon number of 6 to 10, and examples thereof include a phenyl group and a naphthyl group.

The acyl group of Ra₁ is preferably an acyl group having a carbon number of 2 to 20, and examples thereof include a formyl group, an acetyl group, a propanoyl group, a butanoyl group, a pivaloyl group, and a benzoyl group.

The alkenyl group of Ra₂ and Ra₃ is preferably an alkenyl group having a carbon number of 2 to 15, and examples thereof include a vinyl group, an allyl group, a butenyl group, and a cyclohexenyl group.

As for the ring structure which may be formed by combining Ra₂ and Ra₃ with each other, a group capable of forming a 5- or 6-membered ring, more preferably a 5-membered ring (that is, a tetrahydrothiophene ring), together with the sulfur atom in formula (ZI-2) is preferred. The ring may contain an oxygen atom, and specific examples of the ring are the same as those of the ring which may be formed by combining R₁₅'s with each other in formula (ZI-1).

Examples of the monovalent group of Ra₄ include an alkyl group (preferably having a carbon number of 1 to 20), a monovalent aliphatic hydrocarbon ring group (preferably having a carbon number of 3 to 20, more preferably a cycloalkyl group having a carbon number of 3 to 20), an aryl group (preferably having a carbon number of 6 to 10), an alkoxy group (preferably having a carbon number of 1 to 20), an acyl group (preferably having a carbon number of 2 to 20), an acyloxy group (preferably having a carbon number of 2 to 20), a fluorine atom, a chlorine atom, a bromine atom, an iodine atom, a hydroxyl group, a carboxyl group, a nitro group, a cyano group, an alkoxycarbonyl group, an alkylsulfonyl group, an arylsulfonyl group, an arylcarbonyl group, an alkylcarbonyl group, and an alkenylcarbonyl group.

Ra₁ is more preferably an alkyl group, still more preferably an alkyl group having a carbon number of 1 to 4.

Ra₂ and Ra₃ more preferably constitute a 5- or 6-membered ring by combining with each other.

Each of the groups in Ra₁ to Ra₄ may further have a substituent, and examples of the substituent which may be further substituted on are the same as those of the further substituent which may be substituted on each of the groups of R₁₃ to R₁₅ in formula (ZI-1).

Specific preferred examples of the cation in the compound represented by formula (ZI-2) are illustrated below.

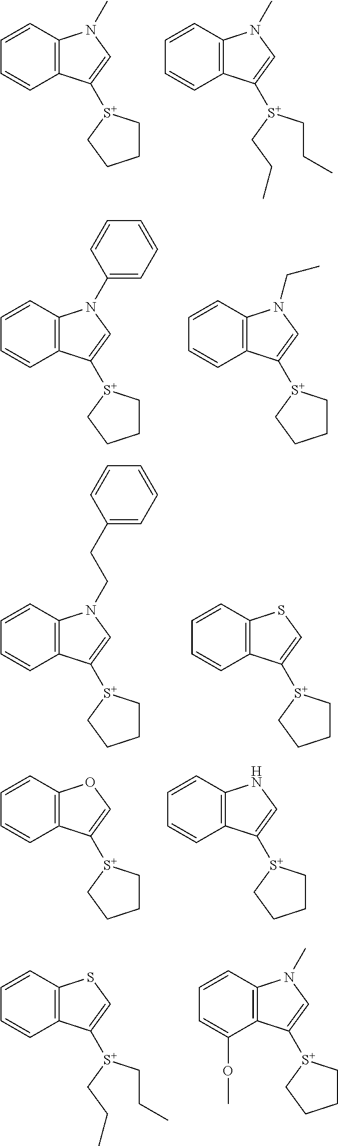

The cation structure (ZI-3) is a structure represented by the following formula (ZI-3):

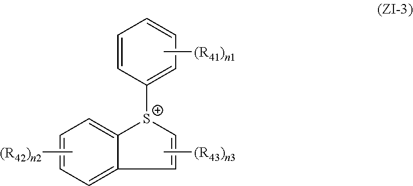

In formula (ZI-3), each of R₄₁ to R₄₃ independently represents an alkyl group, an acetyl group, an alkoxy group, a carboxy group, a halogen atom, a hydroxyl group or a hydroxyalkyl group.

Examples of the alkyl group and alkoxy group as R₄₁ to R₄₃ are the same as those for R₁₃ to R₁₅ in formula (ZI-1).

The hydroxyalkyl group is preferably a group formed by substituting a hydroxy group for one hydrogen atom or a plurality of hydrogen atoms in the alkyl group above, and examples thereof include a hydroxymethyl group, a hydroxyethyl group and a hydroxypropyl group.

n1 is an integer of 0 to 3, preferably 1 or 2, more preferably 1.

n2 is an integer of 0 to 3, preferably 0 or 1, more preferably 0.

n3 is an integer of 0 to 2, preferably 0 or 1, more preferably 1.

Each of the groups in R₄₁ to R₄₃ may further have a substituent, and examples of the substituent which may be further substituted on are the same as those of the further substituent which may be substituted on each of the groups of R₁₃ to R₁₅ in formula (ZI-1).

Specific preferred examples of the cation in the compound represented by formula (ZI-3) are illustrated below.

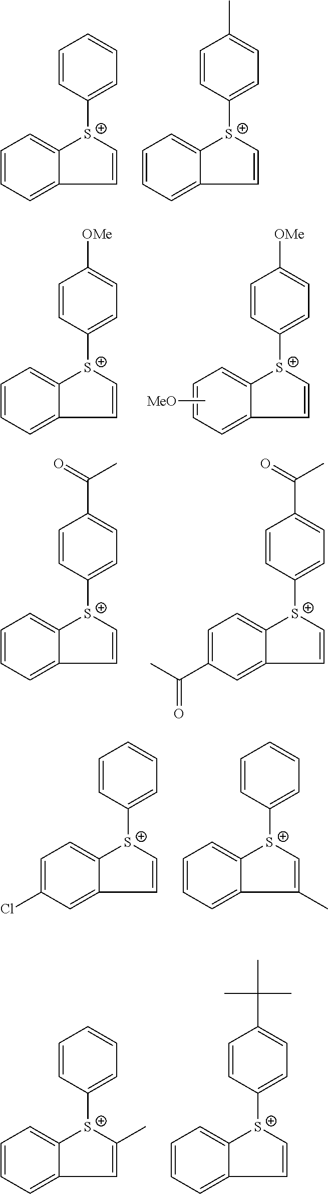

Among the cation structures represented by formulae (ZI-1) to (ZI-3), structures (ZI-1) and (ZI-2) are preferred, and (ZI-1) is more preferred.

Next, (ZA-1-2) is described.

(ZA-1-2) is a group where each of R₂₀₁ to R₂₀₃ in formula (ZA-1) independently represents an aromatic ring-free organic group. The aromatic ring as used herein encompasses an aromatic ring containing a heteroatom.

The aromatic ring-free organic group as R₂₀₁ to R₂₀₃ has a carbon number of generally from 1 to 30, preferably from 1 to 20.

Each of R₂₀₁ to R₂₀₃ is independently preferably an alkyl group, a monovalent aliphatic hydrocarbon ring group, an allyl group or a vinyl group, more preferably a linear or branched 2-oxoalkyl group, a 2-oxo aliphatic hydrocarbon ring group or an alkoxycarbonylmethyl group, still more preferably a linear or branched 2-oxo aliphatic hydrocarbon ring group.

The alkyl group and aliphatic hydrocarbon ring group of R₂₀₁ to R₂₀₃ are preferably a linear or branched alkyl group having a carbon number of 1 to 10 (e.g., methyl, ethyl, propyl, butyl, pentyl) and an aliphatic hydrocarbon ring group having a carbon number of 3 to 10 (e.g., cyclopentyl, cyclohexyl, norbornyl). The alkyl group is more preferably a 2-oxoalkyl group or an alkoxycarbonylmethyl group. The aliphatic hydrocarbon ring group is more preferably a 2-oxo aliphatic hydrocarbon ring group. It is preferred that the aliphatic hydrocarbon ring group is a cycloalkyl group.

The 2-oxoalkyl group may be either linear or branched and is preferably a group having >C═O at the 2-position of the above-described alkyl group.

The 2-oxo aliphatic hydrocarbon ring group is preferably a group having >C═O at the 2-position of the above-described aliphatic hydrocarbon ring group. It is preferred that the 2-oxo aliphatic hydrocarbon ring group is a 2-oxocycloalkyl group.

The alkoxy group in the alkoxycarbonylmethyl group is preferably an alkoxy group having a carbon number of 1 to 5 (e.g., methoxy, ethoxy, propoxy, butoxy, pentoxy).

Each of R₂₀₁ to R₂₀₃ may be further substituted with a halogen atom, an alkoxy group (for example, having a carbon number of 1 to 5), a hydroxyl group, a cyano group or a nitro group.

Next, (ZA-1-3) is described.

(ZA-1-3) is a group represented by the following formula and is a group having a phenacylsulfonium salt structure:

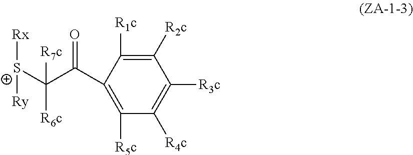

In formula (ZA-1-3), each of R_{1c} to R_{5c} independently represents a hydrogen atom, an alkyl group, a monovalent aliphatic hydrocarbon ring group, an alkoxy group, a phenylthio group or a halogen atom.

Each of R_{6c} and R_{7c} independently represents a hydrogen atom, an alkyl group or a monovalent aliphatic hydrocarbon ring group.

Each of Rₓ and R_{y} independently represents an alkyl group, a monovalent aliphatic hydrocarbon ring group, an allyl group or a vinyl group.

Any two or more members out of R_{1c} to R_{5c}, the pair of R_{6c} and R_{7c}, and the pair of Rₓ and R_{y}, each may combine to form a ring structure. The ring structure may contain an oxygen atom, a sulfur atom, an ester bond or an amide bond. Examples of the group that is formed by combining any two or more members out of R_{1c} to R_{5c}, the pair of R_{6c} and R_{7c}, or the pair of Rₓ and R_{y} include a butylene group and a pentylene group.

The alkyl group as R_{1c} to R_{7c} may be either linear or branched and includes, for example, an alkyl group having a carbon number of 1 to 20, preferably a linear or branched alkyl group having a carbon number of 1 to 12 (e.g., methyl, ethyl, linear or branched propyl, linear or branched butyl, linear or branched pentyl).

The monovalent aliphatic hydrocarbon ring group as R_{1c} to R_{7c} may be either monocyclic or polycyclic and includes, for example, a monovalent aliphatic hydrocarbon ring group having a carbon number of 3 to 8 (e.g., cyclopentyl, cyclohexyl). The monovalent aliphatic hydrocarbon ring group is preferably a cycloalkyl group.

The alkoxy group as R_{1c} to R_{5c} may be linear, branched or cyclic and includes, for example, an alkoxy group having a carbon number of 1 to 10, preferably a linear or branched alkoxy group having a carbon number of 1 to 5 (e.g., methoxy, ethoxy, linear or branched propoxy, linear or branched butoxy, linear or branched pentoxy), and a cyclic alkoxy group having a carbon number of 3 to 8 (e.g., cyclopentyloxy, cyclohexyloxy).

A configuration where any one of R_{1c} to R_{5c} is a linear or branched alkyl group, a monovalent aliphatic hydrocarbon ring group, or a linear, branched or cyclic alkoxy group is preferred, and a configuration where the sum of carbon numbers of R_{1c} to R_{5c} is from 2 to 15 is more preferred. Thanks to such a configuration, the solvent solubility is more enhanced and production of particles during storage can be suppressed.

The alkyl group and monovalent aliphatic hydrocarbon ring group as Rₓ and R_{y} include the same alkyl group and monovalent aliphatic hydrocarbon ring group as in R_{1c} to R_{7c} and are preferably a 2-oxoalkyl group, a 2-oxo aliphatic hydrocarbon ring group or an alkoxycarbonylmethyl group.

The 2-oxoalkyl group and 2-oxo aliphatic hydrocarbon ring group include groups having >C═O at the 2-position of the alkyl group and aliphatic hydrocarbon ring group as R_{1c} to R_{7c}.

The alkoxy group in the alkoxycarbonylmethyl group includes the same alkoxy group as in R_{1c} to R_{5c}.

Rₓ and R_{y} are preferably an alkyl group or monovalent aliphatic hydrocarbon ring group having a carbon number of 4 or more, more preferably 6 or more, still more preferably 8 or more.

The ring structure which may be formed by combining Rₓ and R_{y} with each other includes a 5- or 6-membered ring, preferably a 5-membered ring (that is, a tetrahydrothiophene ring), formed by divalent Rₓ and R_{y} (for example, a methylene group, an ethylene group or a propylene group) together with the sulfur atom in formula (ZA-1-3).

Formula (ZA-2) is described below.

In formula (ZA-2), each of R₂₀₄ and R₂₀₅ independently represents an aryl group, an alkyl group or a monovalent aliphatic hydrocarbon ring group.

The aryl group of R₂₀₄ and R₂₀₅ is preferably a phenyl group or a naphthyl group, more preferably a phenyl group. The aryl group of R₂₀₄ and R₂₀₅ may be an aryl group having a heterocyclic structure containing an oxygen atom, a nitrogen atom, a sulfur atom or the like. Examples of the aryl group having a heterocyclic structure include a pyrrole residue group (a group formed by removing one hydrogen atom from a pyrrole), a furan residue group (a group formed by removing one hydrogen atom from a furan), a thiophene residue group (a group formed by removing one hydrogen atom from a thiophene), an indole residue group (a group formed by removing one hydrogen atom from an indole), a benzofuran residue group (a group formed by removing one hydrogen atom from a benzofuran) and a benzothiophene residue group (a group formed by removing one hydrogen atom from a benzothiophene).

The alkyl group and monovalent aliphatic hydrocarbon ring group of R₂₀₄ and R₂₀₅ are preferably a linear or branched alkyl group having a carbon number of 1 to 10 (e.g., methyl, ethyl, propyl, butyl, pentyl) and a monovalent aliphatic hydrocarbon ring group having a carbon number of 3 to 10 (e.g., cyclopentyl, cyclohexyl, norbornyl). The monovalent aliphatic hydrocarbon ring group is preferably a cycloalkyl group.

The aryl group, alkyl group and monovalent aliphatic hydrocarbon ring group of R₂₀₄ and R₂₀₅ may have a substituent. Examples of the substituent which may be substituted on the aryl group, alkyl group and monovalent aliphatic hydrocarbon ring group of R₂₀₄ and R₂₀₅ include an alkyl group (for example, having a carbon number of 1 to 15), a monovalent aliphatic hydrocarbon ring group (for example, having a carbon number of 3 to 15; preferably a cycloalkyl group having a carbon number of 3 to 15), an aryl group (for example, having a carbon number of 6 to 15), an alkoxy group (for example, having a carbon number of 1 to 15), a halogen atom, a hydroxyl group and a phenylthio group.

Specific examples of the cation constituting the onium salt suitable as Z in formula (IV) are illustrated below.

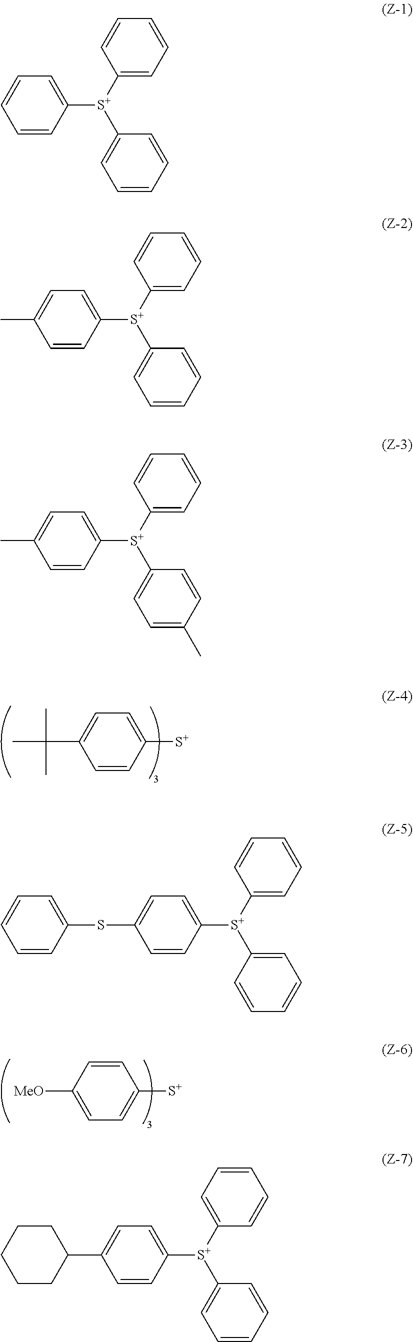

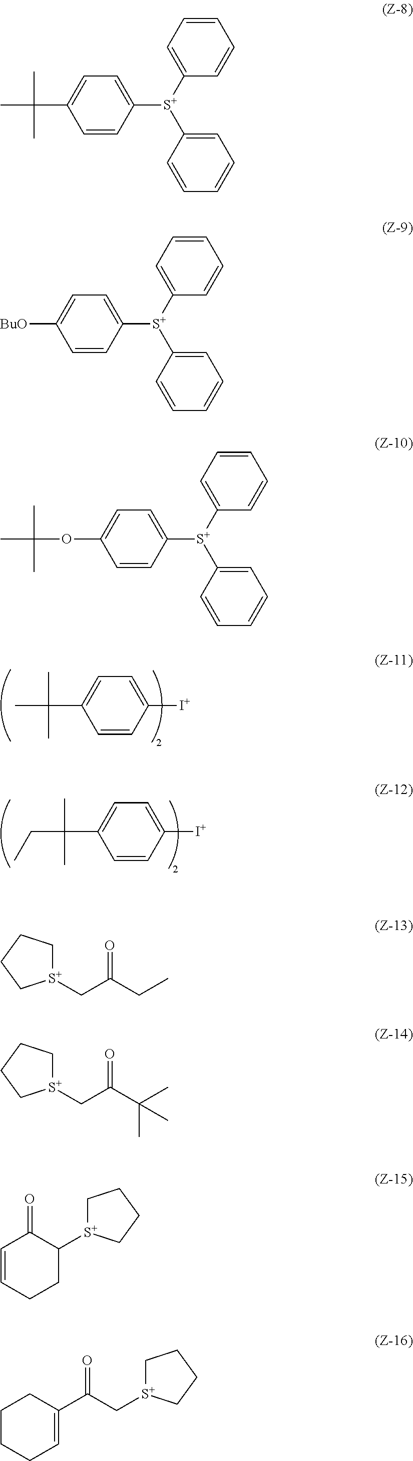

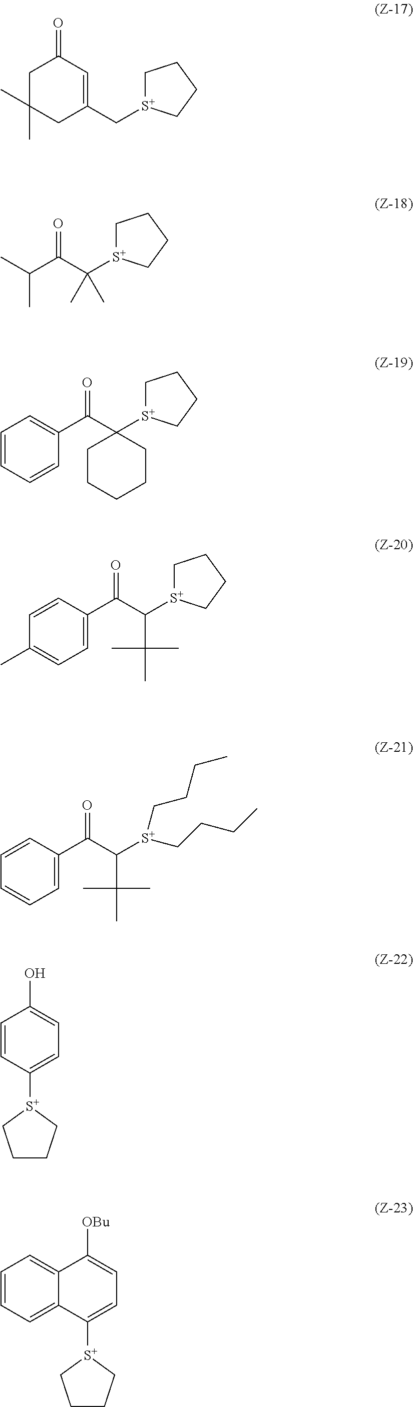

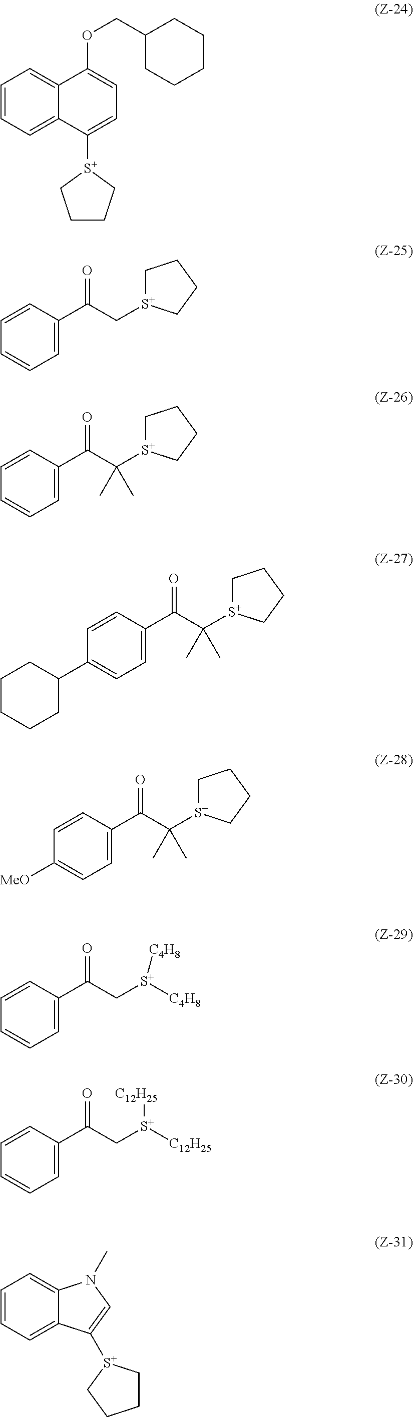

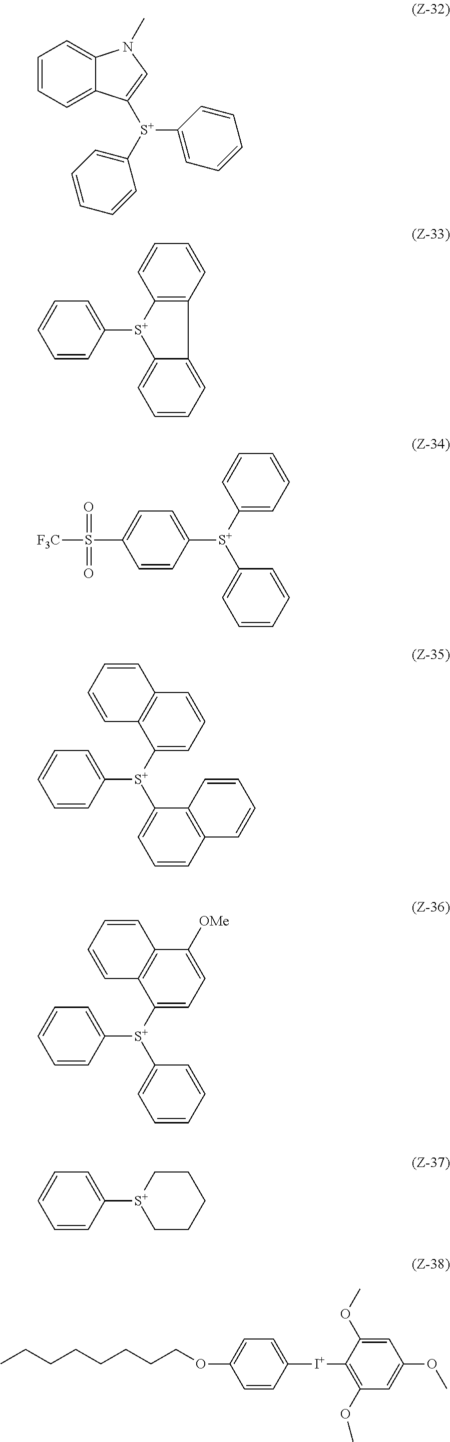

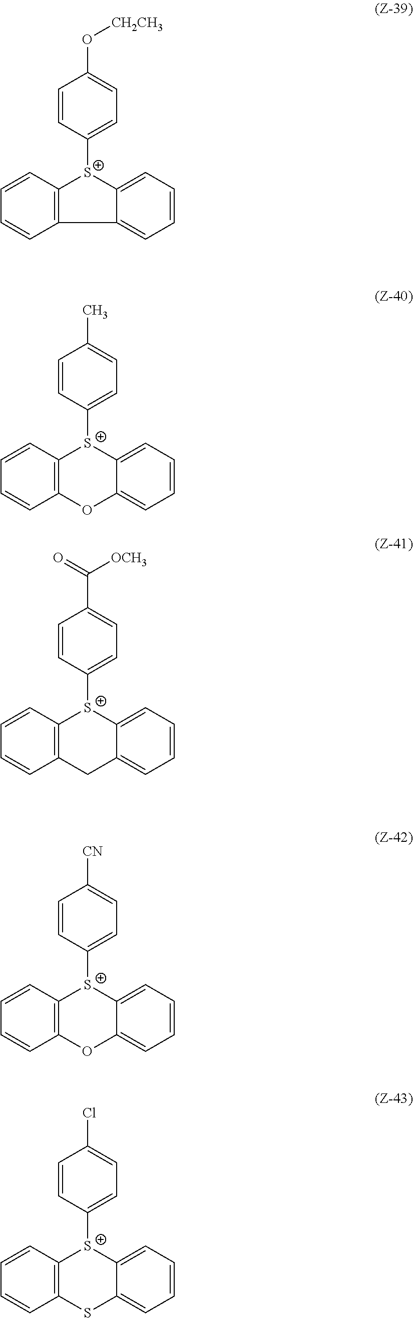 [SMILES: CCOc1ccc(-[s+]2c3ccccc3c3ccccc32)cc1 ; Cc1ccc([S+]2c3ccccc3Oc3ccccc32)cc1 ; COC(=O)c1ccc([S+]2c3ccccc3Cc3ccccc32)cc1 ; N#Cc1ccc([S+]2c3ccccc3Oc3ccccc32)cc1 ; Clc1ccc([S+]2c3ccccc3Sc3ccccc32)cc1]

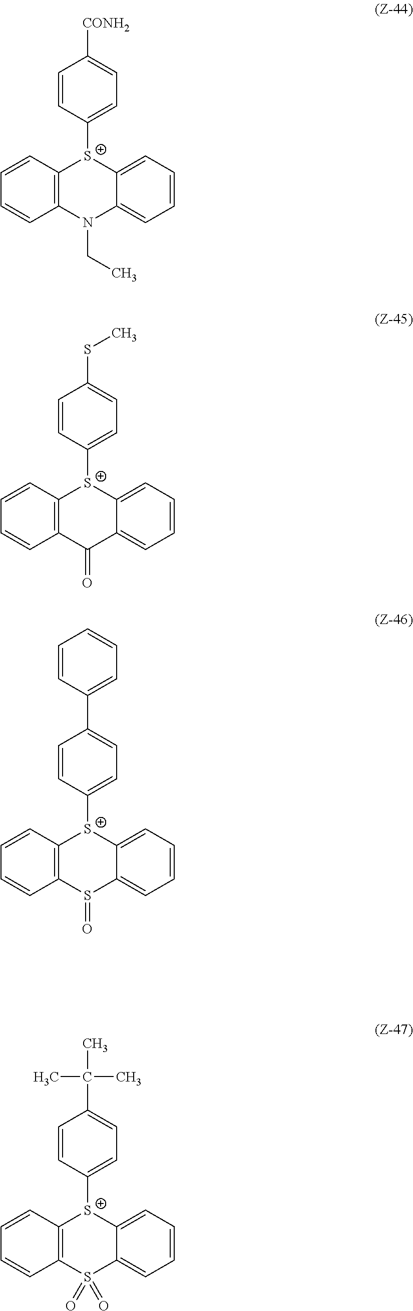 [SMILES: CCN1c2ccccc2[S+](c2ccc(C(N)=O)cc2)c2ccccc21 ; CSc1ccc(-[s+]2c3ccccc3c(=O)c3ccccc32)cc1 ; O=S1c2ccccc2[S+](c2ccc(-c3ccccc3)cc2)c2ccccc21 ; CC(C)(C)c1ccc([S+]2c3ccccc3S(=O)(=O)c3ccccc32)cc1]

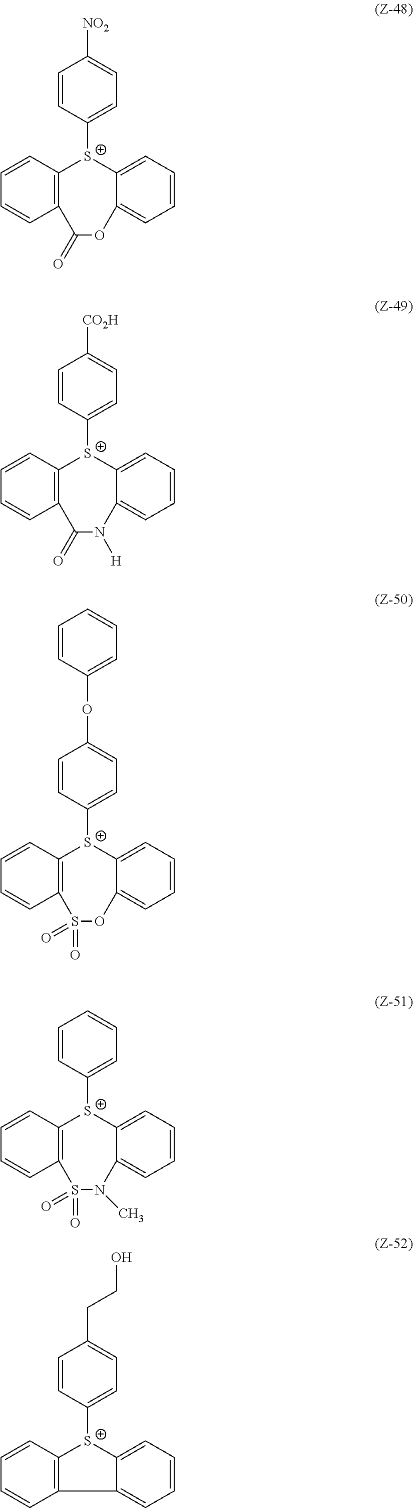 [SMILES: O=C1Oc2ccccc2[S+](c2ccc([N+](=O)[O-])cc2)c2ccccc21 ; O=C(O)c1ccc([S+]2c3ccccc3NC(=O)c3ccccc32)cc1 ; O=S1(=O)Oc2ccccc2[S+](c2ccc(Oc3ccccc3)cc2)c2ccccc21 ; CN1c2ccccc2[S+](c2ccccc2)c2ccccc2S1(=O)=O ; OCCc1ccc(-[s+]2c3ccccc3c3ccccc32)cc1]

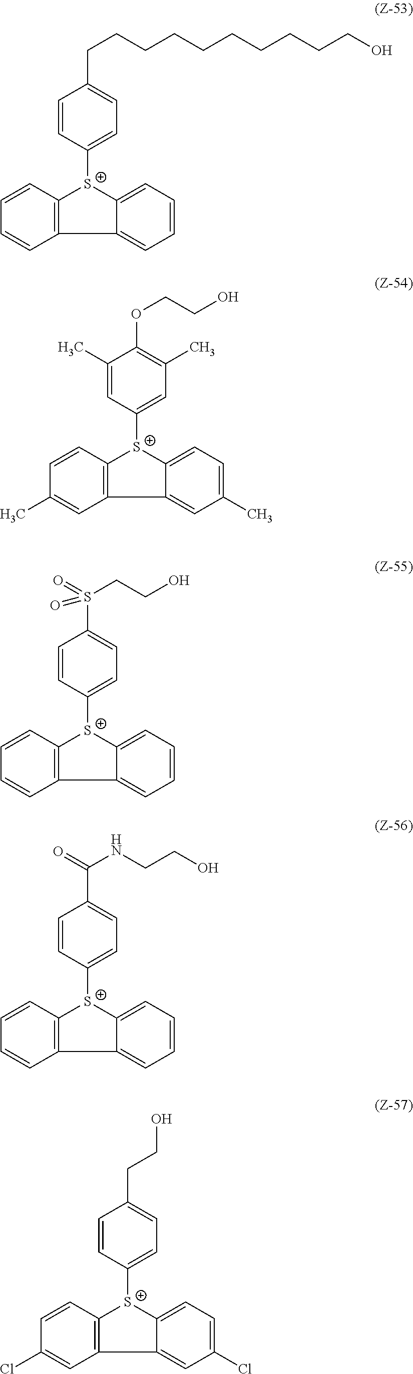

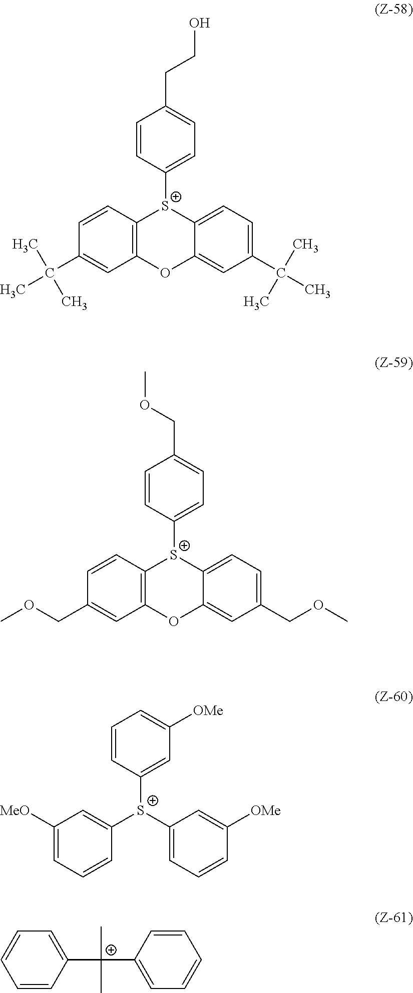

With respect to the repeating unit represented by formula (IV), specific examples of the monomer corresponding to the acid anion that is produced resulting from leaving of the cation upon irradiation with an actinic ray or radiation are illustrated below.

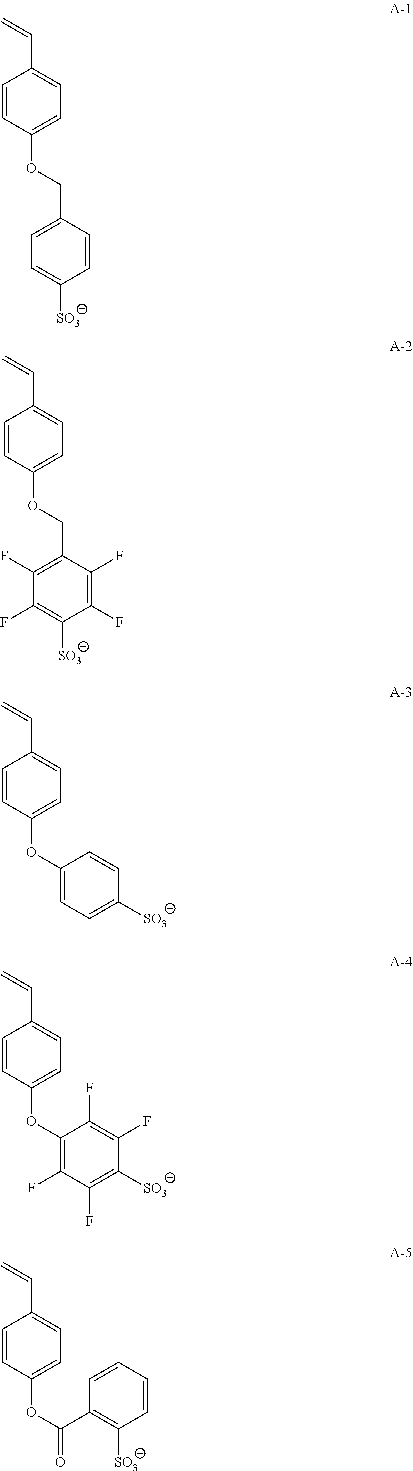

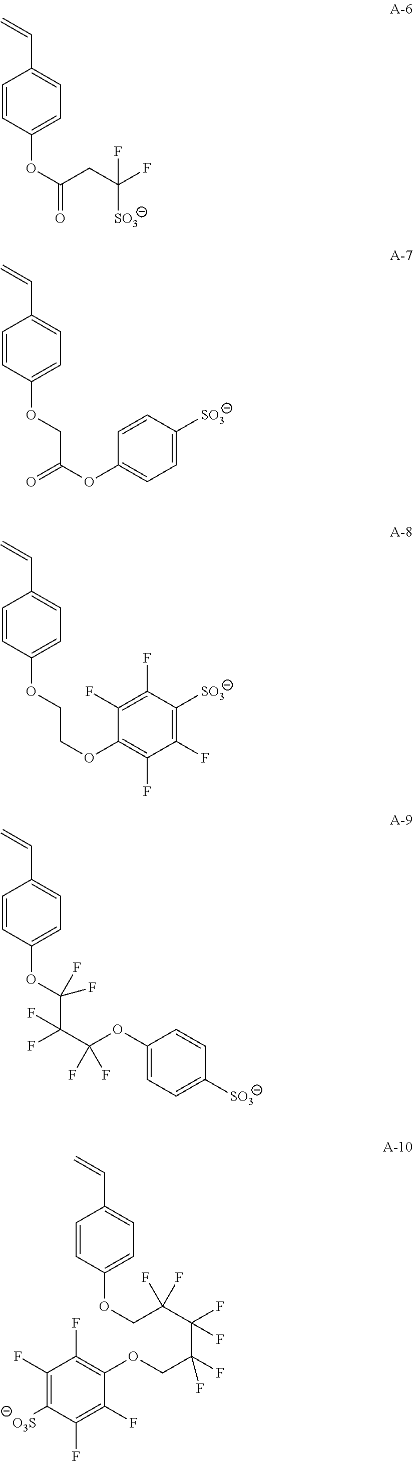

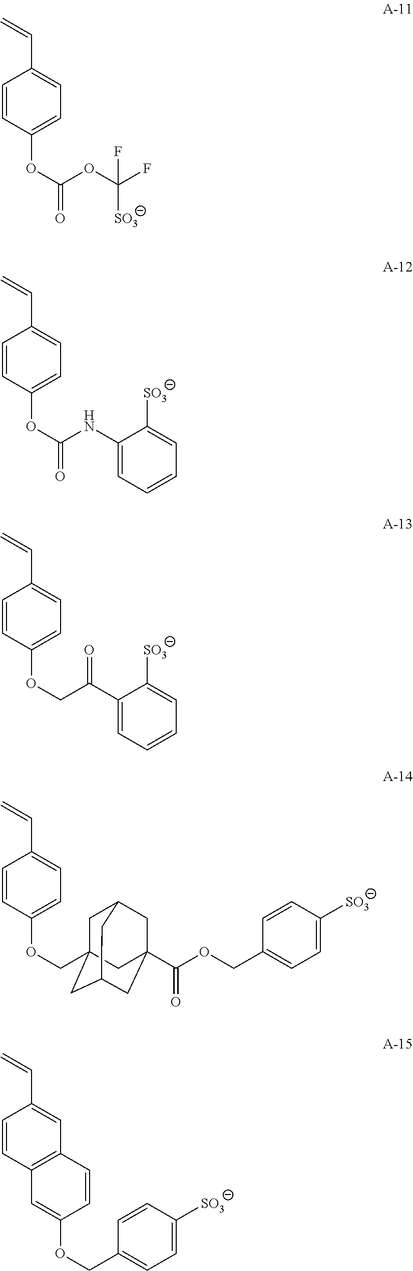

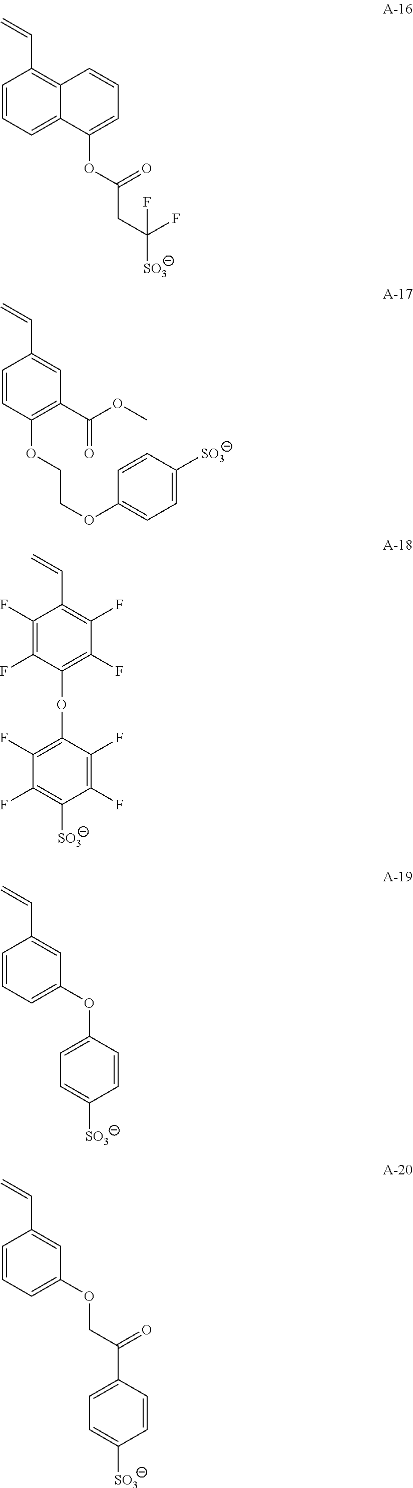

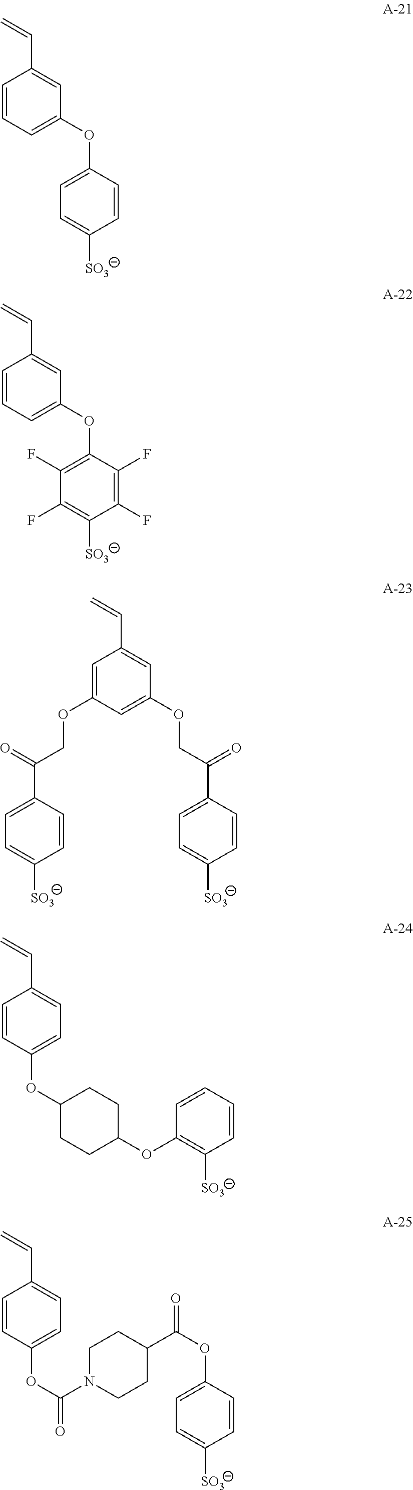

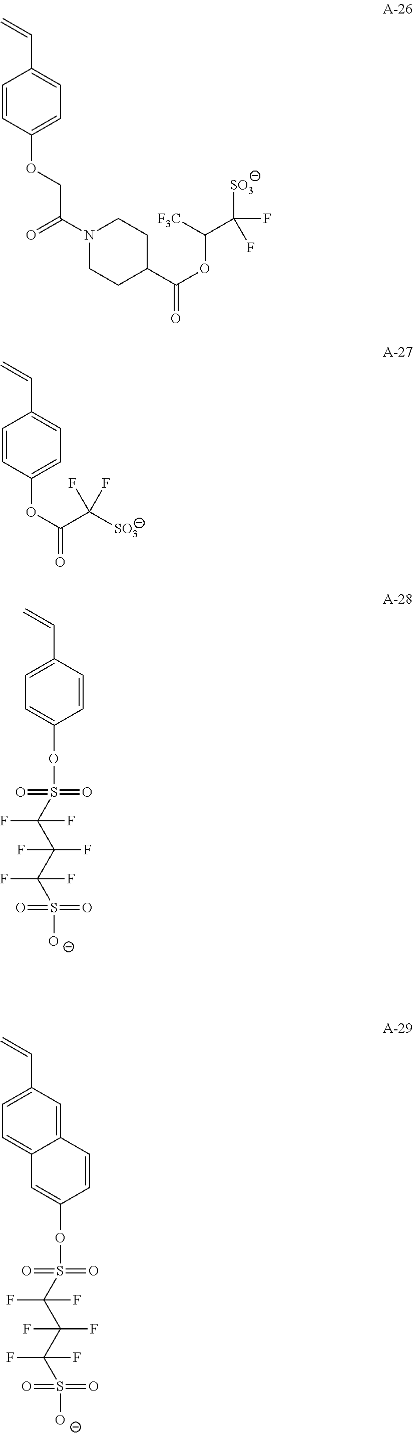

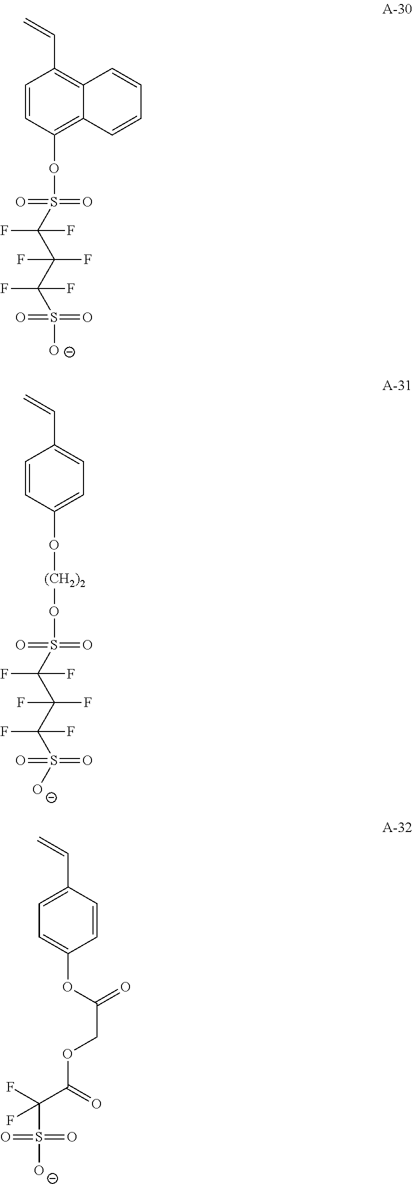

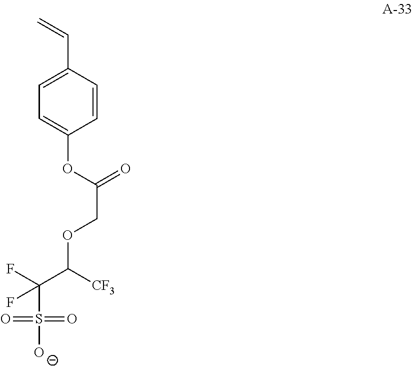

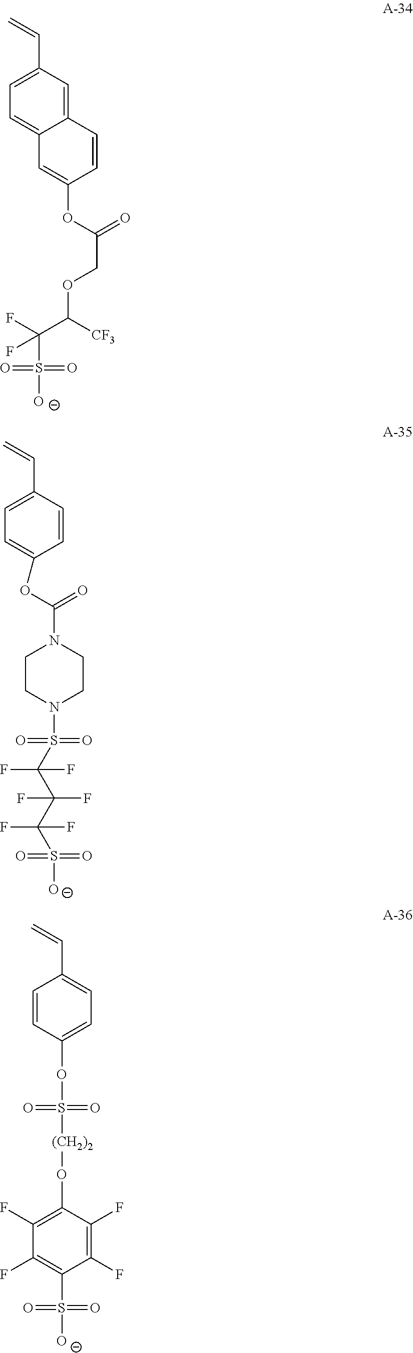

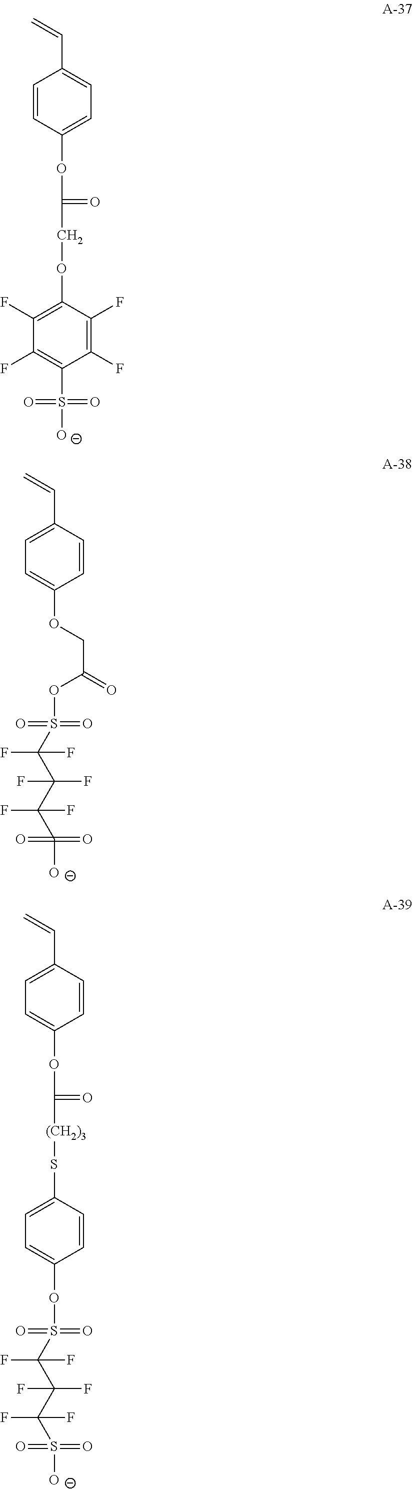

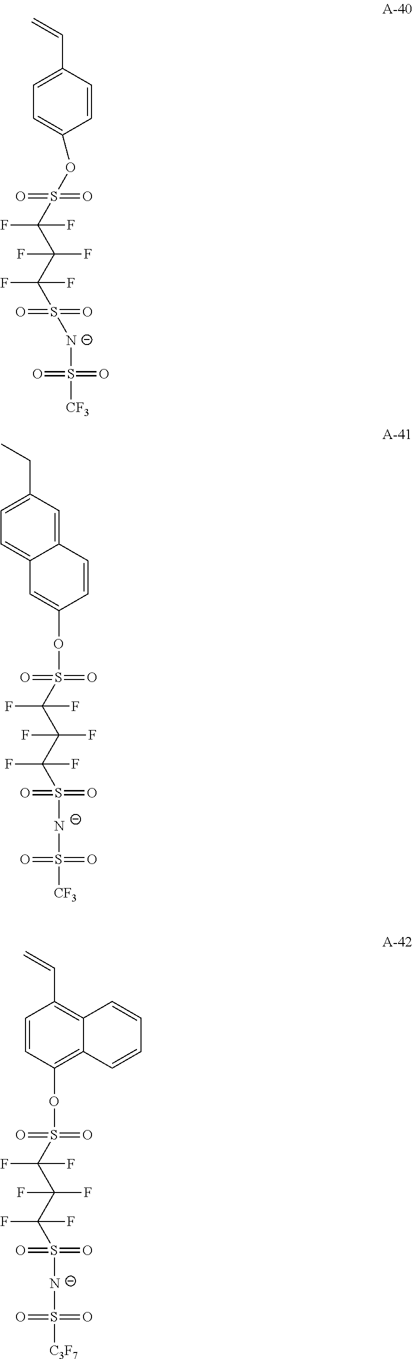

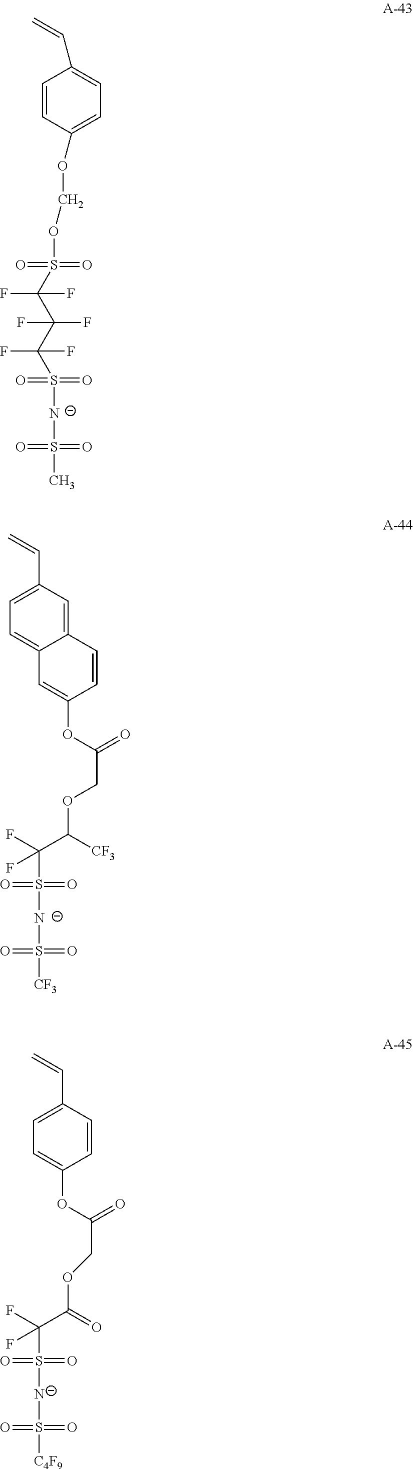

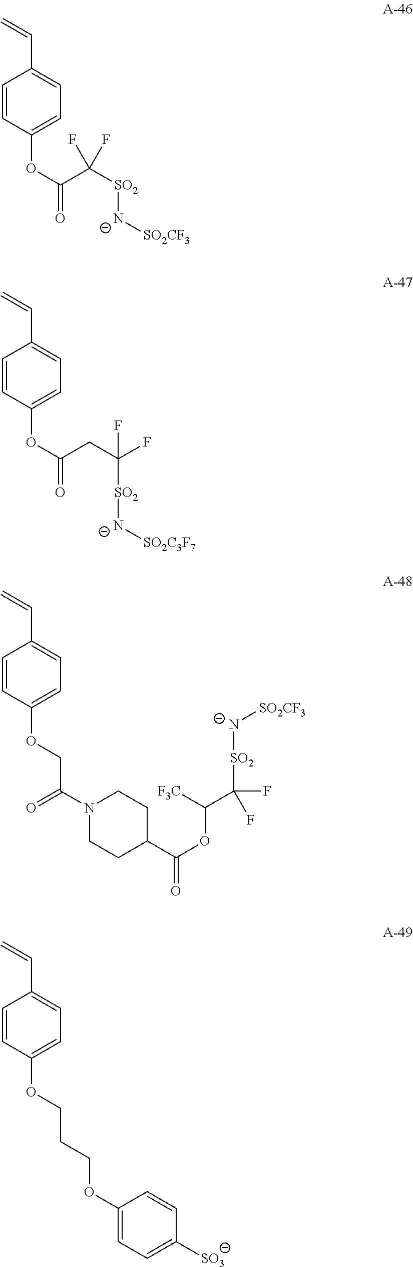

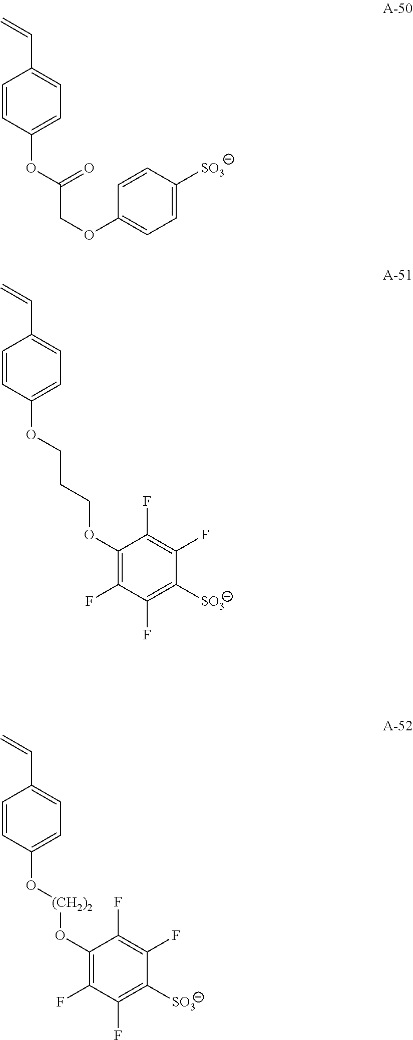

In Table 1 below, specific examples of the monomer corresponding to the repeating unit (A) are shown as the combination of a cation structure ((Z-1) to (Z-61) exemplified above) and an anion structure ((A-1) to (A-52) exemplified above).

TABLE 1

| Repeating | Cation | Anion |
|---|---|---|
| Unit (A) | Structure | Structure |
| M-001 | Z-1 | A-1 |
| M-002 | Z-8 | A-1 |
| M-003 | Z-11 | A-1 |
| M-004 | Z-26 | A-1 |
| M-005 | Z-27 | A-1 |
| M-006 | Z-33 | A-1 |
| M-007 | Z-38 | A-1 |
| M-008 | Z-52 | A-1 |
| M-009 | Z-55 | A-1 |
| M-010 | Z-56 | A-1 |
| M-011 | Z-59 | A-1 |
| M-012 | Z-60 | A-1 |
| M-013 | Z-1 | A-2 |
| M-014 | Z-2 | A-2 |
| M-015 | Z-4 | A-2 |
| M-016 | Z-6 | A-2 |
| M-017 | Z-15 | A-2 |
| M-018 | Z-29 | A-2 |
| M-019 | Z-37 | A-2 |
| M-020 | Z-45 | A-2 |
| M-021 | Z-60 | A-2 |
| M-022 | Z-1 | A-3 |
| M-023 | Z-2 | A-3 |
| M-024 | Z-16 | A-3 |
| M-025 | Z-22 | A-3 |
| M-026 | Z-33 | A-3 |
| M-027 | Z-37 | A-3 |
| M-028 | Z-38 | A-3 |
| M-029 | Z-40 | A-3 |
| M-030 | 2-44 | A-3 |
| M-031 | Z-53 | A-3 |
| M-032 | Z-57 | A-3 |
| M-033 | Z-59 | A-3 |
| M-034 | Z-60 | A-3 |
| M-035 | Z-1 | A-4 |
| M-036 | Z-4 | A-4 |
| M-037 | Z-11 | A-4 |
| M-038 | Z-27 | A-4 |
| M-039 | Z-33 | A-4 |
| M-040 | Z-38 | A-4 |
| M-041 | Z-40 | A-4 |
| M-042 | Z-52 | A-4 |
| M-043 | Z-60 | A-4 |
| M-044 | Z-1 | A-5 |
| M-045 | Z-12 | A-5 |
| M-046 | Z-24 | A-5 |
| M-047 | Z-33 | A-5 |
| M-048 | Z-38 | A-5 |
| M-049 | Z-52 | A-5 |
| M-050 | Z-60 | A-5 |
| M-051 | Z-18 | A-6 |
| M-052 | Z-31 | A-6 |
| M-053 | Z-47 | A-6 |
| M-054 | Z-1 | A-7 |
| M-055 | Z-8 | A-7 |
| M-056 | Z-23 | A-7 |
| M-057 | Z-38 | A-7 |
| M-058 | Z-55 | A-7 |
| M-059 | Z-1 | A-8 |
| M-060 | Z-3 | A-8 |
| M-061 | Z-16 | A-8 |
| M-062 | Z-28 | A-8 |
| M-063 | Z-1 | A-9 |
| M-064 | Z-6 | A-9 |
| M-065 | Z-32 | A-9 |
| M-066 | Z-46 | A-9 |
| M-067 | Z-1 | A-10 |
| M-068 | Z-2 | A-10 |
| M-069 | Z-12 | A-10 |
| M-070 | Z-27 | A-10 |
| M-071 | Z-38 | A-10 |
| M-072 | Z-39 | A-10 |
| M-073 | Z-59 | A-10 |
| M-074 | Z-60 | A-10 |
| M-075 | Z-1 | A-11 |
| M-076 | Z-19 | A-11 |
| M-077 | Z-4 | A-12 |
| M-078 | Z-49 | A-12 |
| M-079 | Z-7 | A-13 |
| M-080 | Z-33 | A-13 |
| M-081 | Z-41 | A-13 |
| M-082 | Z-9 | A-14 |
| M-083 | Z-48 | A-14 |
| M-084 | Z-13 | A-15 |
| M-085 | Z-29 | A-15 |
| M-086 | Z-23 | A-16 |
| M-087 | Z-36 | A-16 |
| M-088 | Z-1 | A-17 |
| M-089 | Z-26 | A-17 |
| M-090 | Z-2 | A-18 |
| M-091 | Z-43 | A-18 |
| M-092 | Z-4 | A-19 |
| M-093 | Z-32 | A-19 |
| M-094 | Z-57 | A-19 |
| M-095 | Z-1 | A-20 |
| M-096 | Z-25 | A-20 |
| M-097 | Z-5 | A-21 |
| M-098 | Z-49 | A-21 |
| M-099 | Z-8 | A-22 |
| M-100 | Z-29 | A-22 |
| M-101 | Z-43 | A-22 |
| M-102 | Z-59 | A-22 |
| M-103 | Z-1 | A-23 |
| M-104 | Z-11 | A-23 |
| M-105 | Z-2 | A-24 |
| M-106 | Z-24 | A-24 |
| M-107 | Z-1 | A-25 |
| M-108 | Z-2 | A-26 |
| M-109 | Z-47 | A-26 |
| M-110 | Z-7 | A-27 |
| M-111 | Z-33 | A-27 |
| M-112 | Z-1 | A-28 |
| M-113 | Z-2 | A-28 |
| M-114 | Z-4 | A-28 |
| M-115 | Z-27 | A-28 |
| M-116 | Z-38 | A-28 |
| M-117 | Z-39 | A-28 |
| M-118 | Z-52 | A-28 |
| M-119 | Z-60 | A-28 |
| M-120 | Z-7 | A-29 |
| M-121 | Z-23 | A-29 |
| M-122 | Z-55 | A-29 |
| M-123 | Z-1 | A-30 |
| M-124 | Z-13 | A-30 |
| M-125 | Z-28 | A-30 |
| M-126 | Z-4 | A-31 |
| M-127 | Z-26 | A-31 |
| M-128 | Z-37 | A-31 |
| M-129 | Z-1 | A-32 |
| M-130 | Z-23 | A-32 |
| M-131 | Z-38 | A-32 |
| M-132 | Z-46 | A-32 |
| M-133 | Z-1 | A-33 |
| M-134 | Z-22 | A-33 |
| M-135 | Z-30 | A-33 |
| M-136 | Z-52 | A-33 |
| M-137 | Z-2 | A-34 |
| M-138 | Z-12 | A-34 |
| M-139 | Z-5 | A-35 |
| M-140 | Z-34 | A-35 |
| M-141 | Z-1 | A-36 |
| M-142 | Z-11 | A-36 |
| M-143 | Z-45 | A-36 |
| M-144 | Z-53 | A-36 |
| M-145 | Z-60 | A-36 |
| M-146 | Z-1 | A-37 |
| M-147 | Z-20 | A-37 |
| M-148 | Z-38 | A-37 |
| M-149 | Z-59 | A-37 |
| M-150 | Z-3 | A-38 |
| M-151 | Z-25 | A-38 |
| M-152 | Z-51 | A-38 |
| M-153 | Z-8 | A-39 |
| M-154 | Z-18 | A-39 |
| M-155 | Z-1 | A-40 |
| M-156 | Z-8 | A-40 |
| M-157 | Z-11 | A-40 |
| M-158 | Z-24 | A-40 |
| M-159 | Z-33 | A-40 |
| M-160 | Z-38 | A-40 |
| M-161 | Z-39 | A-40 |
| M-162 | Z-51 | A-40 |
| M-163 | Z-52 | A-40 |
| M-164 | Z-57 | A-40 |
| M-165 | Z-59 | A-40 |
| M-166 | Z-60 | A-40 |
| M-167 | Z-1 | A-41 |
| M-168 | Z-2 | A-41 |
| M-169 | Z-26 | A-41 |
| M-170 | Z-39 | A-41 |
| M-171 | Z-59 | A-41 |
| M-172 | Z-60 | A-41 |
| M-173 | Z-1 | A-42 |
| M-174 | Z-10 | A-42 |
| M-175 | Z-27 | A-42 |
| M-176 | Z-59 | A-42 |
| M-177 | Z-1 | A-43 |
| M-178 | Z-21 | A-43 |
| M-179 | Z-37 | A-43 |
| M-180 | Z-47 | A-43 |
| M-181 | Z-2 | A-44 |
| M-182 | Z-28 | A-44 |
| M-183 | Z-40 | A-44 |
| M-184 | Z-52 | A-44 |
| M-185 | Z-1 | A-45 |
| M-186 | Z-14 | A-45 |
| M-187 | Z-22 | A-45 |
| M-188 | Z-38 | A-45 |
| M-189 | Z-46 | A-45 |
| M-190 | Z-1 | A-46 |
| M-191 | Z-27 | A-46 |
| M-192 | Z-29 | A-46 |
| M-193 | Z-43 | A-46 |
| M-194 | Z-53 | A-46 |
| M-195 | Z-1 | A-47 |
| M-196 | Z-11 | A-47 |
| M-197 | Z-32 | A-47 |
| M-198 | Z-58 | A-47 |
| M-199 | Z-2 | A-48 |
| M-200 | Z-60 | A-48 |
| M-201 | Z-1 | A-49 |
| M-202 | Z-6 | A-49 |
| M-203 | Z-33 | A-49 |
| M-204 | Z-52 | A-49 |
| M-205 | Z-60 | A-49 |
| M-206 | Z-1 | A-50 |
| M-207 | Z-3 | A-50 |
| M-208 | Z-8 | A-50 |
| M-209 | Z-59 | A-50 |
| M-210 | Z-61 | A-50 |
| M-211 | Z-1 | A-51 |
| M-212 | Z-2 | A-51 |
| M-213 | Z-20 | A-51 |
| M-214 | Z-52 | A-51 |
| M-215 | Z-59 | A-51 |
| M-216 | Z-60 | A-51 |
| M-217 | Z-1 | A-52 |
| M-218 | Z-4 | A-52 |
| M-219 | Z-28 | A-52 |
| M-220 | Z-52 | A-52 |
| M-221 | Z-60 | A-52 |

The content of the repeating unit (A) in the resin (P) is preferably from 0.5 to 80 mol %, more preferably from 1 to 60 mol %, still more preferably from 3 to 40 mol/%, based on all repeating units in the resin (P).

### [Repeating Unit (C)]

The repeating unit (C) is a repeating unit represented by the following formula (I):

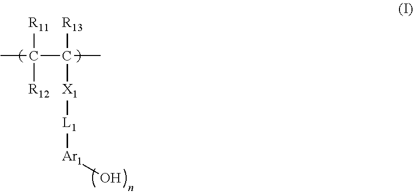

In formula (I), each of R₁₁, R₁₂ and R₁₃ independently represents a hydrogen atom, an alkyl group, a cycloalkyl group, a halogen atom, a cyano group or an alkoxycarbonyl group. R₁₂ may combine with Ar₁ to form a ring and in this case, R₁₂ represents an alkylene group.

X₁ represents a single bond, —COO— or —CONR₁₄—, wherein R₁₄ represents a hydrogen atom or an alkyl group.

L₁ represents a single bond or an alkylene group.

Ar₁ represents a (n+1)-valent aromatic ring group, provided that when Ar₁ combines with R₁₂, Ar₁ represents a (n+2)-valent aromatic ring group.

n represents an integer of 1 or more.

The alkyl group as R₁₁ to R₁₃ is, for example, an alkyl group having a carbon number of 20 or less and is preferably a methyl group, an ethyl group, a propyl group, an isopropyl group, an n-butyl group, a sec-butyl group, a hexyl group, a 2-ethylhexyl group, an octyl group or a dodecyl group. The alkyl group is more preferably an alkyl group having a carbon number of 8 or less. These alkyl groups may have a substituent.

As for the alkyl group contained in the alkoxycarbonyl group, the same as those for the alkyl group in R₁₁ to R₁₃ are preferred.

The cycloalkyl group may be a monocyclic cycloalkyl group or a polycyclic cycloalkyl group and is preferably a monocyclic cycloalkyl group having a carbon number of 3 to 8, such as cyclopropyl group, cyclopentyl group and cyclohexyl group. These cycloalkyl groups may have a substituent.

The halogen atom includes a fluorine atom, a chlorine atom, a bromine atom and an iodine atom and is preferably a fluorine atom.

In the case where R₁₂ represents an alkylene group, the alkylene group is preferably an alkylene group having a carbon number of 1 to 8, such as methylene group, ethylene group, propylene group, butylene group, hexylene group and octylene group.

Each of R₁₁, R₁₂ and R₁₃ independently preferably represents a hydrogen atom or an alkyl group, more preferably a hydrogen atom.

X₁ represents a single bond, —COO— or —CONR₁₄—, wherein R₁₄ represents a hydrogen atom or an alkyl group.

Examples of the alkyl group of R₁₄ are the same as those of the alkyl group of R₁₁ to R₁₃, and the preferred range is also the same

X₁ most preferably represents a single bond.

L₁ represents a single bond or an alkylene group.

The alkylene group as L₁ is preferably a linear or branched alkylene group having a carbon number of 1 to 20, more preferably a carbon number of 1 to 10, and examples thereof include a methylene group, an ethylene group and a propylene group.

L₁ most preferably represents a single bond.

Ar₁ represents a (n+1)-valent aromatic ring group, provided that when Ar₁ combines with R₁₂, Ar₁, represents a (n+2)-valent aromatic ring group.

The divalent aromatic ring group represented by Ar₁ when n is 1 is the same as the divalent aromatic ring group represented by Ar₄ when q is 1 in formula (IV), and the preferred range is also the same.

The (n+1)-valent aromatic ring group represented by Ar₁ in formula (I) may have a substituent. Examples of the substituent are the same as those of the substituent which may be substituted on the (q+1)-valent aromatic ring group represented by Ar₄ in formula (IV), and preferred ranges are also the same.

Specific examples of the (n+1)-valent aromatic ring group represented by Ar₁ when n is an integer of 2 or more include a group formed by removing arbitrary (n−1) hydrogen atoms from the divalent aromatic ring group above.

n represents an integer of 1 or more. n preferably represents an integer of 1 to 5, more preferably 1 or 2, and most preferably 1.

In the repeating unit represented by formula (I), when Ar₁ is a phenylene group, the bonding position of —OH to the benzene ring of Ar₁ may be a para-position, a meta-position or an ortho-position with respect to the bonding position of the benzene ring to L₁ or X₁ (when both L₁ and X₁ are a single bond, to the polymer main chain) but is preferably a para-position or a meta-position, most preferably a para-position.

From the standpoint of satisfying both sensitivity and resolution, the repeating unit (C) is preferably a repeating unit represented by the following formula (II):

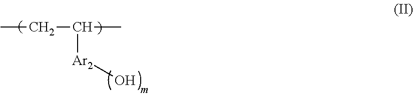

In formula (II), Ar₂ represents a (m+1)-valent aromatic ring group.

m represents an integer of 1 or more.

Ar₂ represents a (m+1)-valent aromatic ring group.

The divalent aromatic ring group represented by Ar₂ when m is 1 is the same as the divalent aromatic ring group represented by Ar₄ when q is 1 in formula (IV), and the preferred range is also the same.

The (m+1)-valent aromatic ring group represented by Ar₂ in formula (II) may have a substituent. Examples of the substituent are the same as those of the substituent which may be substituted on the (q+1)-valent aromatic ring group represented by Ar₄ in formula (IV), and preferred ranges are also the same.

Specific examples of the (m+1)-valent aromatic ring group represented by Ar₂ when m is an integer of 2 or more include a group formed by removing arbitrary (m−1) hydrogen atoms from the divalent aromatic ring group above.

m represents an integer of 1 or more. m preferably represents an integer of 1 to 5, more preferably 1 or 2, and most preferably 1.

In the repeating unit represented by formula (II), when Ar₂ is a phenylene group, the bonding position of —OH to the benzene ring of Ar₂ may be a para-position, a meta-position or an ortho-position with respect to the bonding position of the benzene ring to the polymer main chain but is preferably a para-position or a meta-position, most preferably a para-position.

The repeating unit (C) is a repeating unit having an alkali-soluble group and has a function of controlling the alkali developability of the resist.

Specific examples of the repeating unit (C) are illustrated below, but the present invention is not limited thereto.

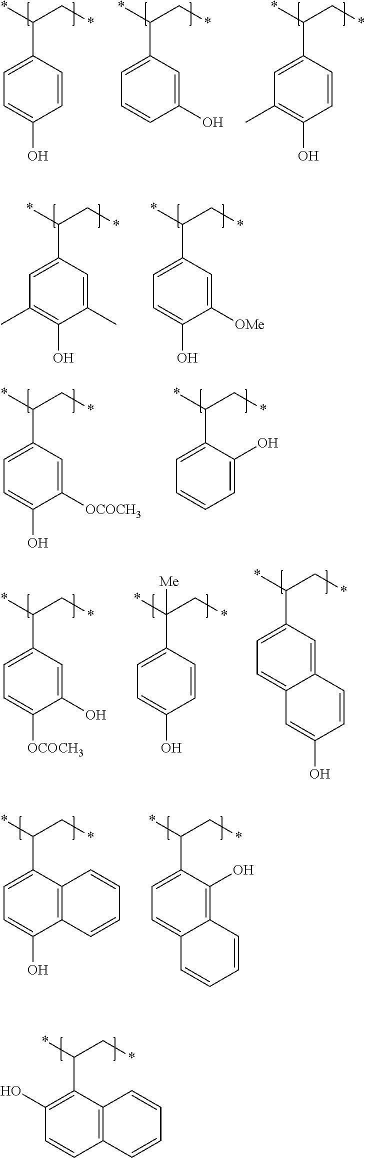

Among these, preferred examples of the repeating unit (C) are a repeating unit where the aromatic ring group represented by Ar₁ or Ar₂ is an unsubstituted phenylene group, and include the repeating units illustrated below.

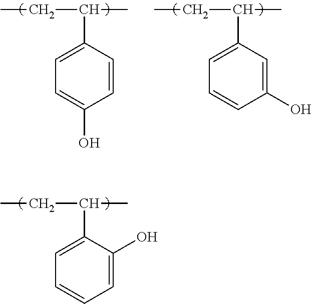

The content of the repeating unit (C) in the resin (P) is preferably from 3 to 98 mol %, more preferably from 10 to 80 mol %, still more preferably from 25 to 70 mol %, based on all repeating units in the resin (P).

### [Repeating Unit (B)]

The repeating unit (P) preferably further contains (B) a repeating unit capable of decomposing by the action of an acid to generate an alkali-soluble group.

More specifically, the repeating unit (B) is preferably a repeating unit represented by the following formula (III):

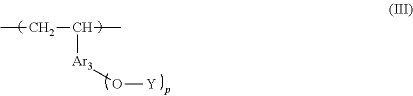

In formula (III), Ar₃ represents a (p+1)-valent aromatic ring group.

Y represents a hydrogen atom or a group capable of leaving by the action of an acid, and when a plurality of Y's are present, each Y may be the same as or different from every other Y, provided that at least one Y represents a group capable of leaving by the action of an acid.

p represents an integer of 1 or more.

Ar₃ represents a (p+1)-valent aromatic ring group.

The divalent aromatic ring group represented by Ar₃ when p is 1 is the same as the divalent aromatic ring group represented by Ar₄ when q is 1 in formula (IV), and the preferred range is also the same.

The (p+1)-valent aromatic ring group represented by Ar₃ in formula (III) may have a substituent. Examples of the substituent are the same as those of the substituent which may be substituted on the (q+1)-valent aromatic ring group represented by Ar₄ in formula (IV), and preferred ranges are also the same.

Specific examples of the (p+1)-valent aromatic ring group represented by Ar₃ when p is an integer of 2 or more include a group formed by removing arbitrary (p−1) hydrogen atoms from the divalent aromatic ring group above.

p represents an integer of 1 or more. p preferably represents an integer of 1 to 5, more preferably 1 or 2, and most preferably 1.

In the repeating unit represented by formula (III), when Ar₃ is a phenylene group, the bonding position of the group represented by —O—Y to the benzene ring of Ar₃ may be a para-position, a meta-position or an ortho-position with respect to the bonding position of the benzene ring to the polymer main chain but is preferably a para-position or a meta-position, most preferably a para-position.

Examples of the group Y capable of leaving by the action of an acid include groups represented by —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—(═O)—O—C(R₃₆)(R₃₇)(R₃₈), and —CH(R₃₆)(Ar).

In the formulae above, each of R₃₆ to R₃₉ independently represents an alkyl group, a cycloalkyl group, an aryl group, an aralkyl group or an alkenyl group, and R₃₆ and R₃₇ may combine with each other to form a ring structure.

Each of R₀₁ and R₀₂ independently represents a hydrogen atom, an alkyl group, a cycloalkyl group, an aryl group, an aralkyl group or an alkenyl group.

Ar represents an aryl group.

The alkyl group as R₃₆ to R₃₉, R₀₁ and R₀₂ is preferably an alkyl group having a carbon number of 1 to 8, and examples thereof include a methyl group, an ethyl group, a propyl group, an n-butyl group, a sec-butyl group, a hexyl group, and an octyl group.

The cycloalkyl group as R₃₆ to R₃₉, R₀₁ and R₀₂ may be monocyclic cycloalkyl group or a polycyclic cycloalkyl group. The monocyclic cycloalkyl group is preferably a cycloalkyl group having a carbon number of 3 to 8, and examples thereof include a cyclopropyl group, a cyclobutyl group, a cyclopentyl group, a cyclohexyl group and a cyclooctyl group. The polycyclic cycloalkyl group is preferably a cycloalkyl group having a carbon number of 6 to 20, and examples thereof include an adamantyl group, a norbornyl group, an isoboronyl group, a camphanyl group, a dicyclopentyl group, an α-pinel group, a tricyclodecanyl group, a tetracyclododecyl group and an androstanyl group. Incidentally, a part of carbon atoms in the cycloalkyl group may be replaced by a heteroatom such as oxygen atom.

The aryl group as R₃₆ to R₃₉, R₀₁, R₀₂ and Ar is preferably an aryl group having a carbon number of 6 to 10, and examples thereof include a phenyl group, a naphthyl group and an anthryl group.

The aralkyl group as R₃₆ to R₃₉, R₀₁ and R₀₂ is preferably an aralkyl group having a carbon number of 7 to 12 and is preferably, for example, a benzyl group, a phenethyl group or a naphthylmethyl group.

The alkenyl group as R₃₆ to R₃₉, R₀₁ and R₀₂ is preferably an alkenyl group having a carbon number of 2 to 8, and examples thereof include a vinyl group, an allyl group, a butenyl group and a cyclohexenyl group.

The ring formed by combining R₃₆ and R₃₇ with each other may be monocyclic or polycyclic. The monocyclic structure is preferably a cycloalkane structure having a carbon number of 3 to 8, and examples thereof include a cyclopropane structure, a cyclobutane structure, a cyclopentane structure, a cyclohexane structure, a cycloheptane structure and a cyclooctane structure. The polycyclic structure is preferably a cycloalkane structure having a carbon number of 6 to 20, and examples thereof include an adamantane structure, a norbornane structure, a dicyclopentane structure, a tricyclodecane structure and a tetracyclododecane structure. Incidentally, a part of carbon atoms in the ring structure may be replaced by a heteroatom such as oxygen atom.

Each of these groups may have a substituent. Examples of the substituent include an alkyl group, a cycloalkyl group, an aryl group, an amino group, an amido group, a ureido group, a urethane ring, a hydroxyl group, a carboxy group, a halogen atom, an alkoxy group, a thioether group, an acyl group, an acyloxy group, an alkoxycarbonyl group, a cyano group, and a nitro group. The carbon number of the substituent is preferably 8 or less.

The group Y capable of leaving by the action of an acid is more preferably a structure represented by the following formula (V):

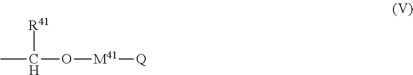

In formula (V), R⁴¹ represents a hydrogen atom, an alkyl group, a cycloalkyl group, an aryl group or an aralkyl group.

M⁴¹ represents a single bond or a divalent linking group.

Q represents an alkyl group, an alicyclic group which may contain a heteroatom, or an aromatic ring group which may contain a heteroatom.

Incidentally, at least two members of R⁴¹, M⁴¹ and Q may combine with each other to form a ring. The ring is preferably a 5- or 6-membered ring.

The alkyl group as R⁴¹ is, for example, an alkyl group having a carbon number of 1 to 8 and is preferably a methyl group, an ethyl group, a propyl group, an isopropyl group, an n-butyl group, a sec-butyl group, a tert-butyl group, a hexyl group or an octyl group.

The alkyl group as R⁴¹ may have a substituent, and examples thereof include a cyano group, a halogen atom, a hydroxyl group, an alkoxy group, a carboxyl group, an alkoxycarbonyl group and a cycloalkyl group.

The cycloalkyl group as R⁴¹ is, for example, a cycloalkyl group having a carbon number of 3 to 15 and is preferably a cyclohexyl group, a norbornyl group or an adamantyl group.

The aryl group as R⁴¹ is, for example, an aryl group having a carbon number of 6 to 15 and is preferably a phenyl group, a tolyl group, a naphthyl group or an anthryl group.

The aralkyl group as R⁴¹ is, for example, an aralkyl group having a carbon number of 6 to 20 and is preferably a benzyl group or a phenethyl group.

R⁴¹ is preferably a hydrogen atom, a methyl group, an isopropyl group, a tert-butyl group, a cyclohexyl group, an adamantyl group, a phenyl group or a benzyl group, more preferably a methyl group or an adamantyl group.

The divalent linking group as M⁴¹ is, for example, an alkylene group (preferably an alkylene group having a carbon number of 1 to 8, e.g., methylene, ethylene, propylene, butylene, hexylene, octylene), a cycloalkenylene group (preferably a cycloalkylene group having a carbon number of 3 to 15, e.g., cyclopentylene, cyclohexylene), —S—, —O—, —CO—, —CS—, —SO₂—, —N(R₀)—, or a combination of two or more thereof, and a linking group having a total carbon number of 20 or less is preferred. Here, R₀ is a hydrogen atom or an alkyl group (for example, an alkyl group having a carbon number of 1 to 8, and specific examples thereof include a methyl group, an ethyl group, a propyl group, an n-butyl group, a sec-butyl group, a hexyl group and an octyl group).

M⁴¹ is preferably a single bond, an alkylene group, or a divalent linking group composed of a combination of an alkylene group and at least one of —O—, —CO—, —CS— and —N(R₀)—, more preferably a single bond, an alkylene group, or a divalent linking group composed of a combination of an alkylene group and —O—. Here, R₀ has the same meaning as R₀ above.

The alkyl group as Q is, for example, the same as the above-described alkyl group of R⁴¹.

The alicyclic group and aromatic ring group as Q include, for example, the above-described cycloalkyl group and aryl group of R⁴¹. The carbon number thereof is preferably from 3 to 18. Incidentally, in the present invention, a group formed by combining plural aromatic rings through a single bond (for example, a biphenyl group and a terphenyl group) is also included in the aromatic group of Q.

Examples of the heteroatom-containing alicyclic group and heteroatom-containing aromatic ring group include thiirane, cyclothiolane, thiophene, furan, pyrrole, benzothiophene, benzofuran, benzopyrrole, triazine, imidazole, benzimidazole, triazole, thiadiazole, thiazole and pyrrolidone. Incidentally, in the present invention, a group formed by combining plural “heteroatom-containing aromatic rings” through a single bond (for example, a viologen group) is also included in the aromatic group of Q.

The alicyclic group and aromatic ring group as Q may have a substituent, and examples thereof include an alkyl group, a cycloalkyl group, a cyano group, a halogen atom, a hydroxyl group, an alkoxy group, a carboxyl group and an alkoxycarbonyl group. (-M⁴¹-Q) is preferably a methyl group, an ethyl group, a cyclohexyl group, a norbornyl group, an aryloxyethyl group, a cyclohexylethyl group or an arylethyl group.

Examples of the case where at least two members of R⁴¹, M⁴¹ and Q combine with each other to form a ring include a case where either M⁴¹ or Q combine with R⁴¹ to form a propylene group or a butylene group and thereby form a 5- or 6-membered ring containing oxygen atom.

Assuming that the total carbon number of R⁴¹, M⁴¹ and Q is denoted by Nc, when Nc is large, the change in alkali dissolution rate of the resin (P) between before and after leaving of the group represented by formula (V) becomes large, and the contrast of dissolution is advantageously enhanced. Nc is preferably from 4 to 30, more preferably from 7 to 25, still more preferably from 7 to 20. When Nc is 30 or less, the glass transition temperature of the resin (P) is kept from decreasing, and occurrence of a problem such that the exposure latitude (EL) of the resist is impaired or the residue after leaving of the group represented by formula (V) remains as a defect on the resist pattern is advantageously suppressed.

In view of dry etching resistance, at least one of R⁴¹, M⁴¹ and Q preferably has an alicyclic or aromatic ring. Here, the alicyclic group and the aromatic ring group are the same as, for example, the above-described alicyclic group and aromatic ring group of Q.

Specific examples of the repeating unit (B) are illustrated below, but the present invention is not limited thereto.

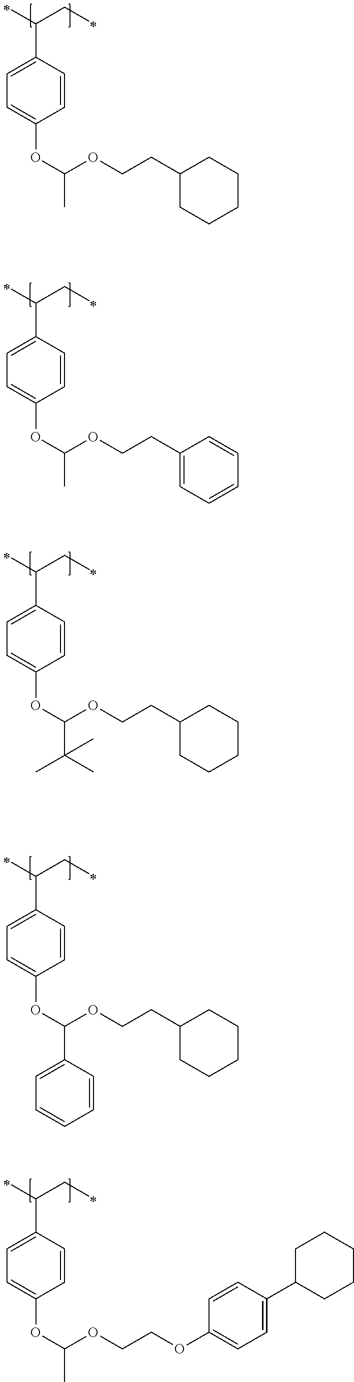

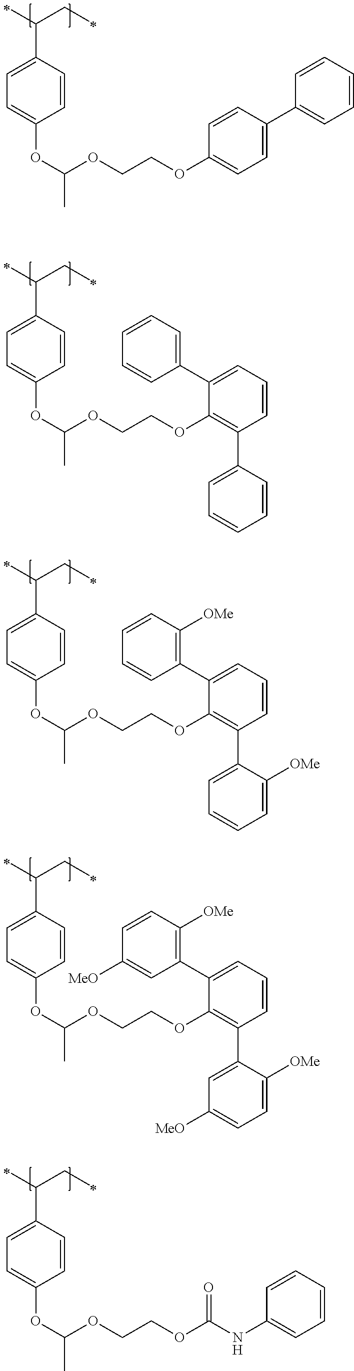

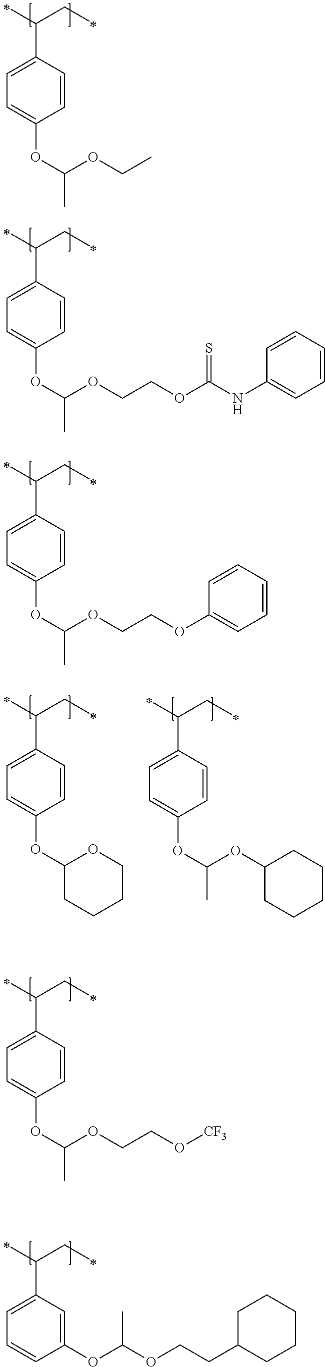

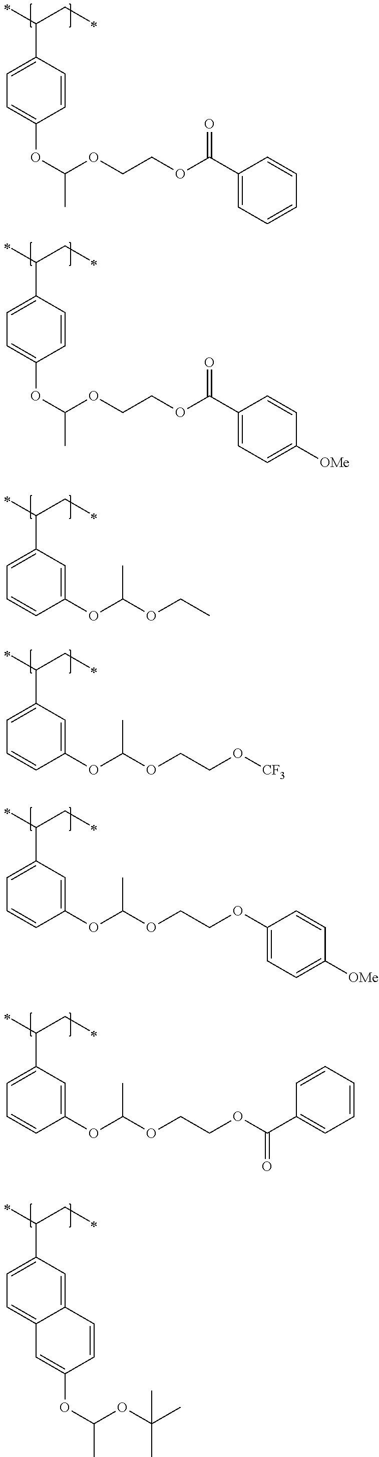

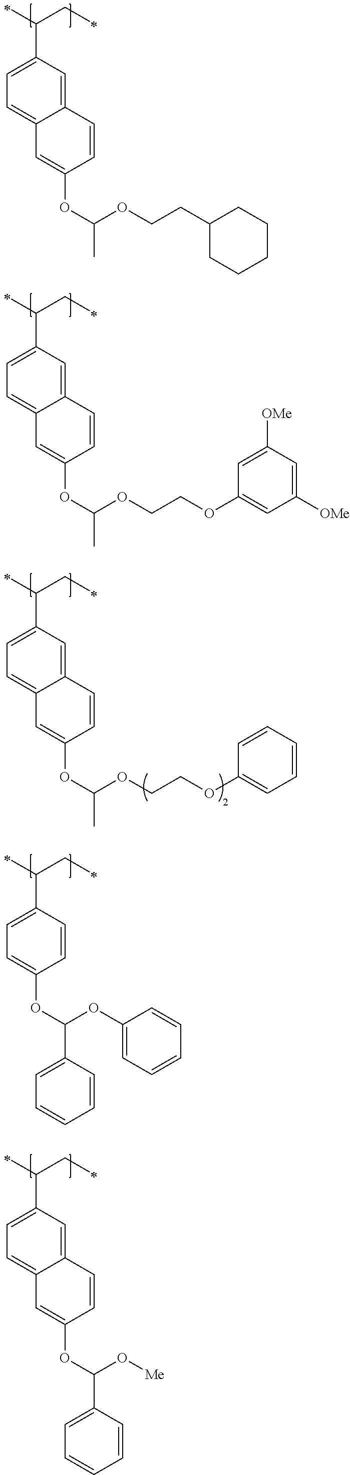

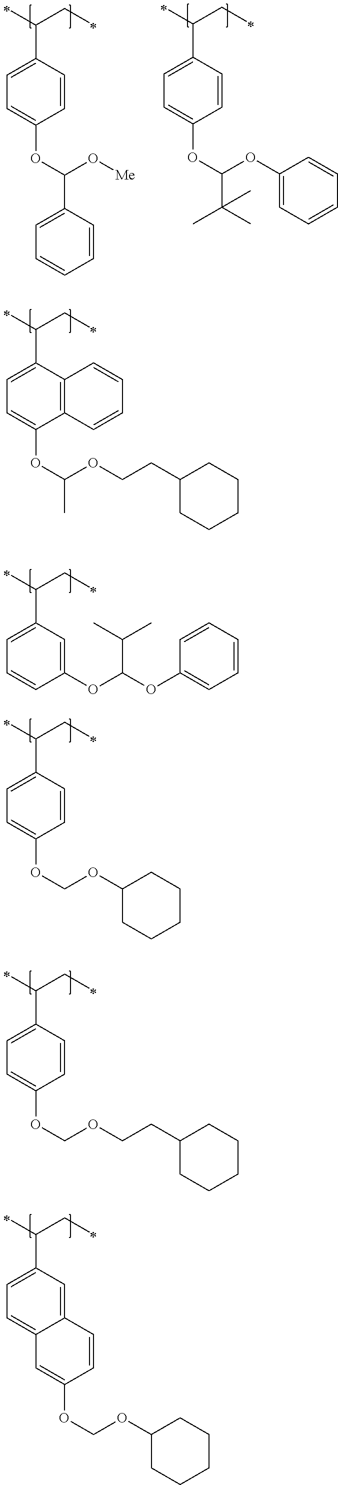

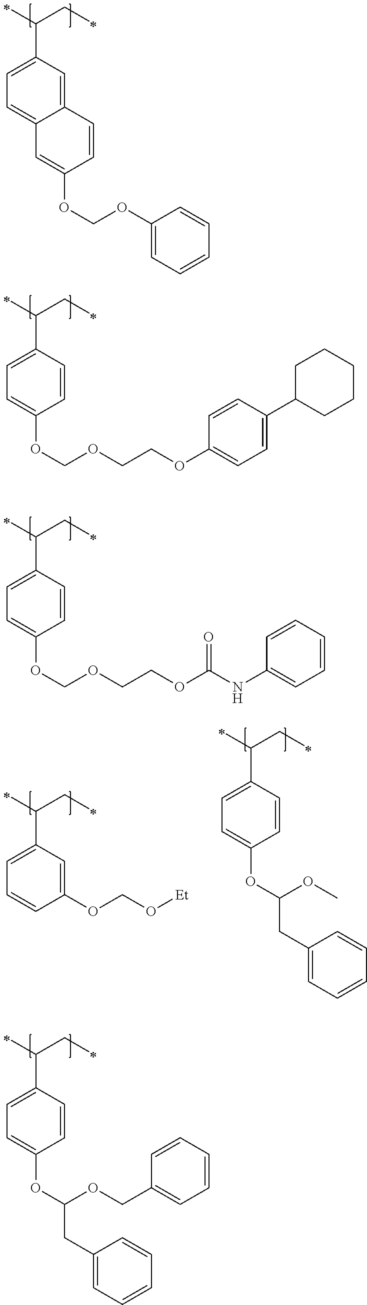

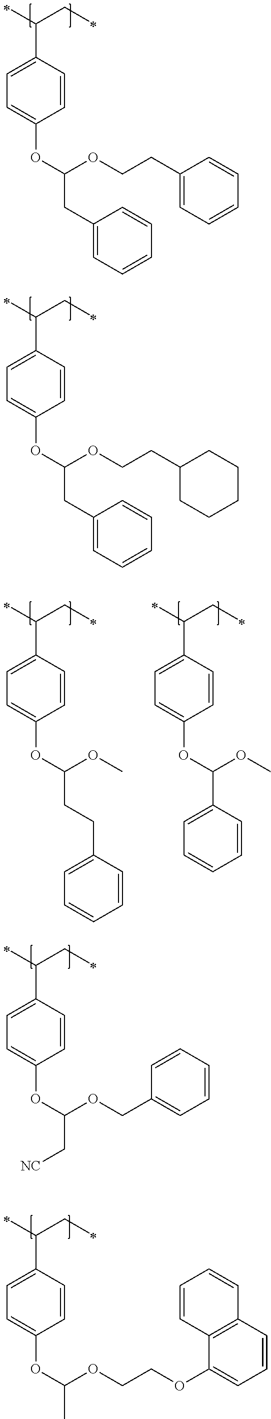

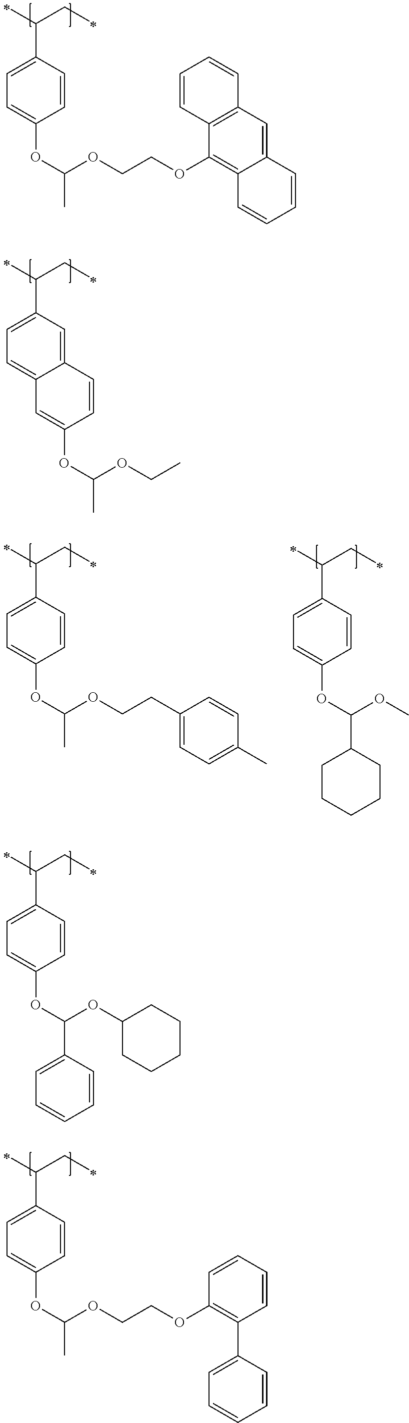

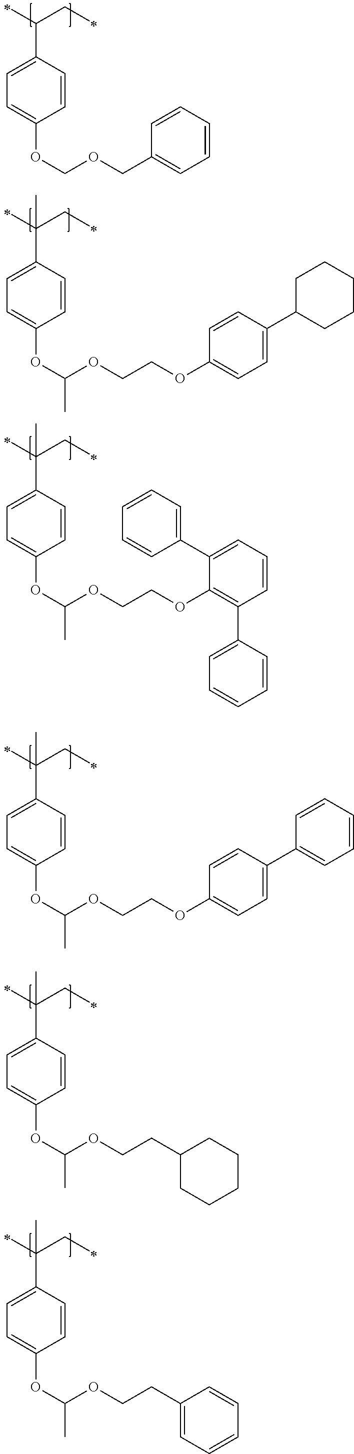

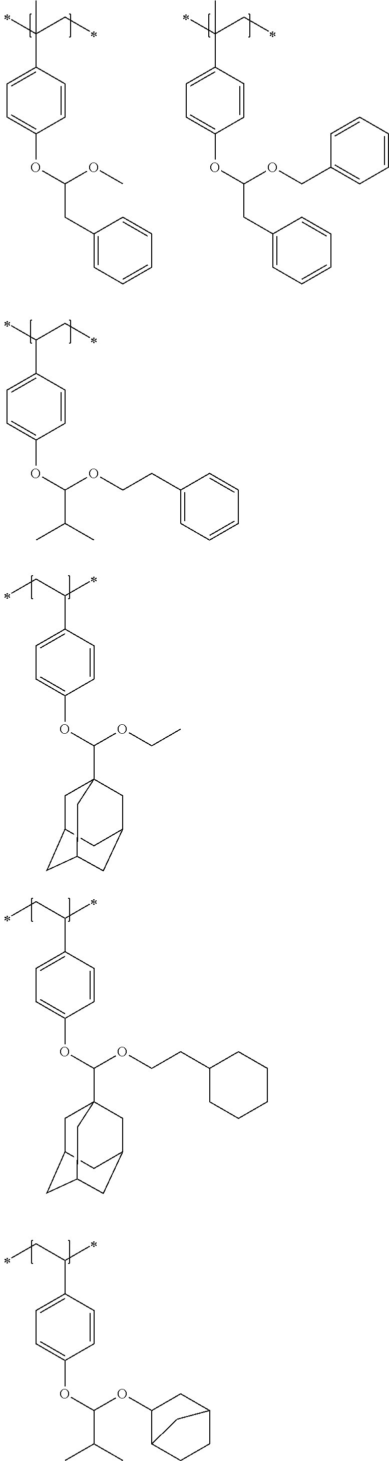

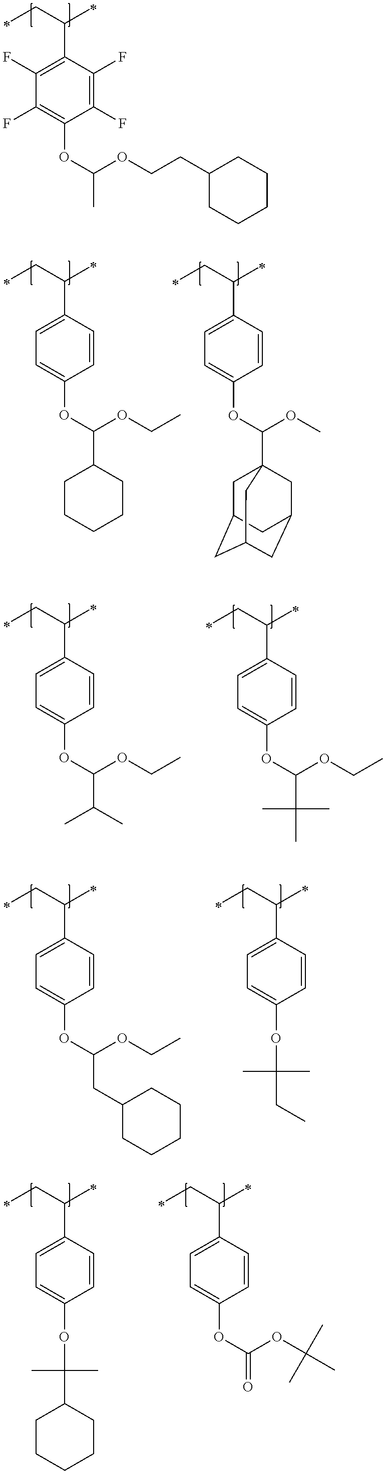

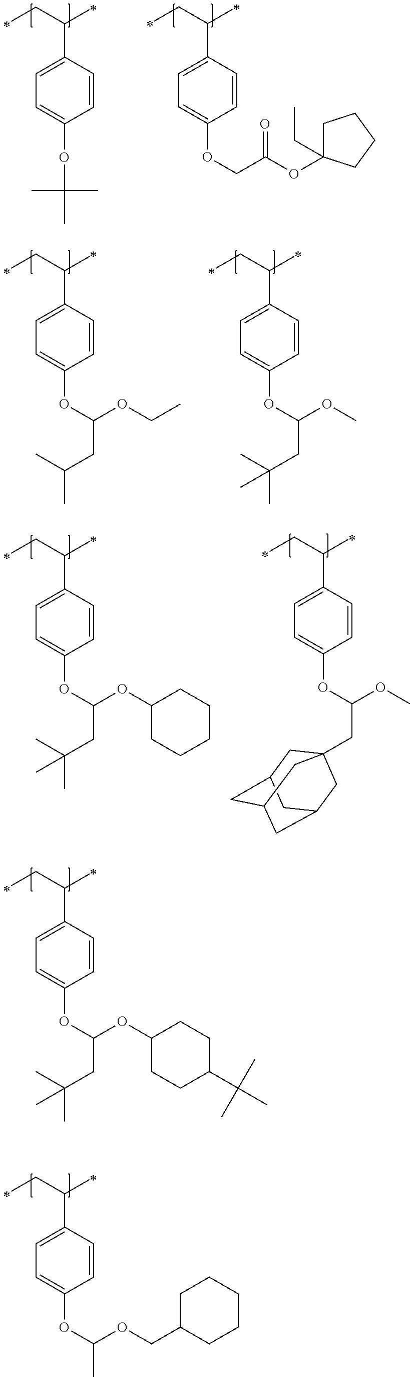

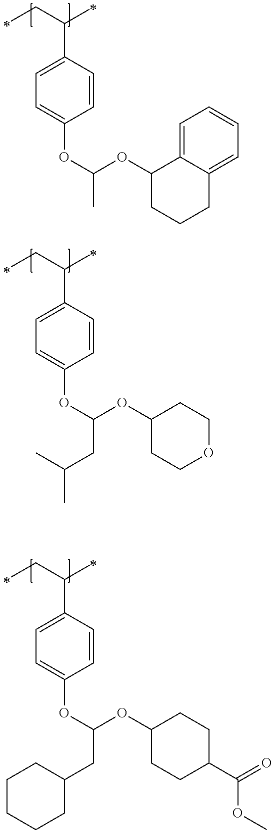

The resin (P) may or may not contain the repeating unit (B) but in the case of containing the repeating unit (B), the content thereof in the resin (P) is preferably from 1 to 80 mol %, more preferably from 10 to 70 mol %, still more preferably from 20 to 60 mol %, based on all repeating units in the resin (P).

It is also preferred that the resin (P) for use in the present invention further contains the following repeating units as a repeating unit other than the above-described repeating units (A) to (C).

The repeating unit includes, for example, a repeating unit having a group capable of decomposing by the action of an alkali developer to increase the dissolution rate in the alkali developer. Examples of the group above include a group having a lactone structure, and a group having a phenyl ester structure, and the repeating unit having a group capable of decomposing by the action of an alkali developer to increase the dissolution rate in the alkali developer is preferably a repeating unit represented by the following formula (AII):

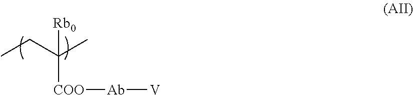

In formula (AII), V represents a group capable of decomposing by the action of an alkali developer to increase the dissolution rate in the alkali developer, Rb₀ represents a hydrogen atom or a methyl group, and Ab represents a single bond or a divalent organic group.

The group V capable of decomposing by the action of an alkali developer is a group having an ester bond and, among other, is preferably a group having a lactone structure. As for the group having a lactone structure, any group may be used as long as it has a lactone structure, but a 5- to 7-membered ring lactone structure is preferred, and a 5- to 7-membered ring lactone structure to which another ring structure is fused to form a bicyclo structure or a spiro structure is preferred.

Ab is preferably a single bond or a divalent linking group represented by -AZ—CO₂— (wherein AZ is an alkylene group or an aliphatic ring group (preferably a cycloalkylene group)). AZ is preferably a methylene group, an ethylene group, a cyclohexylene group, an adamantylene group or a norbornylene group.

Specific examples are illustrated below. In the formulae, Rx represents H or CH₃.

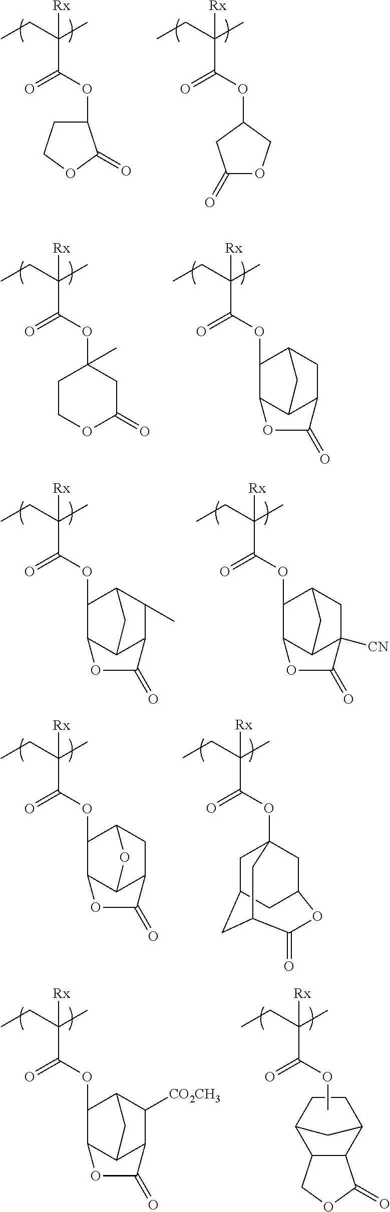

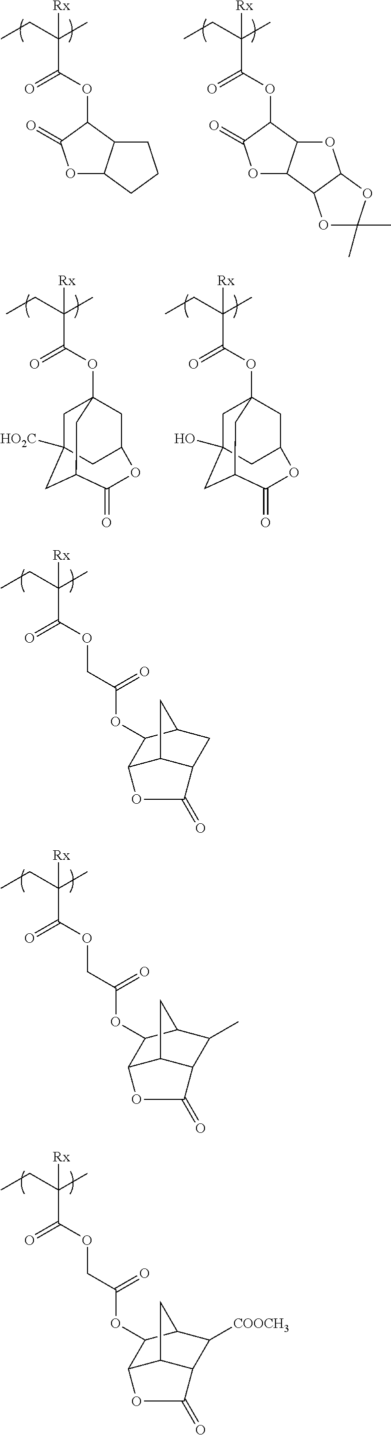

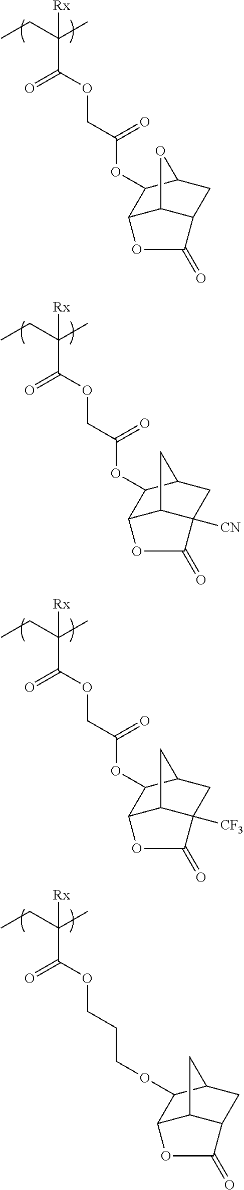

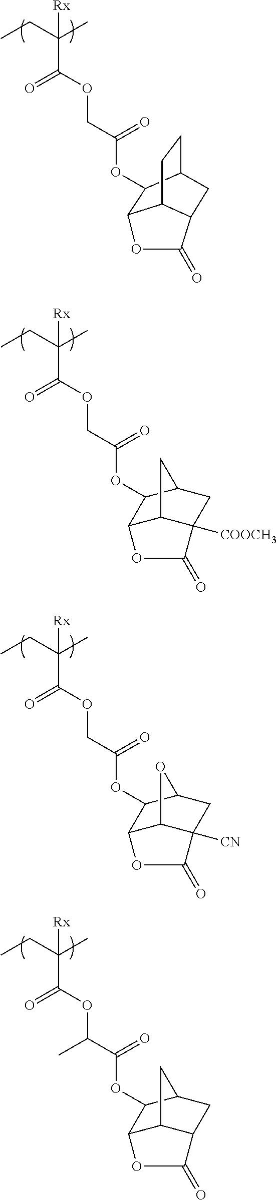

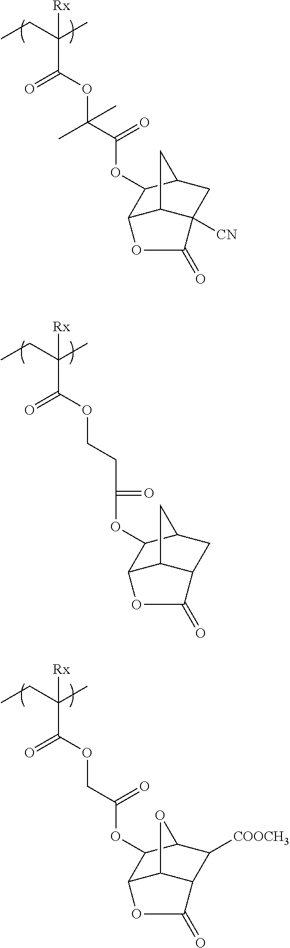

The resin (P) may or may not contain a repeating unit having a group capable of decomposing by the action of an alkali developer to increase the dissolution rate in the alkali developer, but in the case of containing the repeating unit having the group, the content thereof is preferably from 5 to 60 mol %, more preferably from 5 to 50 mol %, still more preferably from 10 to 50 mol %/o, based on all repeating units in the resin (P).

Examples of the polymerizable monomer for forming the repeating unit other than those described above in the resin (P) for use in the present invention include a styrene, an alkyl-substituted styrene, an alkoxy-substituted styrene, an O-alkylated styrene, an O-acylated styrene, a hydrogenated hydroxystyrene, a maleic anhydride, an acrylic acid derivative (e.g., acrylic acid, acrylic acid ester), a methacrylic acid derivative (e.g., methacrylic acid, methacrylic acid ester), an N-substituted maleimide, an acrylonitrile, a methacrylonitrile, a vinylnaphthalene, a vinylanthracene, and an indene which may have a substituent. Preferred examples of the substituted styrene include 4-(1-naphthylmethoxy)styrene, 4-benzyloxystyrene, 4-(4-chlorobenzyloxy)styrene, 3-(1-naphthylmethoxy)styrene, 3-benzyloxystyrene, and 3-(4-chlorobenzyloxy)styrene.

The resin (P) may or may not contain such a repeating unit, but in the case of containing such a repeating unit, the content thereof in the resin (P) is preferably from 1 to 80 mol %, more preferably from 5 to 50 mol %, based on all repeating units constituting the resin (P).

Specific examples of the resin (P) for use in the present invention is illustrated below, but the present invention is not limited thereto.

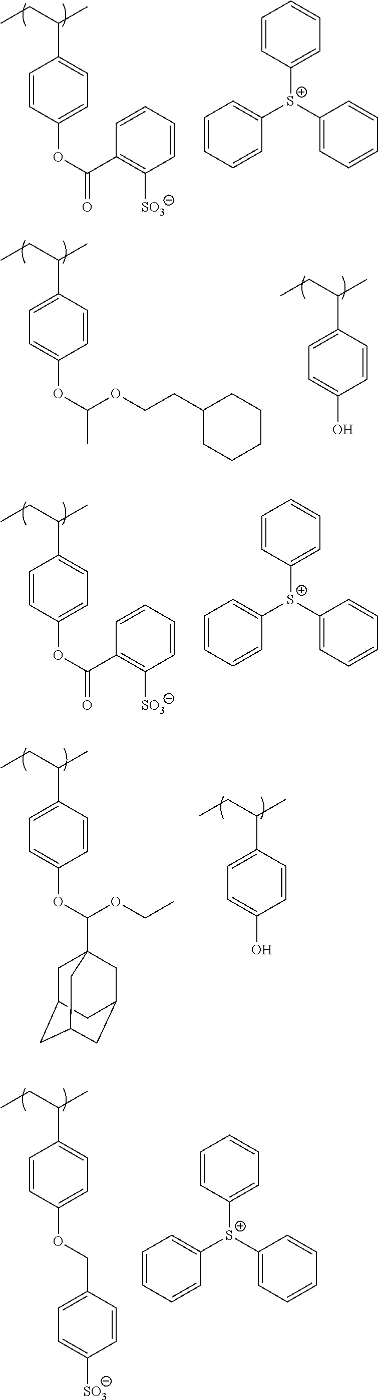

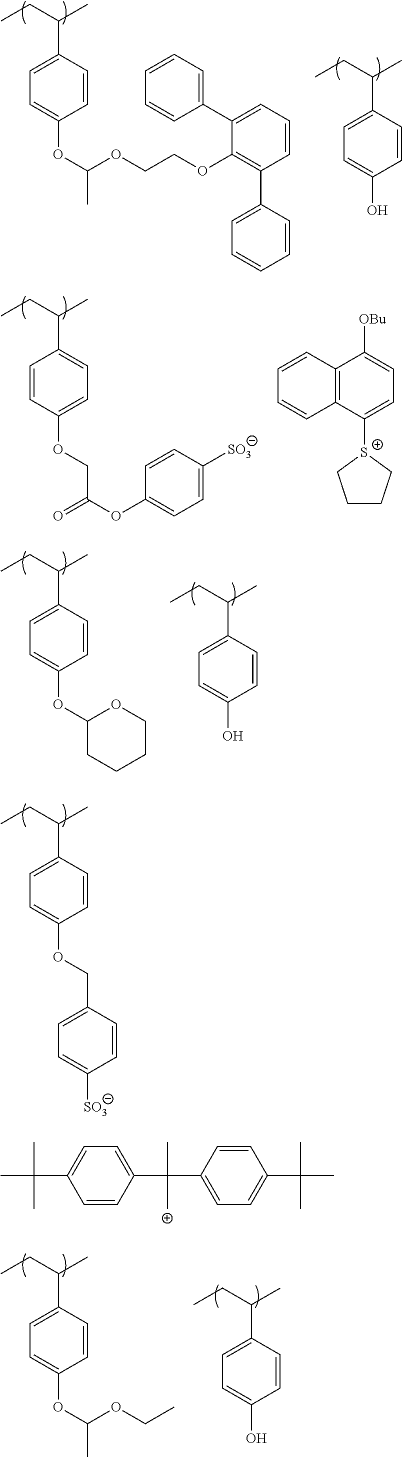

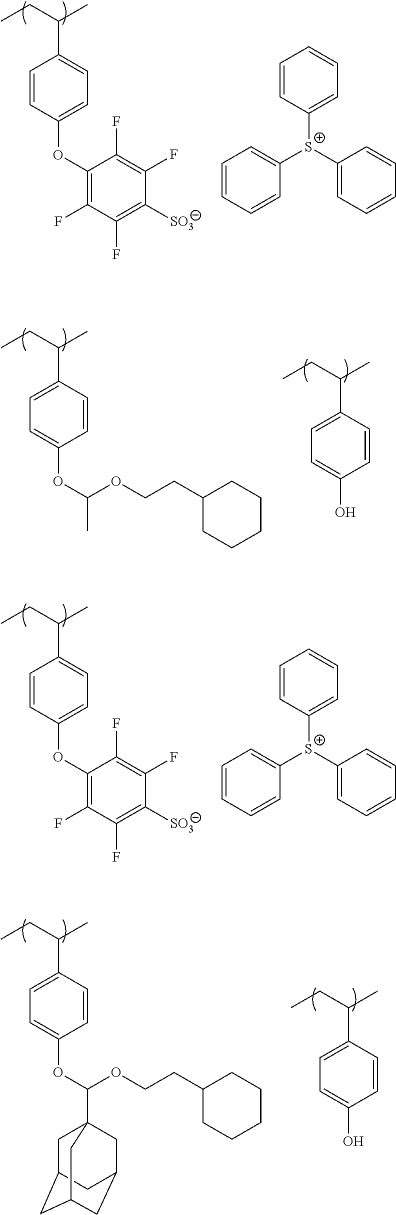

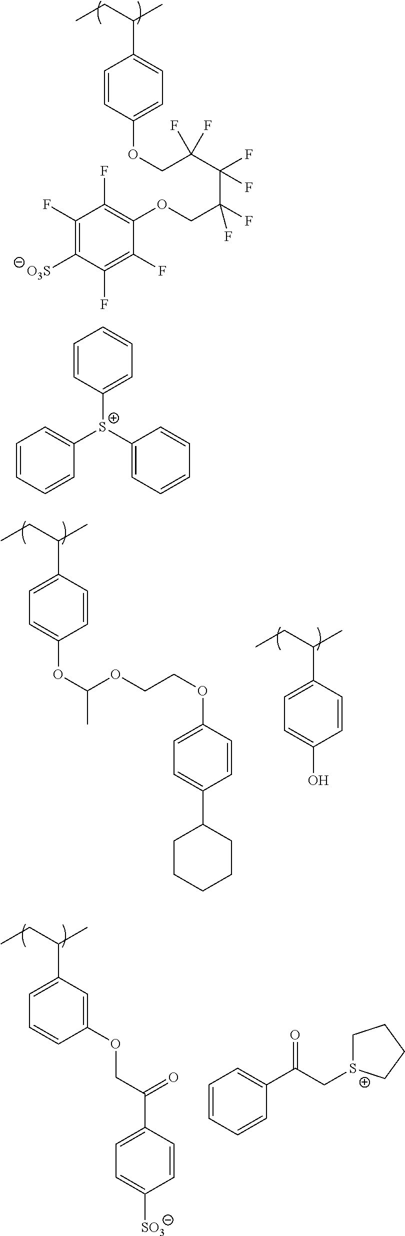

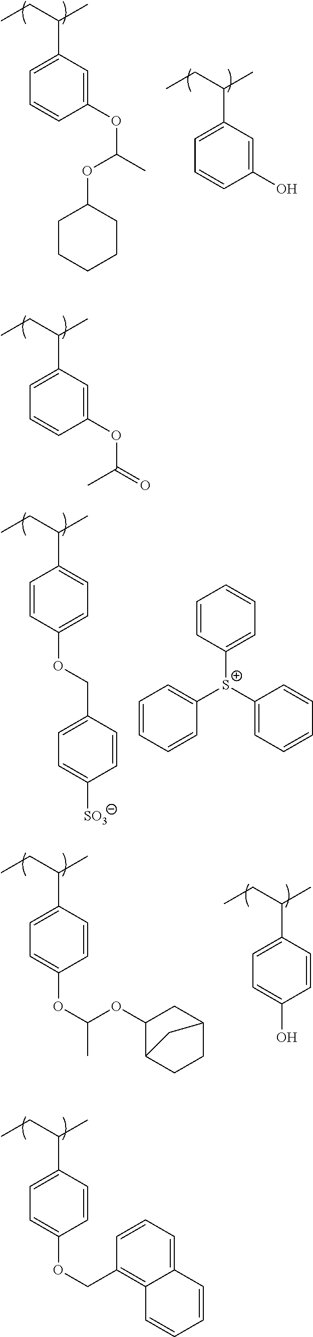

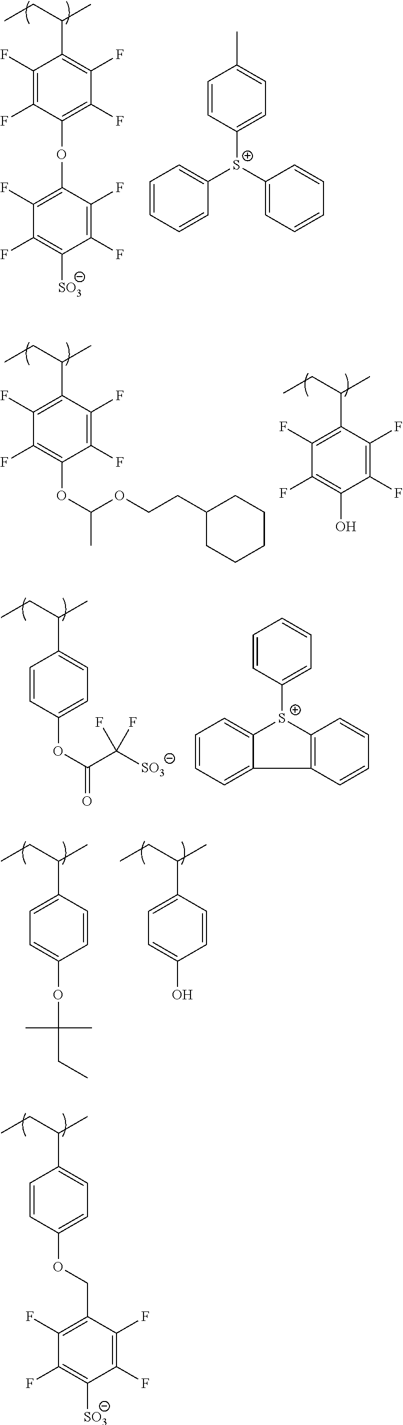

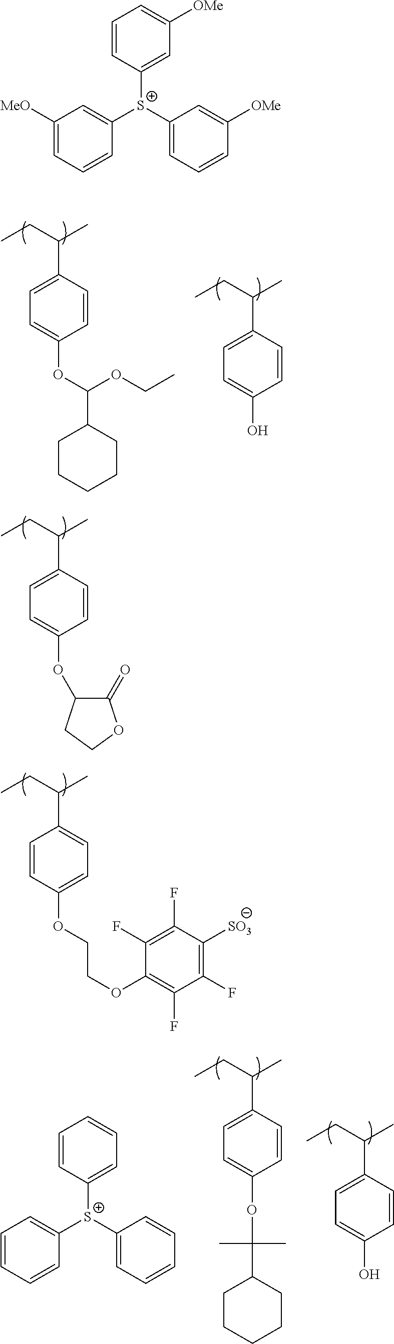

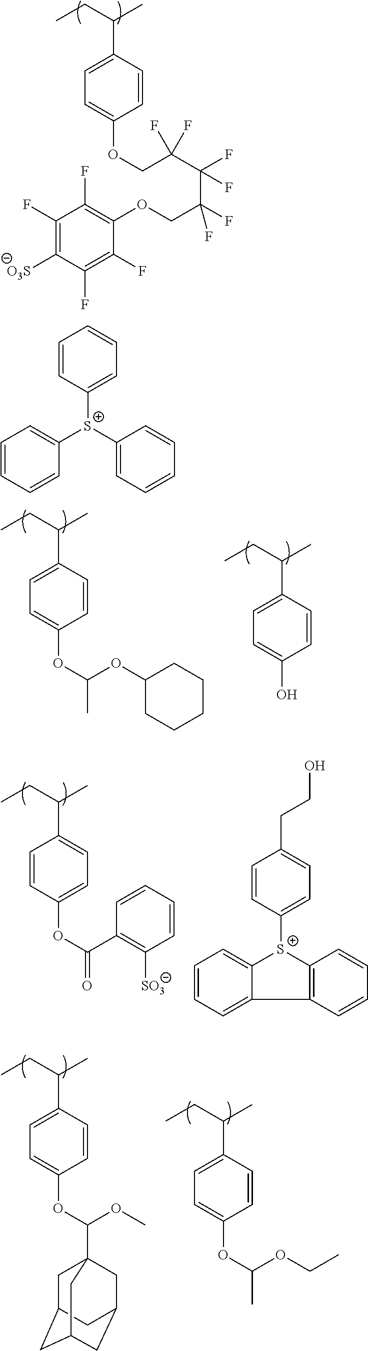

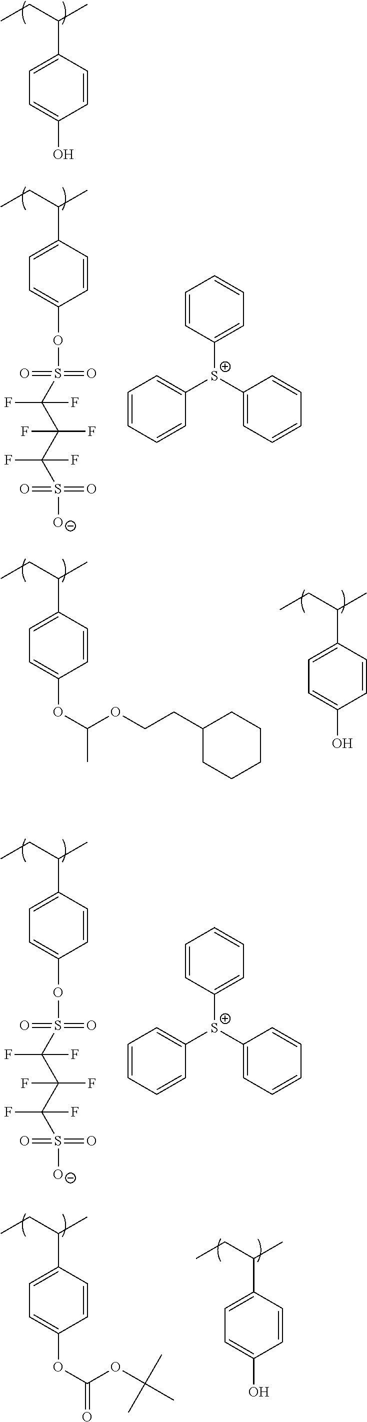

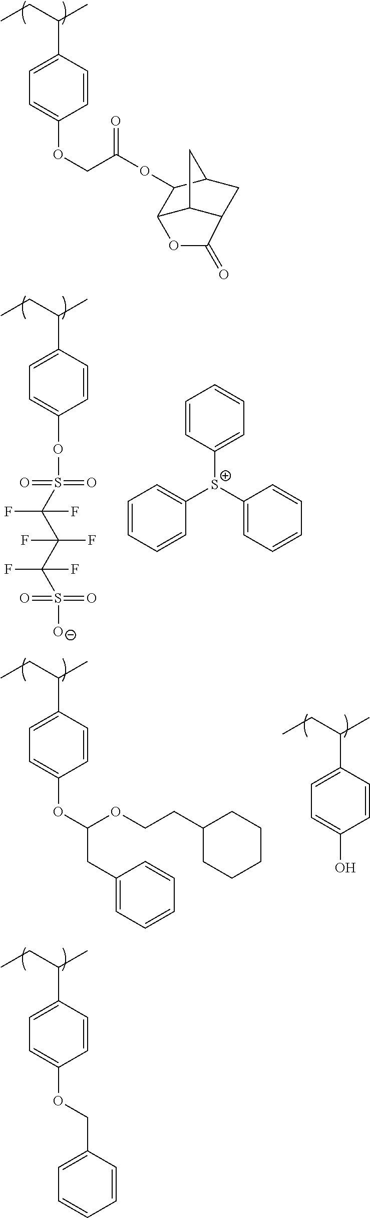

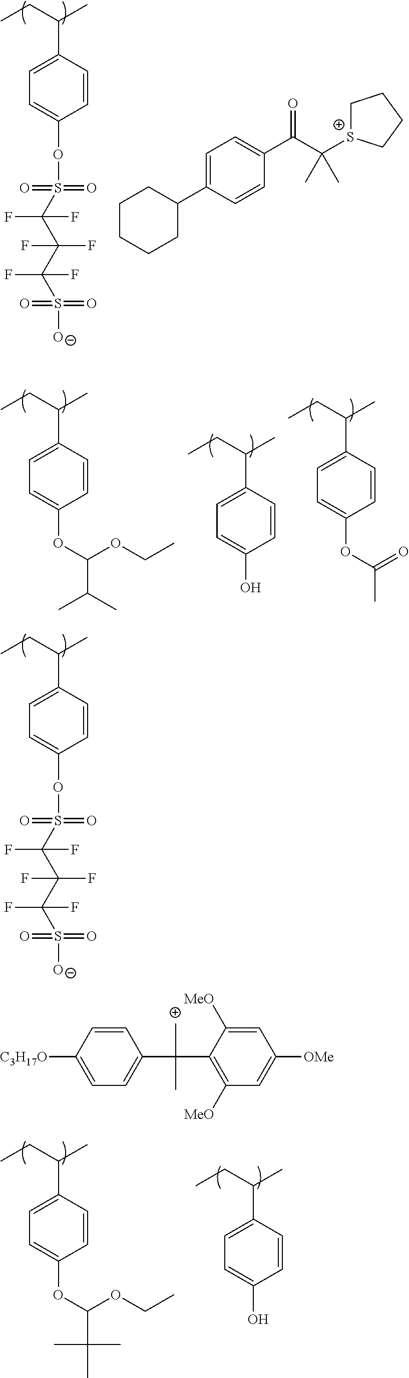

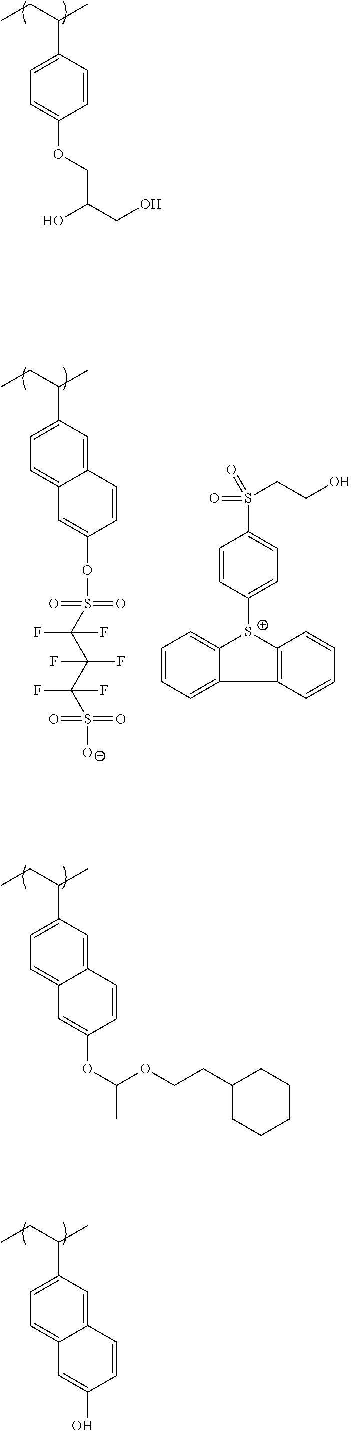

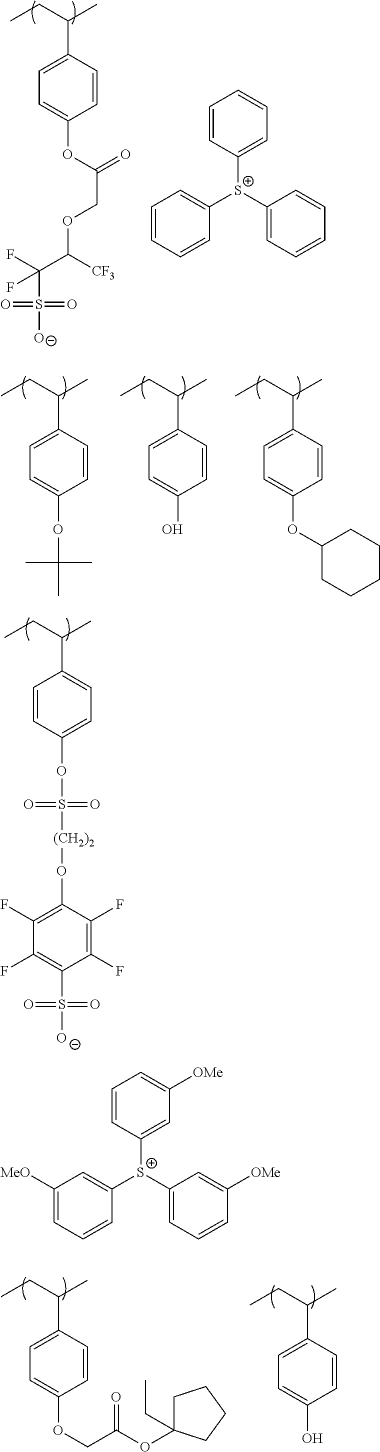

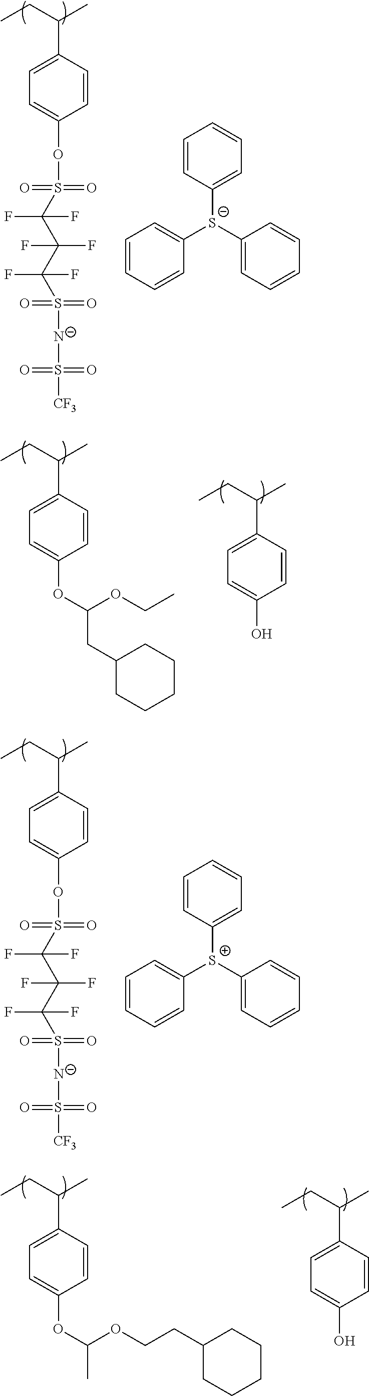

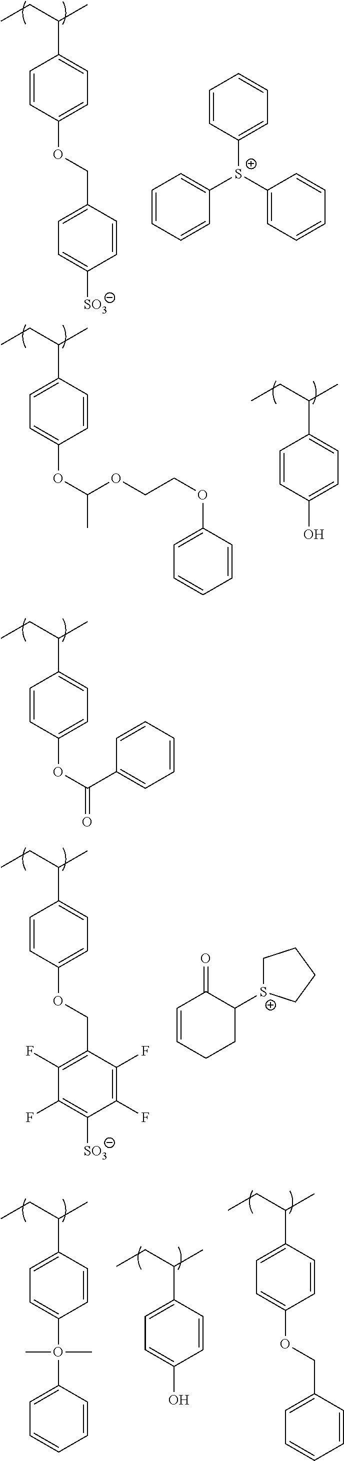

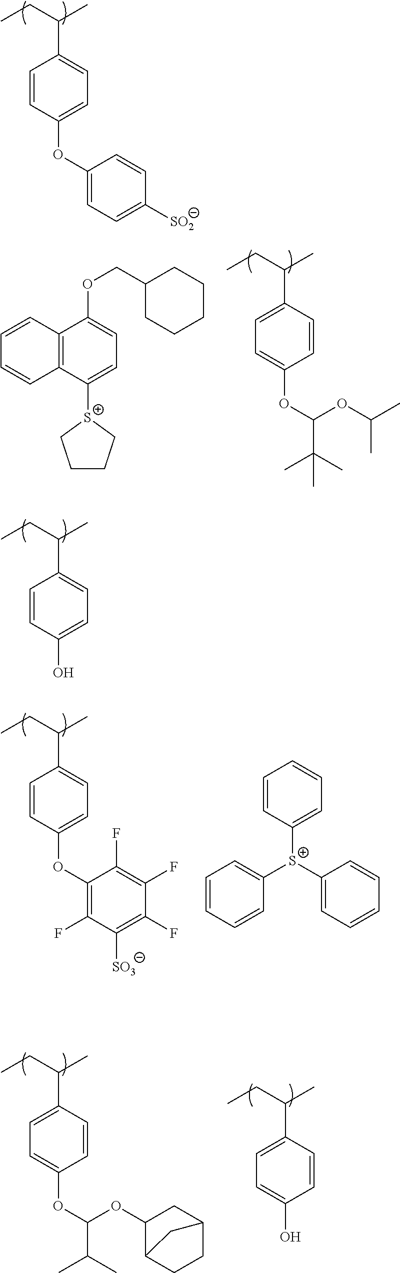

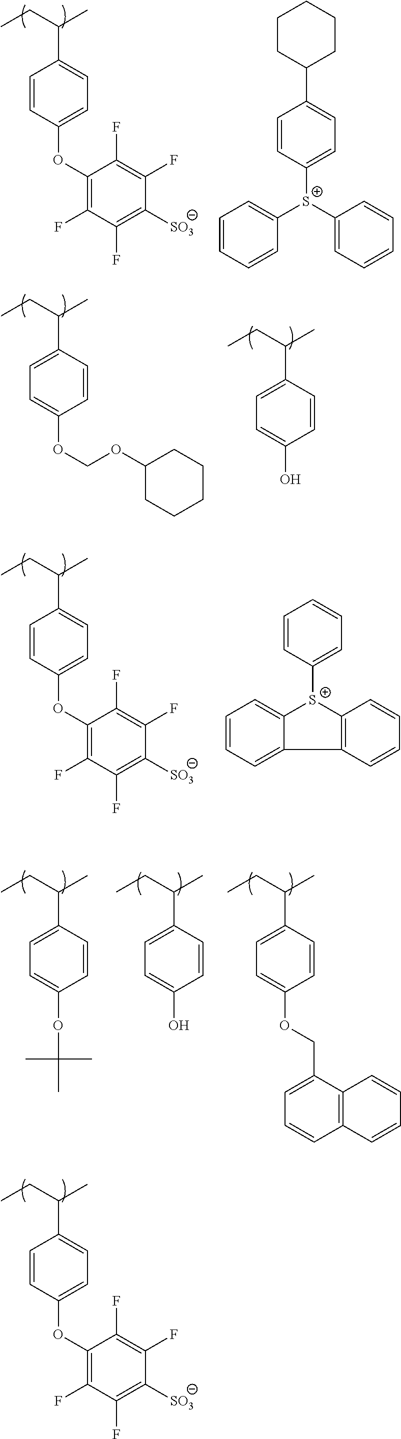

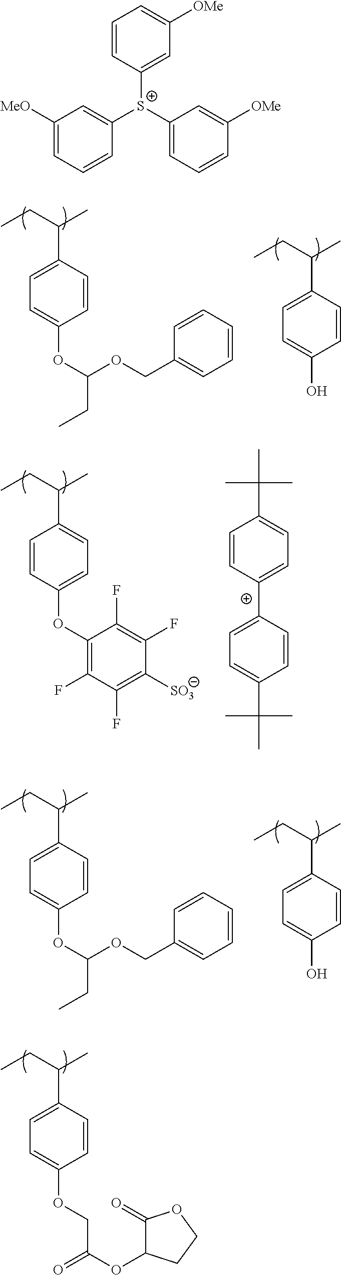

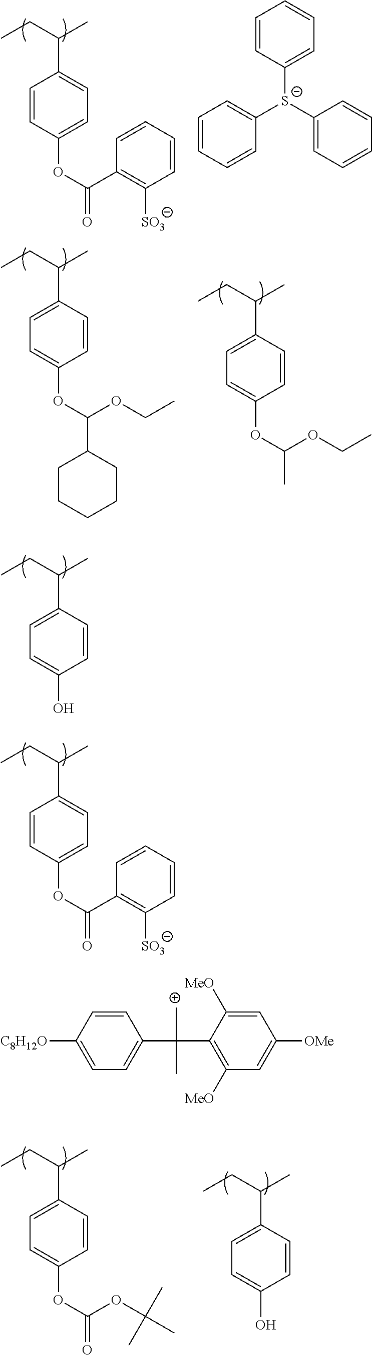

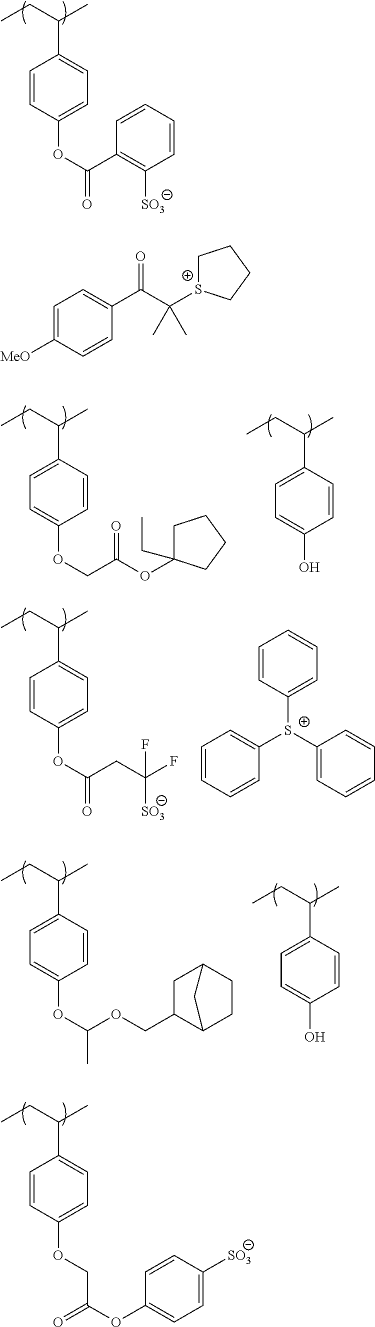

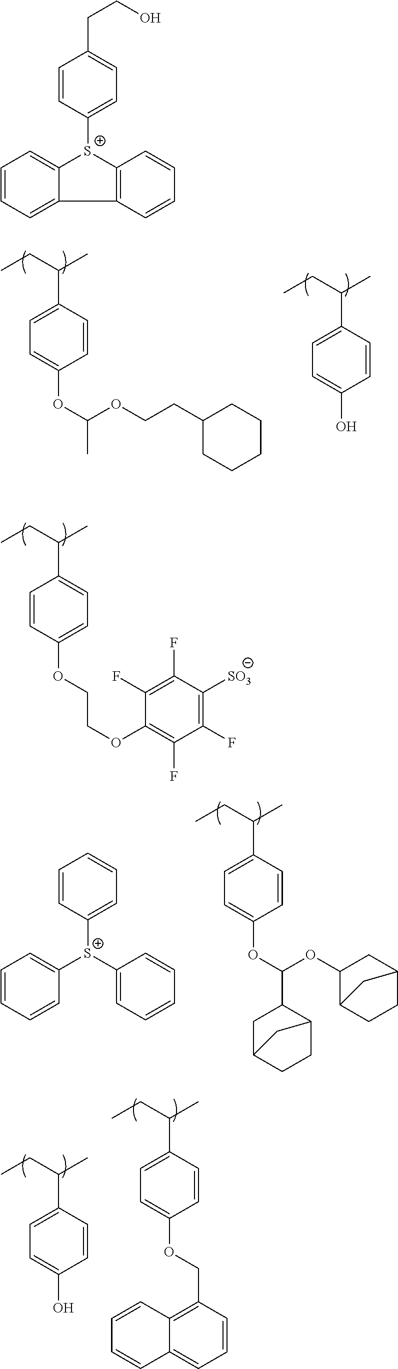

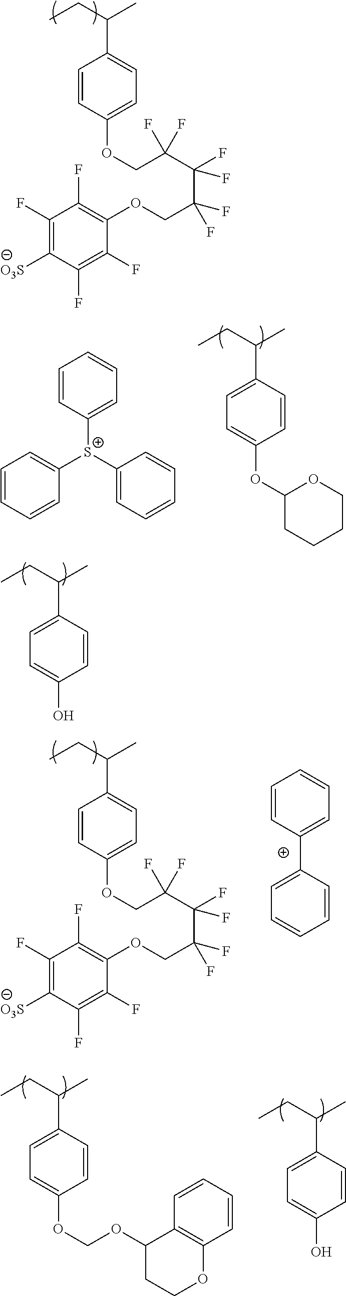

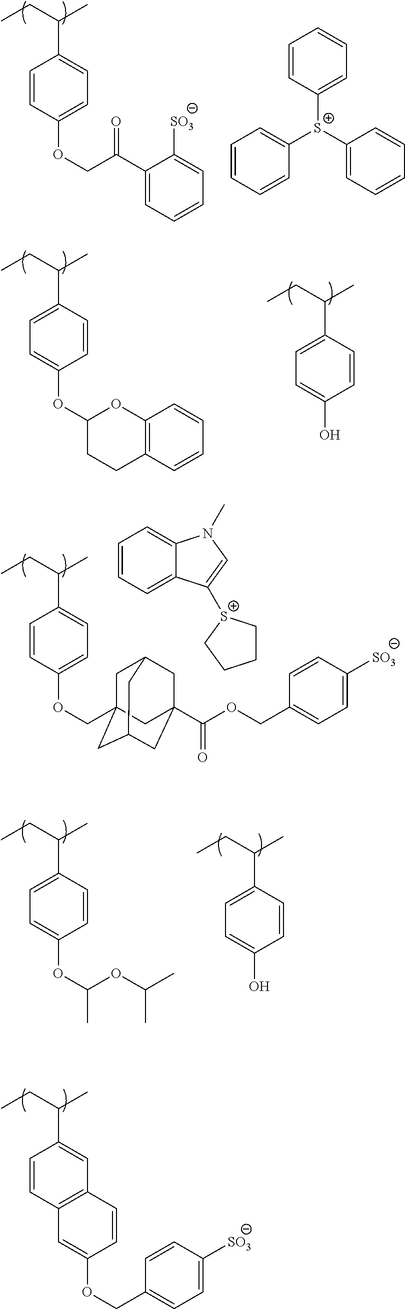

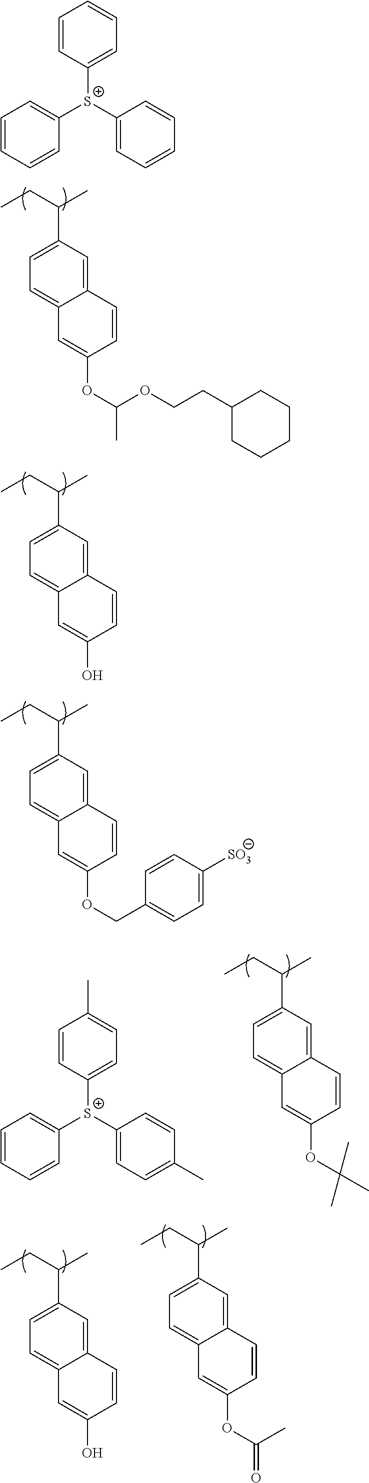

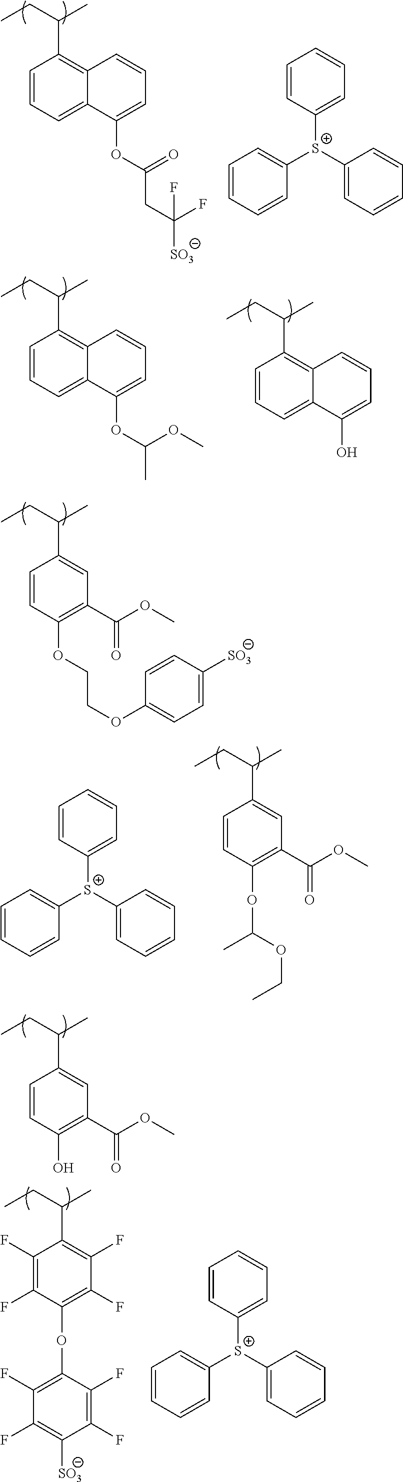

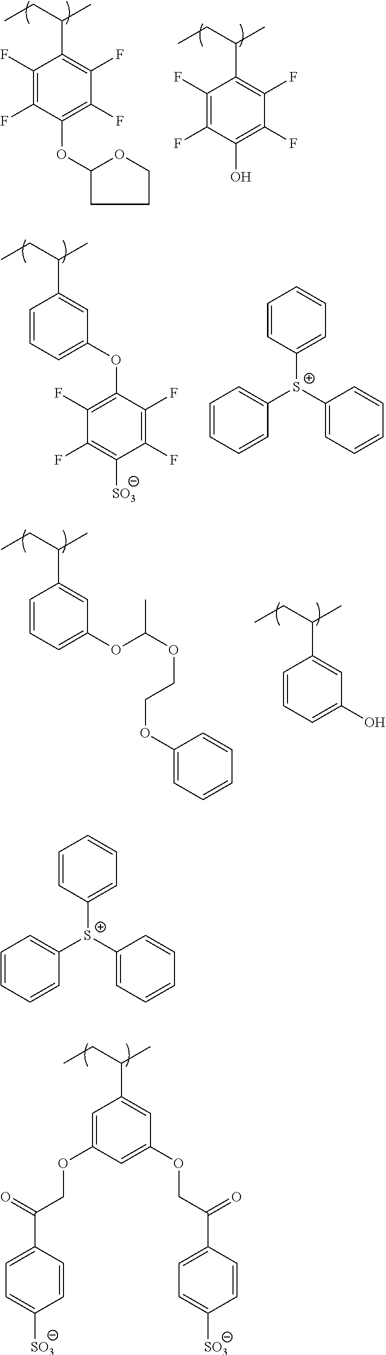

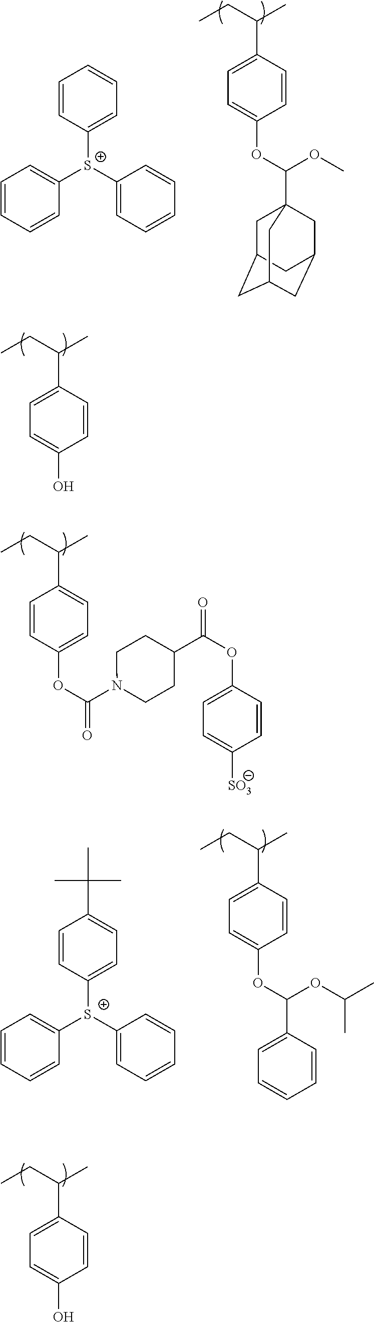

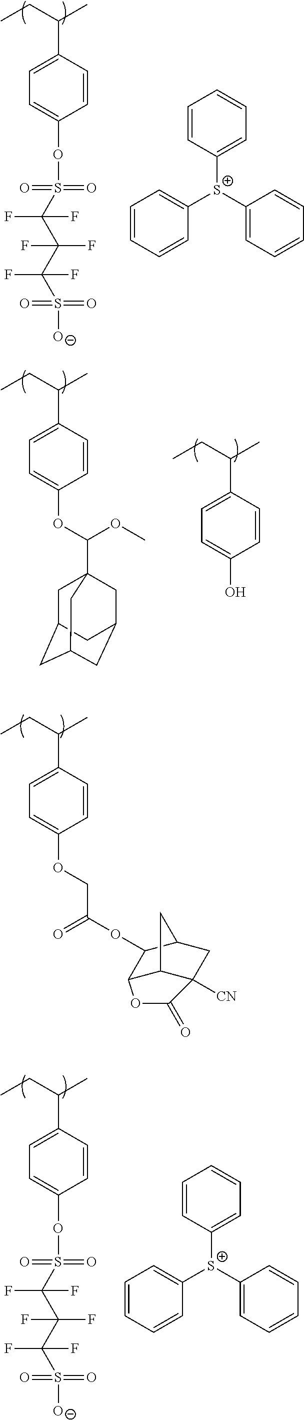

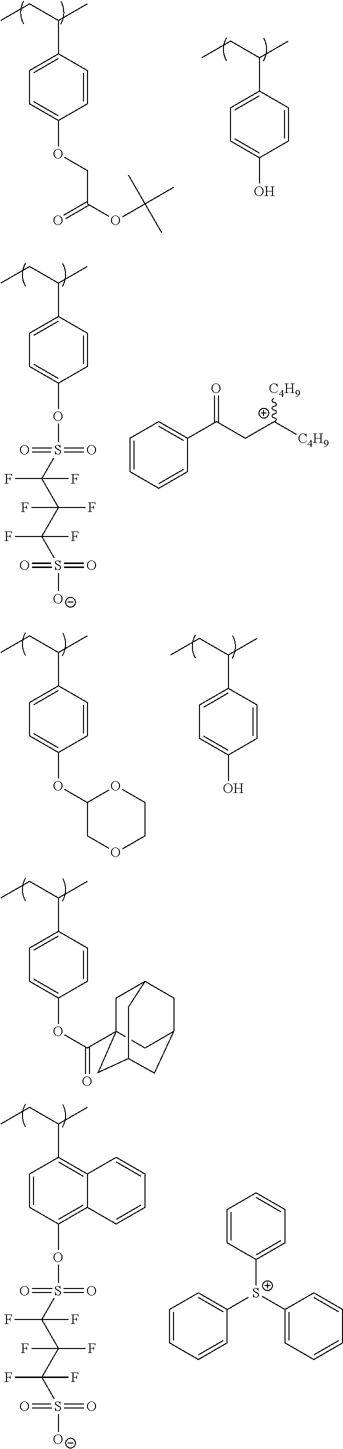

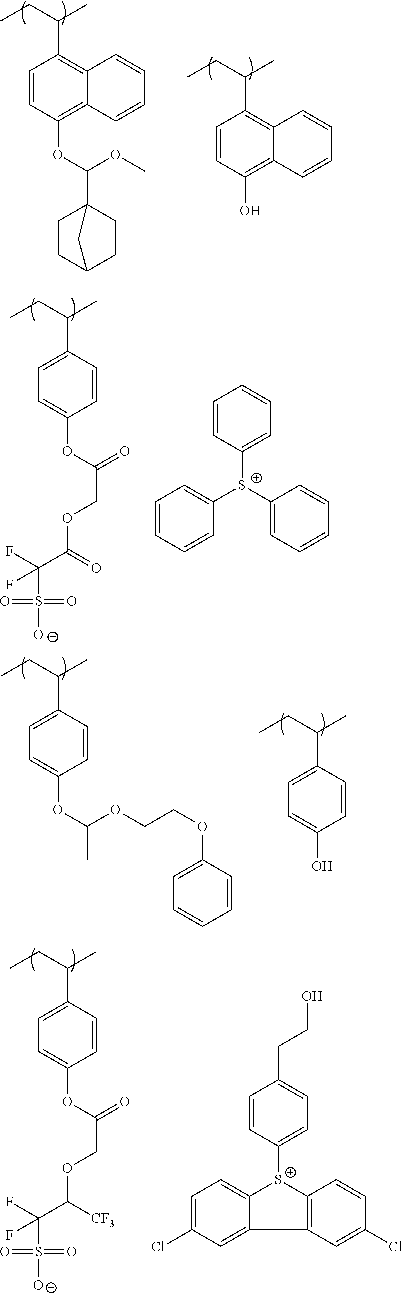

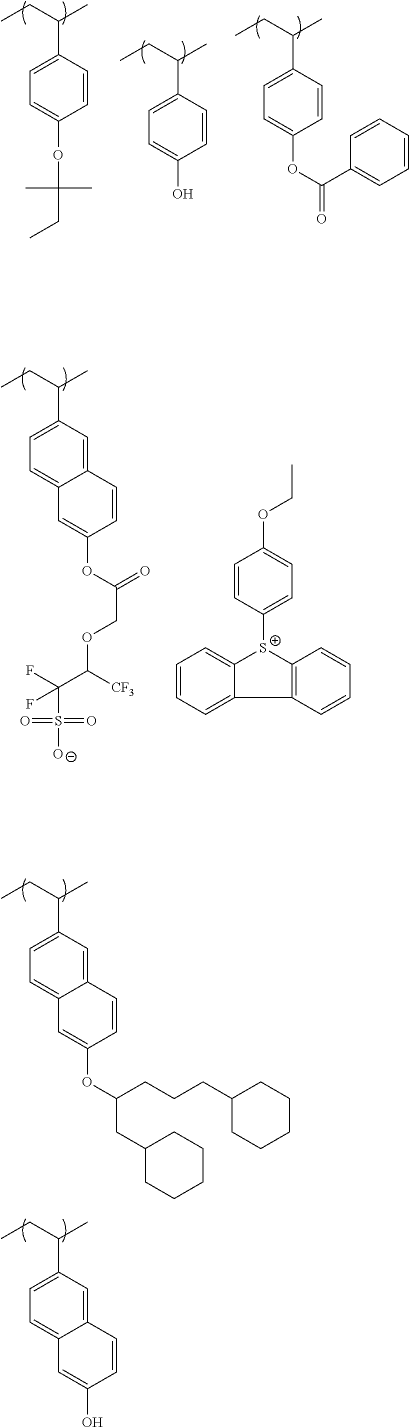

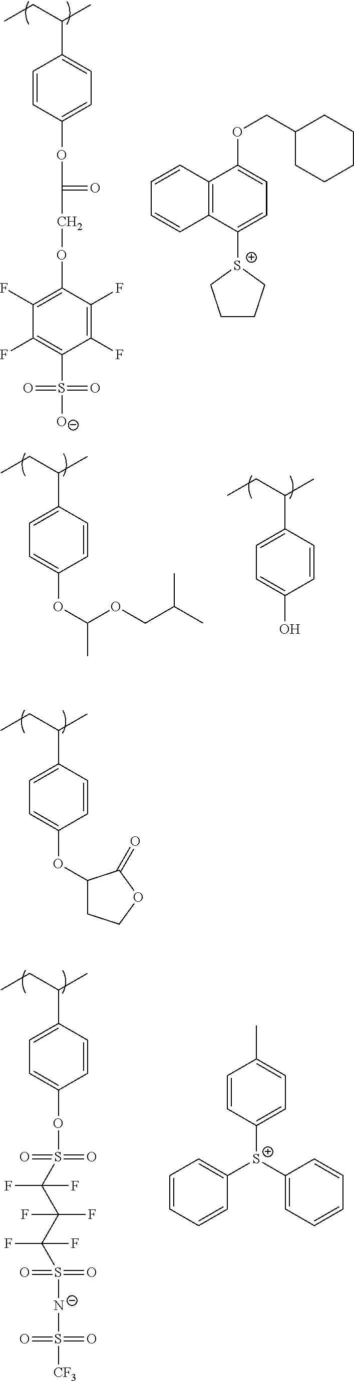

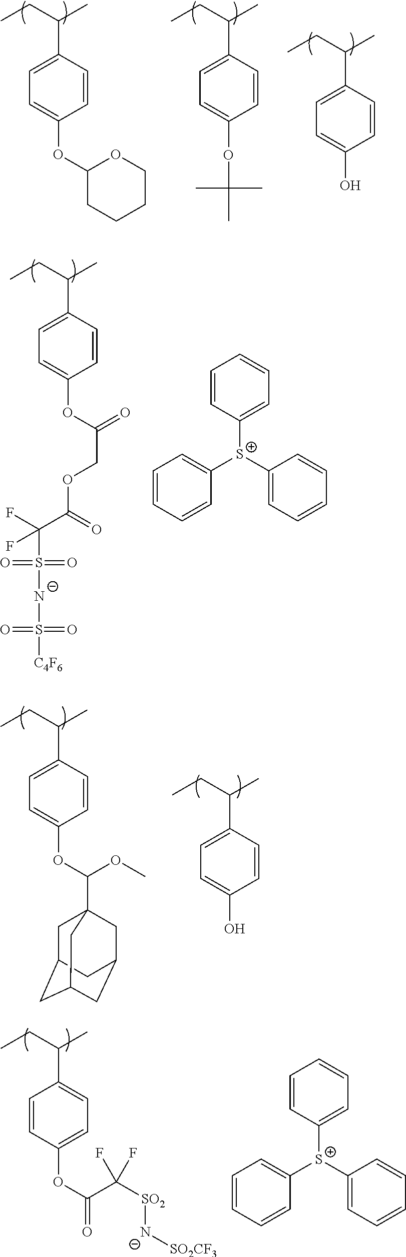

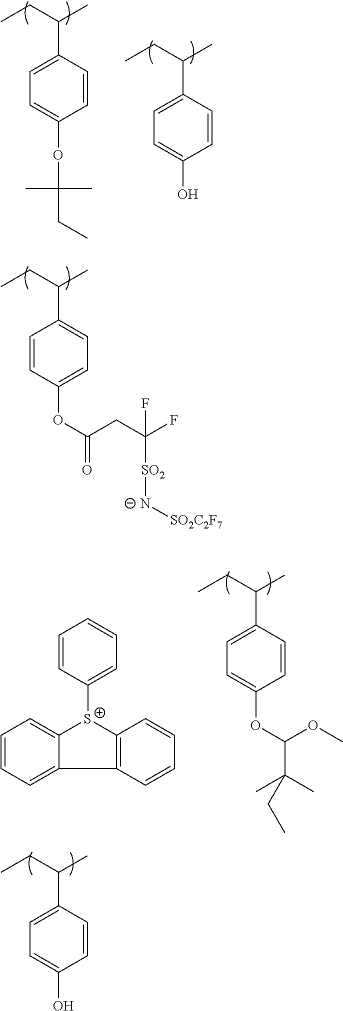

The structure of the resin (P) for use in the present invention can be synthesized, for example, by radical, cationic or anionic polymerization of unsaturated monomers corresponding to respective repeating units, but since the monomer corresponding the repeating unit (A) is liable to decompose under the condition of cationic or anionic polymerization reaction (for example, under the Lewis acid condition such as aluminum trichloride in the case of cationic polymerization, and under the condition using a catalyst such as n-butyllithium in the case of anionic polymerization), the resin has been conventionally synthesized substantially by radical polymerization. However, the resin synthesized by radical polymerization practically fails in having a polydispersity of 1.20 or less, because the radical polymerization is chain polymerization and a product having a high degree of polymerization is produced in the reaction system from early stages of the reaction. Accordingly, in order to obtain the resin (P) by polymerizing unsaturated monomers corresponding to respective repeating units by a radical polymerization method, after the resin is synthesized, the polydispersity must be reduced by sufficiently purifying the resin by a cumbersome method such as separation by reprecipitation or column. However, the necessity to sufficiently purify the resin leads to a low yield of a resin having a dispersion as narrow as a polydispersity of 1.20 or less and furthermore, the production of the resin becomes cumbersome due to a purification step required. For this reason, it is generally undesired to obtain the resin (P) by the above-described method. Also, for the same reason, it has not been conventionally done to reduce the polydispersity to 1.20 or less by sufficiently purifying a resin having a structure corresponding to the resin (P).

The present invention also relates to a novel production method of the resin (P), and according to this method, a resin (P) having a polydispersity of 1.20 or less can be produced without the above-described purification step, so that the problem such as low yield or cumbersome production process can be solved. In addition, the present invention is based on the finding that when a resin containing at least the above-described repeating units (A) and (C) is produced to fall in a non-conventional low dispersion region (that is, polydispersity of 1.20 or less) and the resin is used in an actinic ray-sensitive or radiation-sensitive resin composition, excellent effects described above are obtained.

More specifically, the present invention also relates to a production method of the resin (P), wherein (P) a resin containing the repeating units (A) and (C) and having a polydispersity of 1.20 or less is synthesized from poly(hydroxystyrene)s.

The production method of the present invention is described below. Here, for the reasons above, the resin (P) is preferably synthesized from poly(hydroxystyrene)s.

The term “poly(hydroxystyrene)s” as used herein means a generic term for polymers obtained by using, as a monomer, a compound where at least a vinyl group-containing group (preferably a vinyl group itself) and a hydroxyl group are substituted on an aromatic ring, and polymerizing the monomer. The aromatic ring is not limited to a benzene ring, and a polycyclic aromatic ring such as naphthalene ring and an aromatic heterocyclic ring are also encompassed in the aromatic ring. In the present invention, the aromatic ring is preferably a benzene ring or a naphthalene ring, more preferably a benzene ring.

The poly(hydroxystyrene)s as a raw material are narrow-disperse poly(hydroxystyrene)s, and the polydispersity is preferably from 1.00 to 1.20, more preferably from 1.00 to 1.19, still more preferably from 1.00 to 1.17. As to the poly(hydroxystyrene)s having such a narrow dispersion, for example, a poly(hydroxystyrene) is generally synthesized by a method of anionically polymerizing a tert-butoxystyrene and deprotecting a tert-butyl group under acidic conditions. The poly(hydroxystyrene)s are also available as a commercial product, and examples thereof include a poly(p-hydroxystyrene) (VP-2500, produced by Nippon Soda Co., Ltd.).

Examples of the narrow-disperse poly(hydroxystyrene)s include a narrow-disperse poly(p-hydroxystyrene), a narrow-disperse poly(m-hydroxystyrene), a narrow-disperse poly(2-vinyl-6-hydroxynaphthalene), and a narrow-disperse poly(l-vinyl-5-hydroxynaphthalene). Among these, a narrow-disperse poly(p-hydroxystyrene) and a narrow-disperse poly(m-hydroxystyrene) are preferred, and a narrow-disperse poly(p-hydroxystyrene) is more preferred.

The resin (P) can be synthesized by partially introducing an acid generating group into the narrow-disperse poly(hydroxystyrene)s above and thereby forming the repeating unit (A).

The reaction for partially introducing an acid generating group into narrow-disperse poly(hydroxystyrene)s is a modification reaction of a polymer and therefore, the reactivity has been conventionally low, making it difficult to control the introduction rate of the acid generating group. Also, in the case where the resin (P) has the repeating unit (B), the repeating unit (B) is chemically unstable under the introduction conditions of the repeating unit (A), and production of the resin (P) has been difficult. However, in the present invention, it has been found that when the reaction is performed under the following reaction conditions, the above-described problems are not brought about and the objective resin (P) having a polydispersity of 1.20 or less can be suitably obtained, and based on this finding, the present invention has been accomplished.

The technique for forming the repeating unit (A) may be appropriately changed according to the structure of the objective resin (P), and examples of the possible technique include a technique where an anion moiety is introduced by a method of reacting a hydroxyl group of narrow-disperse poly(hydroxystyrene)s with an acid anhydride (for example, a reaction with a 2-sulfobenzoic anhydride, represented by the following reaction formula 1), a method of reacting a hydroxyl group of narrow-disperse poly(hydroxystyrene)s with an organic acid dihalide and then hydrolyzing another acid halide (for example, a reaction using 1,1,2,2,3,3-hexafluoropropane-1,3-disulfonyl difluoride, represented by the following reaction formula 2), a method of reacting a hydroxyl group of narrow-disperse poly(hydroxystyrene)s with alkyl halides, aryl halides, organic acid halides or the like each having an acid group (for example, a sulfonic acid group or an imide acid group; the acid group may be in the form of a salt) (for example, a reaction with an alkali metal salt of p-chloromethylbenzenesulfonic acid, represented by the following reaction formula 3), or other methods and furthermore, a sulfonium cation, an iodonium cation or the like is introduced by a salt exchange reaction.

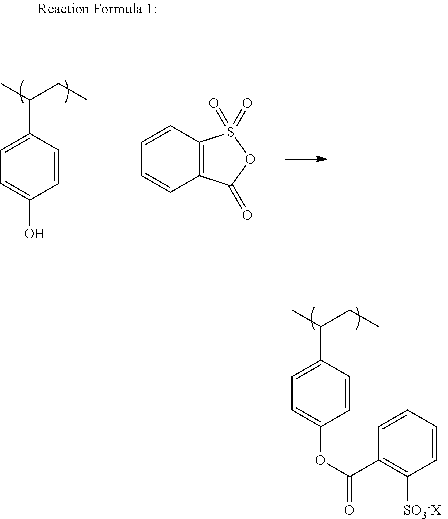

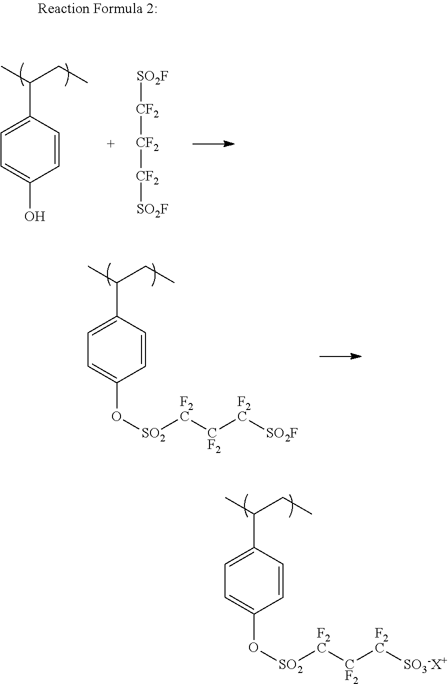

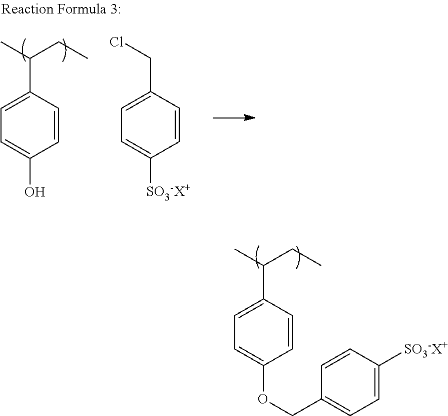

In reaction formulae 1 to 3, X⁺ represents a counter cation of the sulfonic acid.

These reactions are described in more detail below.

Examples of the acid anhydride include 2-sulfobenzoic anhydride.

Examples of the organic acid dihalide include 1,1,2,2,3,3-hexafluoropropane-1,3-disulfonyl difluoride and difluoromethane-disulfonyl difluoride.

Examples of the alkyl halides, aryl halides, organic acid halides and the like each having an acid group include sodium p-chloromethylbenzenesulfonate, a sodium salt of chloromethyl p-sulfobenzoate, sodium pentafluorobenzenesulfonate, and a sodium salt of 2,2-difluoro-2-sulfoacetyl chloride.

### (Additives)

The reaction of a hydroxyl group of poly(hydroxystyrene)s with the acid anhydride, with the organic dihalide, or with the alkyl halides, aryl halides, organic acid halides or the like each having an acid group, is preferably performed in the presence of a base. Accordingly, a base is preferably added as an additive to the reaction system, and specific examples of the base include a triethylamine, a trimethylamine, a tributylamine, an N,N-diisopropylethylamine, a pyridine, an N,N-dimethyl-4-aminopyridine, an aniline, an aqueous sodium hydroxide solution, an aqueous sodium hydrogencarbonate solution, DBU (diazabicycloundecene), an imidazole, a tetrabutylammonium bromide, a tetrabutylammonium hydrogensulfate, and a tetrabutylammonium hydroxide.

### (Solvent)

The solvent used in the reactions above is not particularly limited as long as it is a solvent capable of dissolving poly(hydroxystyrene)s, and specific examples thereof include THF (tetrahydrofuran), DMF (N,N-dimethylformamide), DMSO (dimethylsulfoxide), DMAc (dimethylacetamide), acetone, ethyl acetate, PGMEA (propylene glycol monomethyl ether acetate), methylene chloride, chloroform, 1,4-dioxane, and acetonitrile.

### (Concentration)

The concentration of the poly(hydroxystyrene)s in the reaction system is not particularly limited but is preferably from 0.1 to 70 mass %, more preferably from 2 to 50 mass %. (In this specification, mass ratio is equal to weight ratio.)

The concentration of the acid halide, the organic acid dihalide, or the acid group-containing alkyl halides, aryl halides, organic acid halides or the like, in the reaction system are not particularly limited but is preferably from 0.05 to 50 mass %, more preferably from 1 to 30 mass %. A method of sequentially adding dropwise the halides to the reaction system is also preferably used.

The concentration of the additive in the reaction system is not particularly limited but is preferably from 0.05 to 50 mass %, more preferably from 1 to 30 mass %. A method of sequentially adding dropwise the additive to the reaction system is also preferably used.

### (Reaction Time)

The reaction time of the reaction above is not particularly limited but is preferably from 10 minutes to 24 hours.

### (Reaction Temperature)

The reaction temperature of the reaction above is not particularly limited but is preferably from −80 to 150° C., more preferably from −10 to 80° C.

### (Salt Exchange)

As for the salt exchange reaction of the organic acid salt synthesized above, a salt exchange method described in JP-T-11-501909 (the term “JP-T” as used herein means a published Japanese translation of a PCT patent application) and JP-A-2003-246786 or a salt exchange method described, for example, in JP-A-10-232490 or Japanese Patent No. 4025039, may be employed by using a hydroxide, a bromide, a chloride or the like of iodonium, sulfonium or the like.

Incidentally, the yield of the resin (P) is greatly enhanced particularly when containing the repeating unit (B).

Also, the repeating unit (B) is preferably formed by partially introducing an acid-decomposable group into narrow-disperse poly(hydroxystyrene)s before the acid generating group is partially introduced, or into narrow-disperse poly(hydroxystyrene)s in which the acid generating group is partially introduced. The acid-decomposable group can be introduced into a hydroxyl group of narrow-disperse poly(hydroxystyrene)s as a raw material by an acetalization method or the like described, for example, in WO2005-023880 or Japanese Patent No. 4048171.

Specifically, for example, in the case of Resin (P-17) used in Examples later, a poly(p-hydroxystyrene) is reacted with a 2-cyclohexylethyl vinyl ether and a base such as triethylamine to form the repeating unit (B), subsequently reacted with 1,1,2,2,3,3-hexafluoropropane-1,3-disulfonyl difluoride and a base such as triethylamine and then reacted with sodium hydroxide, and thereafter, salt exchange is performed with triphenylsulfonium bromide to form the repeating unit (A), whereby Resin (P-17) can be synthesized.

The weight average molecular weight of the resin (P) for use in the present invention is preferably from 1,000 to 200,000, more preferably from 2,000 to 50,000, still more preferably from 2,000 to 20,000.

The polydispersity (molecular weight distribution) (Mw/Mn) of the resin (P) is preferably from 1.00 to 1.20, more preferably from 1.00 to 1.19, still more preferably from 1.00 to 1.17. The weight average molecular weight and polydispersity of the resin (P) are defined as a polystyrene-reduced value by GPC measurement (solvent: N-Methyl-2-pyrrolidone (NMP) 3 L, phosphoric acid 2.93 g, LiBr 2.606 g; column: TSK-GEL super AWM-H (TOSOH Corporation); column temperature: 50° C.; flow volume: 0.35 mL/min; detector: HLC-8020 GPC (TOSOH Corporation)).

Also, the resin (P) may be used by mixing two or more thereof.

The amount added of the resin (P) for use in the present invention is preferably from 30 to 100 mass %, more preferably from 50 to 99.95 mass %, still more preferably from 70 to 99.90 mass %.

[2](B) Low Molecular Compound Capable of Generating Acid Upon irradiation with Actinic Ray or Radiation

The actinic ray-sensitive or radiation-sensitive resin composition of the present invention may further contain (B) a low molecular compound capable of generating an acid upon irradiation with an actinic ray or radiation (hereinafter, this compound is simply referred to as “acid generator (B)”, as appropriate).

The low molecular compound (B) as used herein means a compound except for a compound where a moiety capable of generating an acid upon irradiation with an actinic ray or radiation is introduced into the main or side chain of the resin, and is typically a compound where the moiety above is introduced into a monomolecular compound. The molecular weight of the low molecular compound (B) is generally 4,000 or less, preferably 2,000 or less, more preferably 1,000 or less. Also, the molecular weight of the low molecular compound (B) is generally 100 or more, preferably 200 or more.

A preferred embodiment of the acid generator (B) is an onium compound. Examples of the acid generator (B) include a sulfonium salt, an iodonium salt and a phosphonium salt.

Another preferred embodiment of the acid generator (B) is a compound capable of generating a sulfonic acid, an imide acid or a methide acid upon irradiation with an actinic ray or radiation. Examples of the acid generator (B) in this embodiment include a sulfonium salt, an iodonium salt, a phosphonium salt, oxime sulfonate and imidosulfonate.

The acid generator (B) is preferably a compound capable of generating an acid upon irradiation with an electron bema, an X-ray or a soft X-ray.

The actinic ray-sensitive or radiation-sensitive resin composition of the present invention may or may not contain the acid generator (B), but in the case of containing the acid generator, the content thereof is preferably from 0.1 to 30 mass %, more preferably from 0.5 to 20 mass %, still more preferably from 1.0 to 10 mass %, based on the entire solid content of the composition.

As for the acid generator (B), one kind may be used alone, or two or more kinds may be used in combination.

### [3] Basic Compound

The actinic ray-sensitive or radiation-sensitive resin composition of the present invention preferably contains a basic compound as an acid scavenger, in addition to the above-described components. By using a basic compound, performance change with aging from exposure to post-baking can be suppressed. The basic compound is preferably an organic basic compound, and specific examples thereof include aliphatic amines, aromatic amines, heterocyclic amines, nitrogen-containing compounds having a carboxyl group, nitrogen-containing compounds having a sulfonyl group, nitrogen-containing compounds having a hydroxy group, nitrogen-containing compounds having a hydroxyphenyl group, alcoholic nitrogen-containing compounds, amide derivatives, and imide derivatives. An amine oxide compound (described in JP-A-2008-102383) and an ammonium salt (preferably a hydroxide or a carboxylate; more specifically, a tetraalkylammonium hydroxide typified by tetrabutylammonium hydroxide is preferred in view of LER) may be also appropriately used.

Furthermore, a compound capable of increasing the basicity by the action of an acid may be also used as a kind of a basic compound.

Specific examples of the amines include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, 2,4,6-tri(tert-butyl)aniline, triethanolamine, N,N-dihydroxyethylaniline, tris(methoxyethoxyethyl)amine, compounds exemplified in column 3, line 60 et seq. of U.S. Pat. No. 6,040,112, 2-[2-{2-(2,2-dimethoxy-phenoxyethoxy)ethyl}-bis-(2-methoxyethyl)]-amine, and Compounds (C1-1) to (C3-3) illustrated in paragraph [0066] of U.S. Patent Application Publication No. 2007/0224539A1. Examples of the compound having a nitrogen-containing heterocyclic structure include 2-phenylbenzimidazole, 2,4,5-triphenylimidazole, N-hydroxyethylpiperidine, bis(1,2,2,6,6-pentamethyl-4-piperidyl)sebacate, 4-dimethylaminopyridine, antipyrine, hydroxyantipyrine, 1,5-diazabicyclo[4.3.0]non-5-ene, and 1,8-diazabicyclo[5.4.0]undec-7-ene. As the ammonium salt, tetrabutylammonium hydroxide is preferred.

Among these basic compounds, an ammonium salt is preferred from the standpoint of enhance the resolution.

The actinic ray-sensitive or radiation-sensitive resin composition may or may not contain a basic compound, but in the case of containing a basic compound, the content of the basic compound for use in the present invention is preferably from 0.01 to 10 mass %, more preferably from 0.03 to 5 mass %, still more preferably from 0.05 to 3 mass %, based on the entire solid content of the composition.

### [4] Surfactant

The actinic ray-sensitive or radiation-sensitive resin composition of the present invention may further contain a surfactant so as to enhance the coatability. The surfactant is not particularly limited, but examples thereof include a nonionic surfactant such as polyoxyethylene alkyl ethers, polyoxyethylene alkylallyl ethers, polyoxyethylene-polyoxypropylene block copolymers, sorbitan fatty acid esters and polyoxyethylene sorbitan fatty acid esters, a fluorine-containing surfactant such as Megaface F176 (produced by DIC Corporation), Florad FC430 (produced by Sumitomo 3M, Inc.), Surfynol E1004 (produced by Asahi Glass Co., Ltd.), and PF656 and PF6320 produced by OMNOVA, a surfactant containing fluorine and silicon, such as Megaface R08 (produced by DIC Corporation, and an organosiloxane polymer such as Polysiloxane Polymer KP-341 (produced by Shin-Etsu Chemical Co., Ltd.).

The actinic ray-sensitive or radiation-sensitive resin composition of the present invention may or may not contain a surfactant, but in the case where the composition contains a surfactant, the amount of the surfactant used is preferably from 0.0001 to 2 mass %, more preferably from 0.0005 to 1 mass %, based on the entire amount of the composition (excluding the solvent).

The actinic ray-sensitive or radiation-sensitive resin composition of the present invention may further contain a dye, a plasticizer, a photodecomposable basic compound, a photobase generator and the like, if desired. As for all of these compounds, examples include those of respective compounds described in JP-A-2002-6500.

Preferred examples of the solvent used for the actinic ray-sensitive or radiation-sensitive resin composition of the present invention include ethylene glycol monoethyl ether acetate, cyclohexanone, 2-heptanone, propylene glycol monomethyl ether (PGME, another name: 1-methoxy-2-propanol), propylene glycol monomethyl ether acetate (PGMEA, another name: 1-methoxy-2-acetoxypropane), propylene glycol monomethyl ether propionate, propylene glycol monoethyl ether acetate, methyl 3-methoxypropionate, ethyl 3-ethoxypropionate, methyl β-methoxyisobutyrate, ethyl butyrate, propyl butyrate, methyl isobutyl ketone, ethyl acetate, isoamyl acetate, ethyl lactate, toluene, xylene, cyclohexyl acetate, diacetone alcohol, N-methylpyrrolidone, N,N-dimethylformamide, γ-butyrolactone, N,N-dimethylacetamide, propylene carbonate and ethylene carbonate. One of these solvents may be used alone, or some may be used in combination.

The actinic ray-sensitive or radiation-sensitive resin composition is preferably prepared by dissolving the components in the solvent about to give a solid content of, in terms of solid content concentration, from 1 to 40 mass %, more preferably from 1 to 30 mass %, still more preferably from 3 to 20 mass %.

The present invention also relates to a resist film formed using the actinic ray-sensitive or radiation-sensitive resin composition of the present invention, and the resist film is formed, for example, by applying the composition on a support such as substrate. The actinic my-sensitive or radiation-sensitive resin composition of the present invention is applied on a substrate by an appropriate coating method such as spin coating, roll coating, flow coating, dip coating, spray coating and doctor coating and pre-baked at 60 to 150° C. for 1 to 20 minutes, preferably at 80 to 130° C. for 1 to 10 minutes, to form a thin film. The thickness of the coating film is preferably from 30 to 200 nm.

The substrate suitable for the present invention is a silicon substrate, a metal-deposited film or a substrate having provided thereon a metal-containing film, and a substrate having provided on the surface thereof a vapor-deposited film of Cr, MoSi, TaSi or an oxide or nitride thereof is more suited.

The present invention also relates to a resist-coated mask blank coated with the thus-obtained resist film. In order to obtain such a resist-coated mask blank, in the case of forming a resist pattern on a photomask blank for the production of a photomask, the transparent substrate is a transparent substrate such as quartz and calcium fluoride. In general, a light-shielding film, an antireflection film, further a phase shift film, and additionally a required functional film such as etching stopper film and etching mask film, are stacked on the substrate. As for the material of the functional film, a film containing silicon or a transition metal such as chromium, molybdenum, zirconium, tantalum, tungsten, titanium and niobium is stacked. Examples of the material used for the outermost layer include a material where the main constituent material is a material containing silicon or containing silicon and oxygen and/or nitrogen, a silicon compound material where the main constituent material is the material above which further contains a transition metal, and a transition metal compound material where the main constituent material is a material containing a transition metal, particularly, one or more transition metals selected from chromium, molybdenum, zirconium, tantalum, tungsten, titanium and niobium, or further containing one or more elements selected from oxygen, nitrogen and carbon.

The light-shielding film may have a single-layer structure but preferably has a multilayer structure where plural materials are applied one on another. In the case of a multilayer structure, the film thickness per layer is not particularly limited but is preferably from 5 to 100 nm, more preferably from 10 to 80 nm. The thickness of the entire light-shielding film is not particularly limited but is preferably from 5 to 200 nm, more preferably from 10 to 150 urn.

Out of these materials, when pattern formation is performed using the actinic my-sensitive or radiation-sensitive resin composition on a photomask blank having in the outermost surface layer thereof a material containing chromium and oxygen or nitrogen, a so-called tapered profile skirted near the substrate is generally liable to be formed. However, when the present invention is used, the tapered profile can be improved as compared with the conventional mask blank.

Subsequently, this resist film is irradiated with an actinic ray or radiation (e.g., electron beam), preferably baked (usually at 80 to 150° C., preferably at 90 to 130° C.), and then developed, whereby a good pattern can be obtained. Etching, ion implantation or the like is appropriately performed by using this pattern as the mask to produce a semiconductor fine circuit, an imprint mold structure, a photomask or the like.

Incidentally, the process when preparing an imprint mold by using the composition of the present invention is described, for example, in Japanese Patent 4,109,085, JP-A-2008-162101 and Yoshihiko Hirai (compiler), Nanoimprint no Kiso to Gijutsu Kaihatsu/Oyo Tenkai-Nanoimprint no Kiban Gijutsu to Saishin no Gijutsu Tenkai (Basic and Technology Expansion/Application Development of Nanoimprint-Substrate Technology of Nanoimprint and Latest Technology Expansion), Frontier Shuppan.

The use mode of the actinic ray-sensitive or radiation-sensitive resin composition of the present invention and the pattern forming method are described below.

The present invention also relates to a resist pattern forming method including exposing the above-described resist film or resist-coated mask blank and developing the exposed resist film or resist-coated mask blank. In the present invention, the exposure is preferably performed using an electron beam, an X-ray or a soft X-ray.

In the production or the like of a precision integrated circuit device, the exposure of the resist film (pattern forming step) is preferably performed by patternwise irradiating the resist film of the present invention with an electron beam, an X-ray or a soft X-ray. The exposure is performed with an irradiation dose (exposure dose) of, in the case of an electron beam, approximately from 0.1 to 60 μC/cm², preferably on the order of 3 to 50 μC/cm², and in the case of an extreme-ultraviolet ray, approximately from 0.1 to 40 mJ/cm², preferably on the order of 3 to 30 mJ/cm². Thereafter, post-exposure baking is performed on a hot plate at 60 to 150° C. for 1 to 20 minutes, preferably at 80 to 120° C. for 1 to 10 minutes, and subsequently, the resist film is developed, rinsed and dried, whereby a resist pattern is formed. The developer is an aqueous alkali solution with a concentration of 0.1 to 5 mass %, preferably from 2 to 3 mass %, such as tetramethylammonium hydroxide (TMAH), and the development is performed by a conventional method such as dip method, puddle method and spray method for 0.1 to 3 minutes, preferably from 0.5 to 2 minutes. The exposed area is dissolved with the developer and the unexposed area is hardly dissolved with the developer, whereby an objective pattern is formed on the substrate.

The composition of the present invention can be used for a process of obtaining a negative-tone pattern in which a development using a developer containing an organic solvent as a main component is performed after coating, film-forming and exposure of the composition. As such a process, for example, a process described in JP-A-2010-217884 can be used.

As an organic developer, a polar solvent such as an ester-based solvent (for example, butyl acetate and ethyl acetate etc.), a ketone-based solvent (for example, 2-heptanone and cyclohexanone etc.), an alcohol-based solvent, an amide-based solvent, an ether-based solvent and the like or a hydrocarbon-based solvent can be used. The water content in an organic developer as a whole is preferably less than 10 mass %, more preferably substantially free of water.

The present invention also relates to a photomask obtained by exposing and developing the resist-coated mask blank. As for the exposure and development, the above-described steps are applied. The photomask is suitably used for the production of a semiconductor.

The photomask of the present invention may be a light transmitting mask used with an ArF excimer laser and the like or may be a reflective mask used for reflection-system lithography using EUV light as the light source.

Furthermore, the present invention also relates to a production method of a semiconductor device, including the above-described pattern forming method of the present invention, and a semiconductor device produced by this production method.

The semiconductor device of the present invention is suitably mounted in electric/electronic equipment (for example, home appliance, office automation/media-related equipment, optical equipment and communication equipment).

### EXAMPLES

### Synthesis Example 1

### Synthesis of Resin (P-1)

Poly(p-hydroxystyrene) (20 g) (VP-2500, produced by Nippon Soda Co., Ltd.) was dissolved in 80 g of propylene glycol monomethyl ether acetate (PGMEA). To the resulting solution, 10.3 g of 2-cyclohexylethyl vinyl ether and 20 mg of camphorsulfonic acid were added, and the mixture was stirred at room temperature for 2 hours. Subsequently, 84 mg of triethylamine was added and after stirring for a while, the reaction solution was transferred to a separating funnel containing 100 mL of ethyl acetate. The organic layer was washed with 20 mL of distilled water three times and thereafter, the organic layer was dried under reduced pressure.

The obtained polymer was dissolved in 80 g of N,N-dimethylformamide (DMF), and 15.7 g of triethylamine and 2.2 g of 2-sulfobenzoic anhydride were added. After stirring at room temperature for 2 hours, 4.4 g of triphenylsulfonium bromide and 10 mL of methanol were added to the reaction solution, and the mixture was stirred at room temperature for 1 hour. The reaction solution was transferred to a separating funnel containing 300 mL of ethyl acetate, and the organic layer was washed with 50 mL of distilled water five times. The organic layer was then concentrated in an evaporator, and the obtained polymer was dissolved in 300 mL of acetone. The resulting solution was added dropwise and reprecipitated in 3,000 g of hexane, and the precipitate was filtered to obtain 14.3 g of Resin (P-1).

In the resin (P-1), the compositional ratio (molar ratio) was calculated by ¹H-NMR measurement. Also, the weight average molecular weight (Mw: in terms of polystyrene) and polydispersity (Mw/Mn) were calculated by GPC (solvent: N-methyl-2-pyrrolidone) measurement. The results obtained are shown in the following chemical formula.

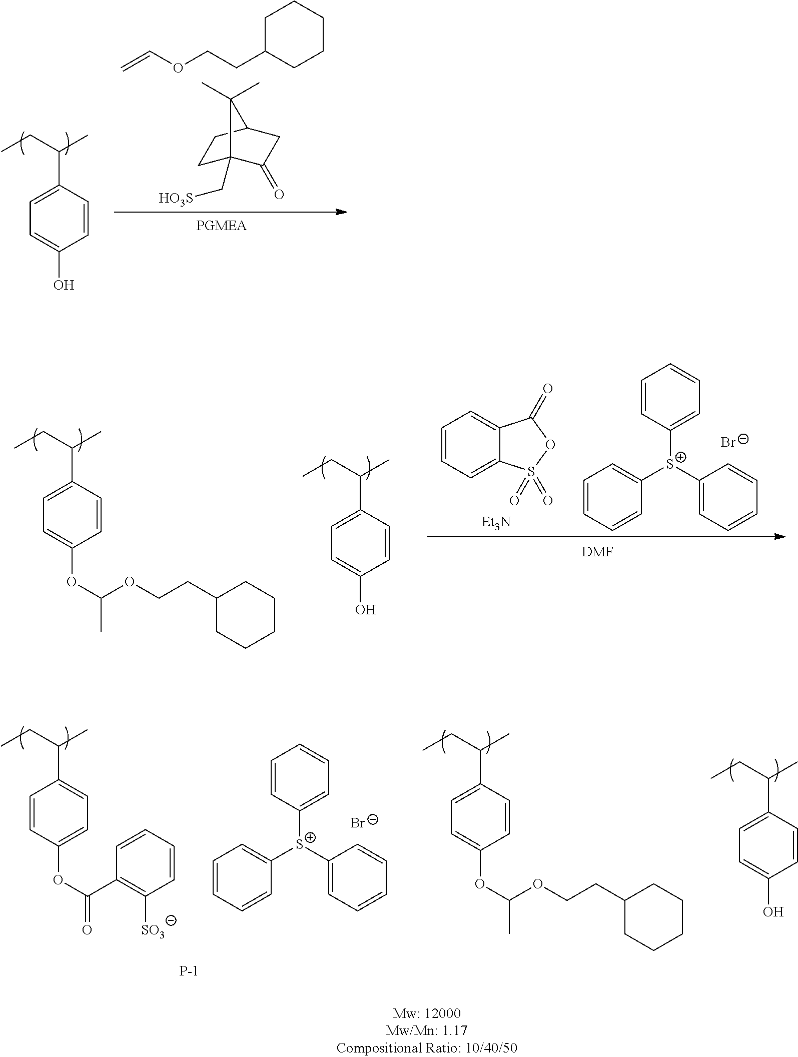

### Synthesis Example 2

### Synthesis of Resin (P-7)

Poly(p-hydroxystyrene) (20 g) (VP-2500, produced by Nippon Soda Co., Ltd.) was dissolved in 100 g of tetrahydrofuran (THF), and 16.8 g of triethylamine was added to the solution. The resulting mixture was cooled in an ice bath, and 20.7 g of Chloroether Compound (CE-1) was added dropwise to the reaction solution. After returning the temperature to room temperature, the reaction solution was stirred for 3 hours, and 50 mL of distilled water was added thereto. After removing THF by an evaporator, the reaction solution was transferred to a separating funnel containing 200 mL of ethyl acetate and washed with 30 mL of distilled water five times. Thereafter, the organic layer was concentrated to dryness by an evaporator.

The obtained polymer was dissolved in 20 g of THF and 20 g of methylene chloride, and 20 g of an aqueous 1 N—NaOH solution, 1.2 g of tetrabutylammonium hydrogensulfate and 10.2 g of sodium pentafluorobenzenesulfonate were added to the solution. After stirring at room temperature for 2 hours, 11.5 g of triphenylsulfonium bromide and 10 mL of methanol were further added to the reaction solution, and the resulting mixture was stirred at room temperature for 1 hours. The reaction solution was transferred to a separating funnel containing 300 mL of ethyl acetate, and the organic layer was washed with 50 mL of distilled water five times. Thereafter, the organic layer was concentrated by an evaporator, and the obtained polymer was dissolved in 300 mL of acetone. This solution was added dropwise to 3,000 g of hexene and reprecipitated, and the precipitate was filtered to obtain 18.5 g of Resin (P-7).

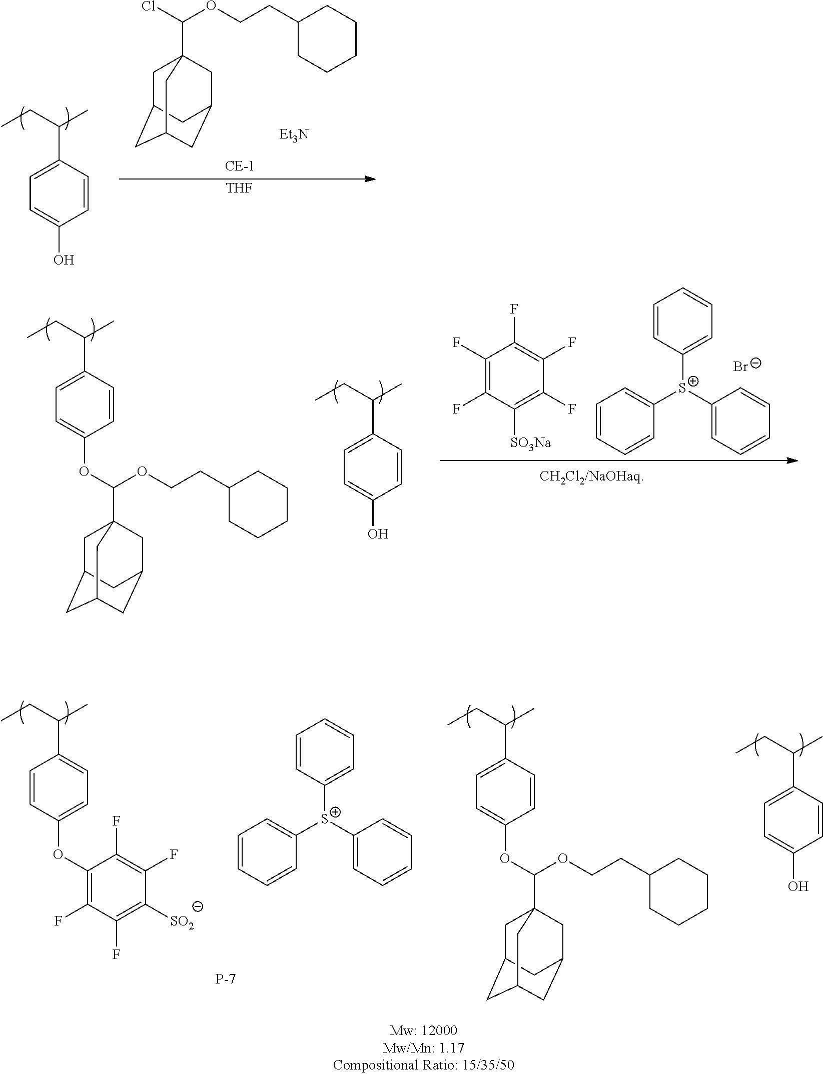

Resins P-2 to P-6, P-8 to P-26, P-31 and P-32 were synthesized in the same manner. The structure, compositional ratio, weight average molecular weight and polydispersity of each of the resins synthesized are shown below. Incidentally, the number of the repeating unit (A) recited in the following structure corresponds to the number in Table 1. The weight average molecular weight and polydispersity of the resin (P) are defined as a polystyrene-reduced value measured by using HLC-8020 GPC (TOSOH Corporation). The measurement was conducted under the measurement conditions that as a sending solvent, N-Methyl-2-pyrrolidone (NMP) 3 L, phosphoric acid 2.93 g and LiBr 2.606 g were used, flow volume was 0.35 mL/min, column was TSK-GEL super AWM-H (TOSOH Corporation) and column temperature was 50° C.

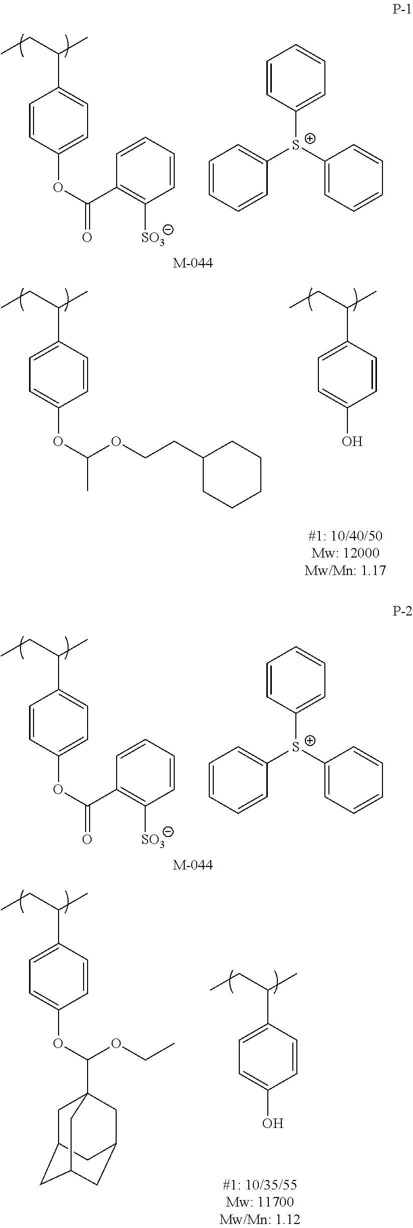

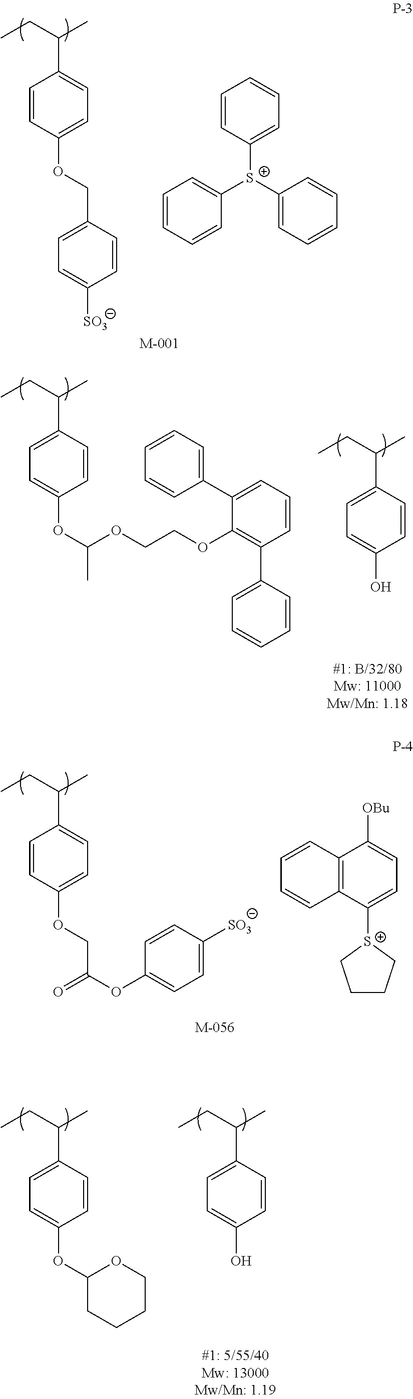

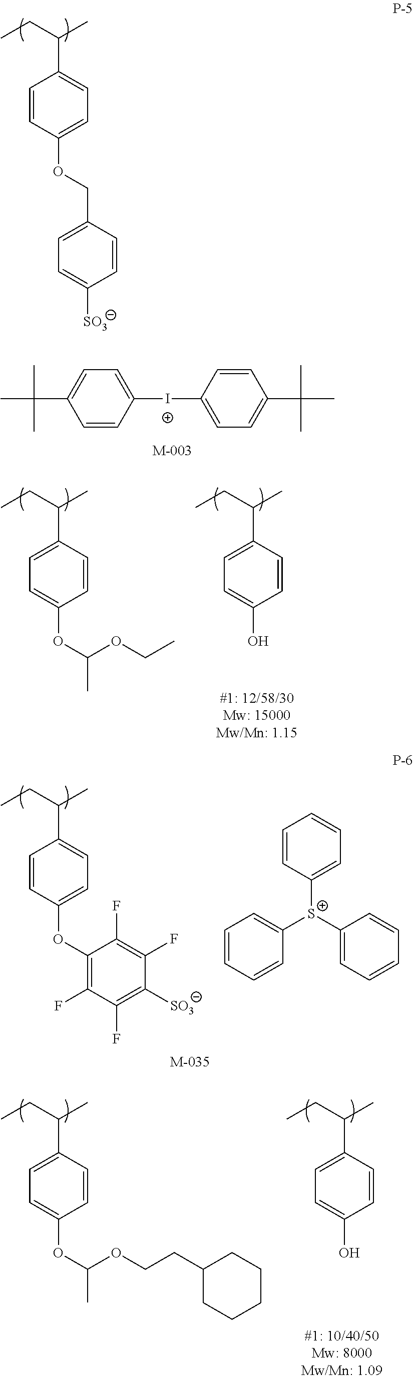

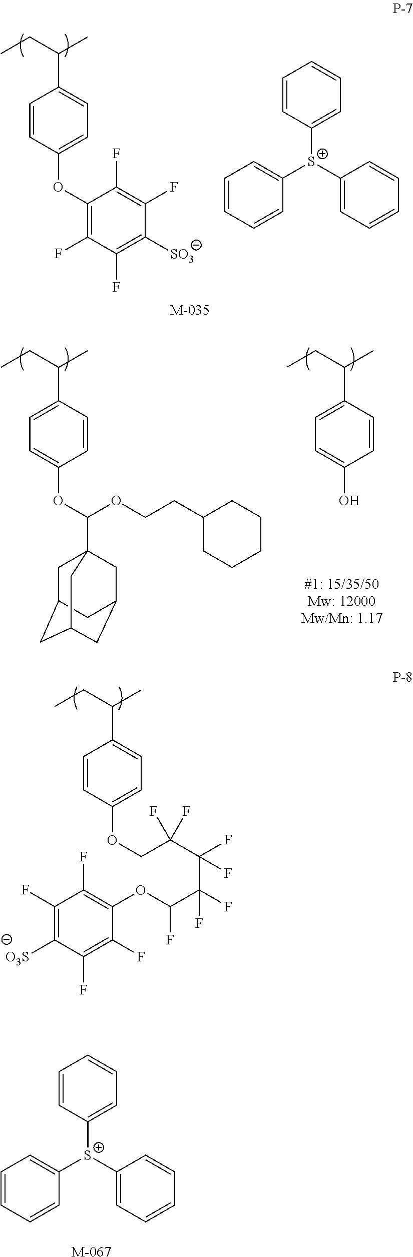

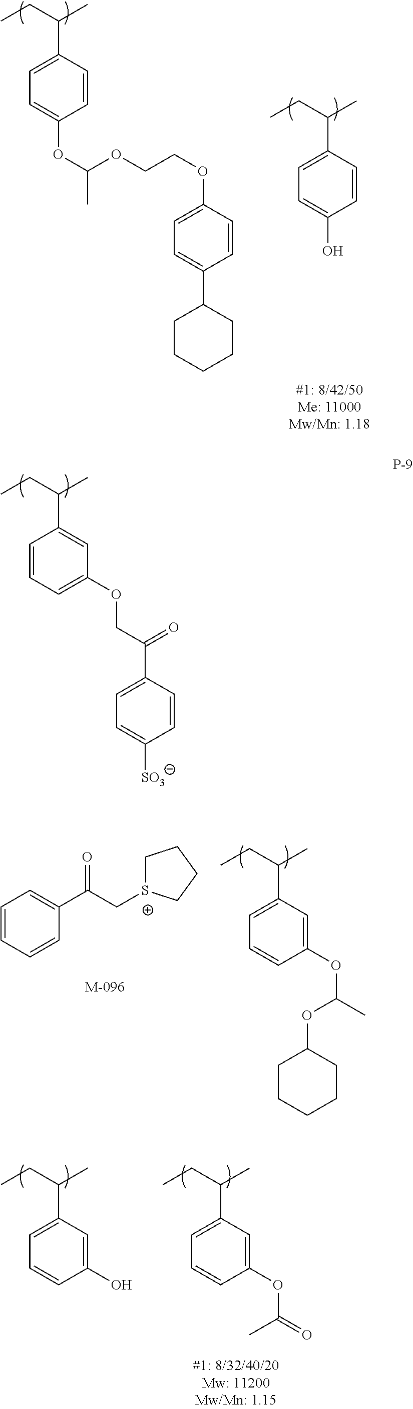

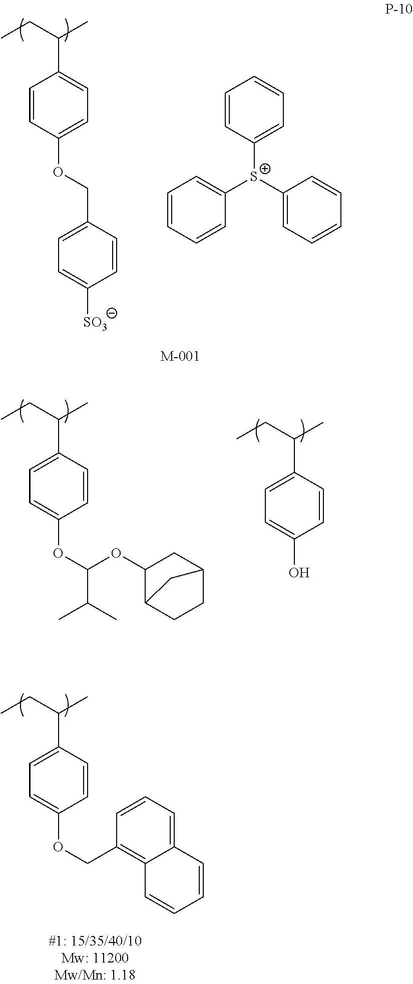

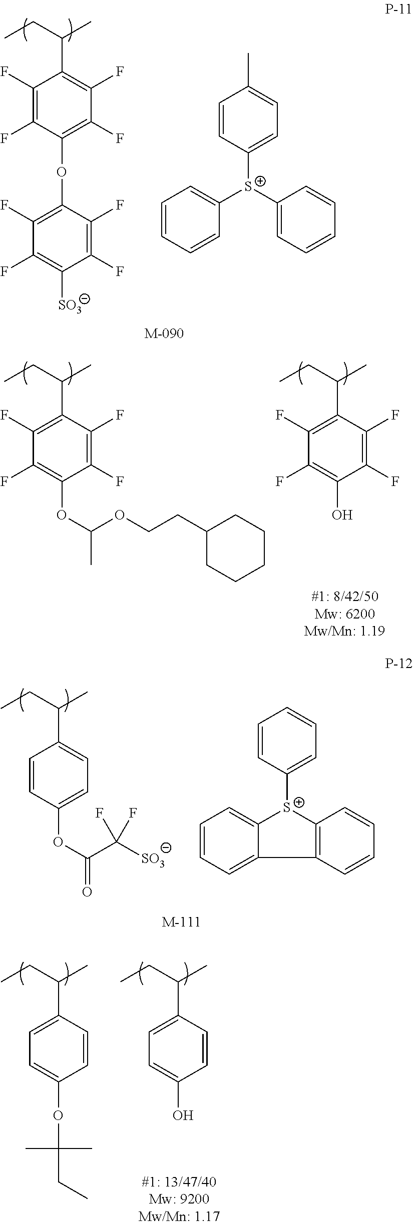

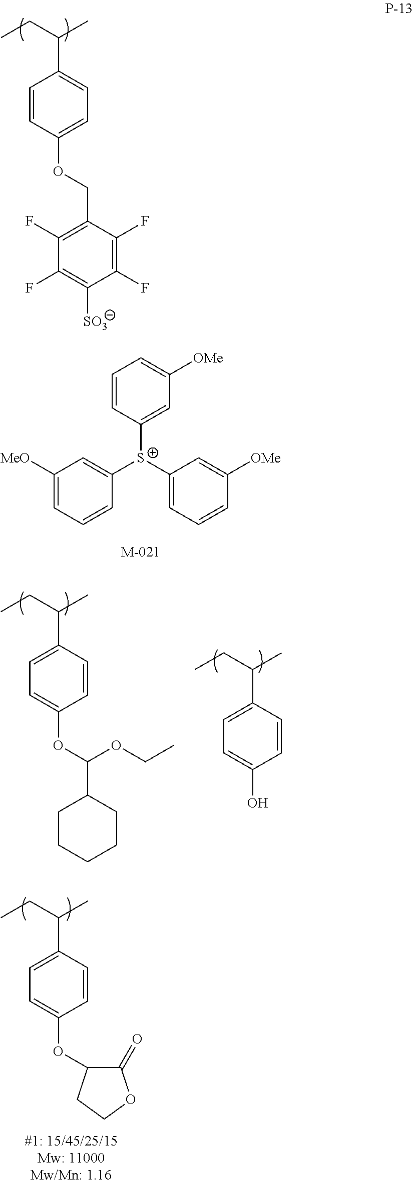

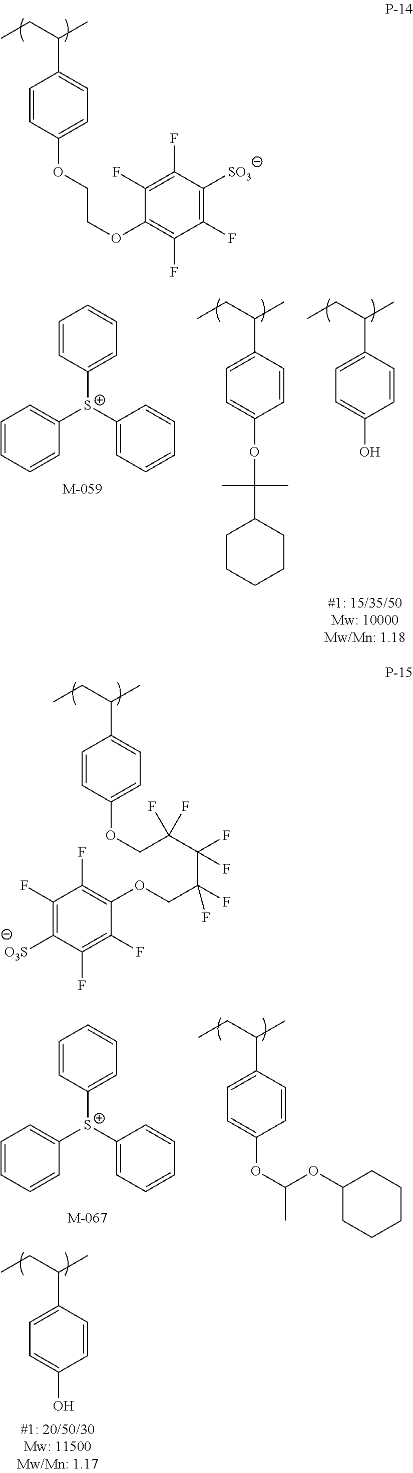

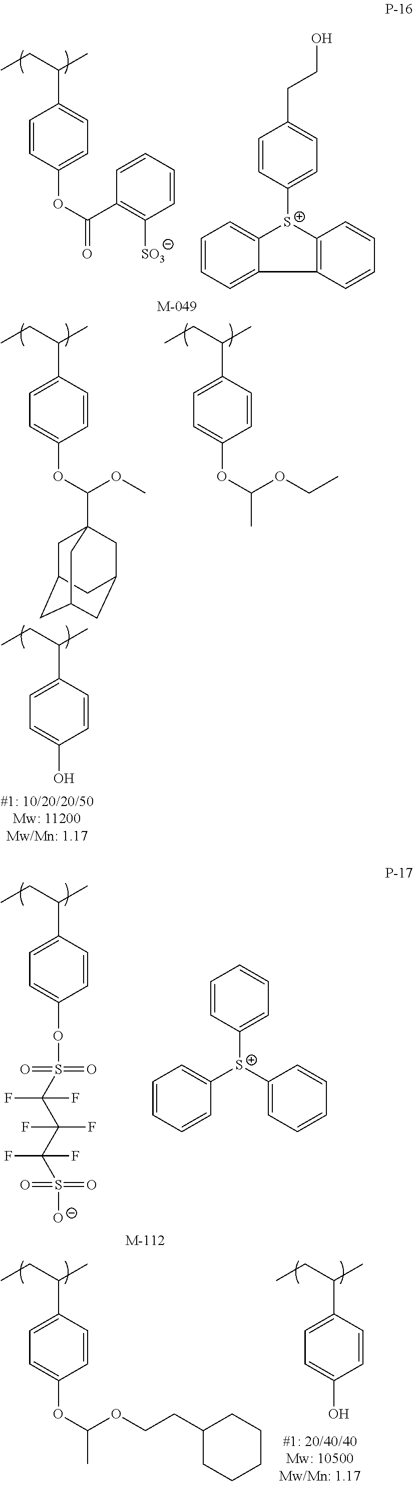

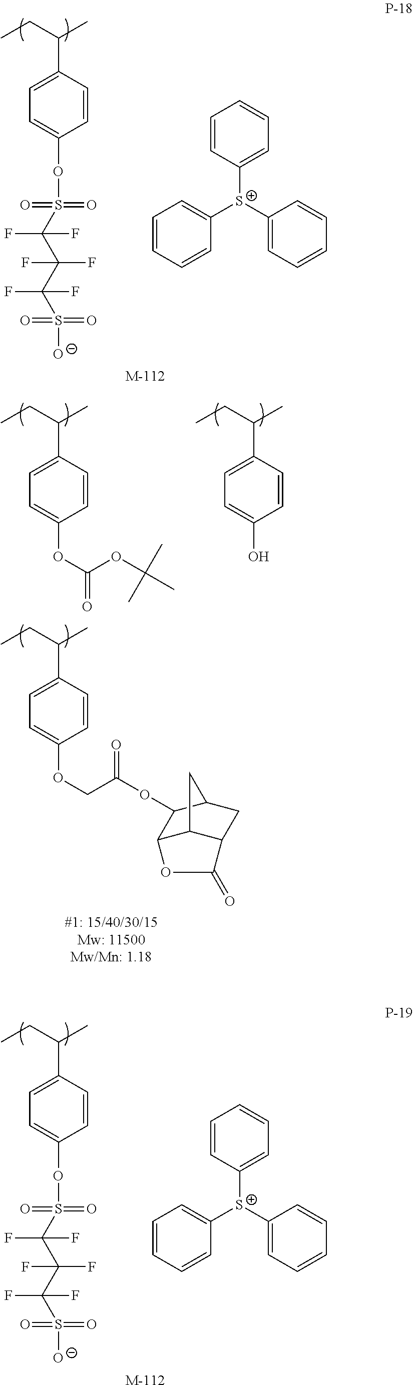

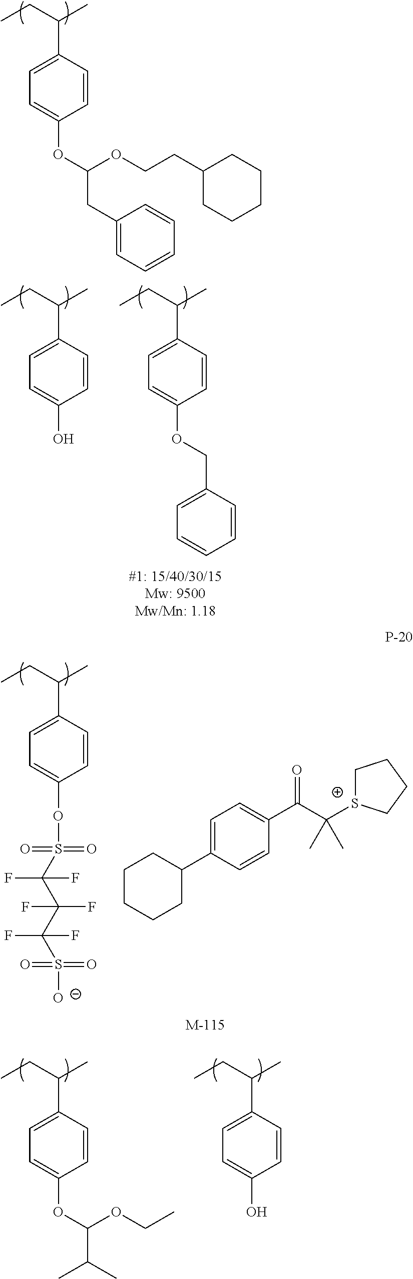

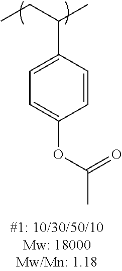

#1 represents compositional ratio.

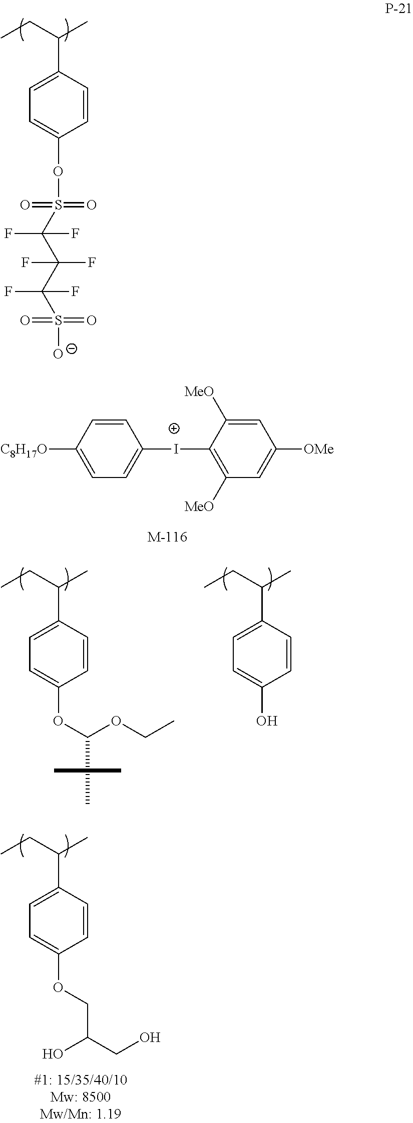

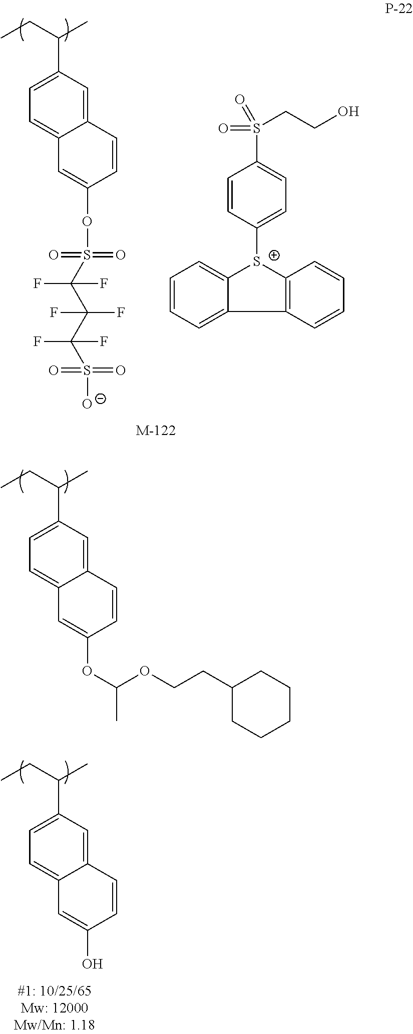

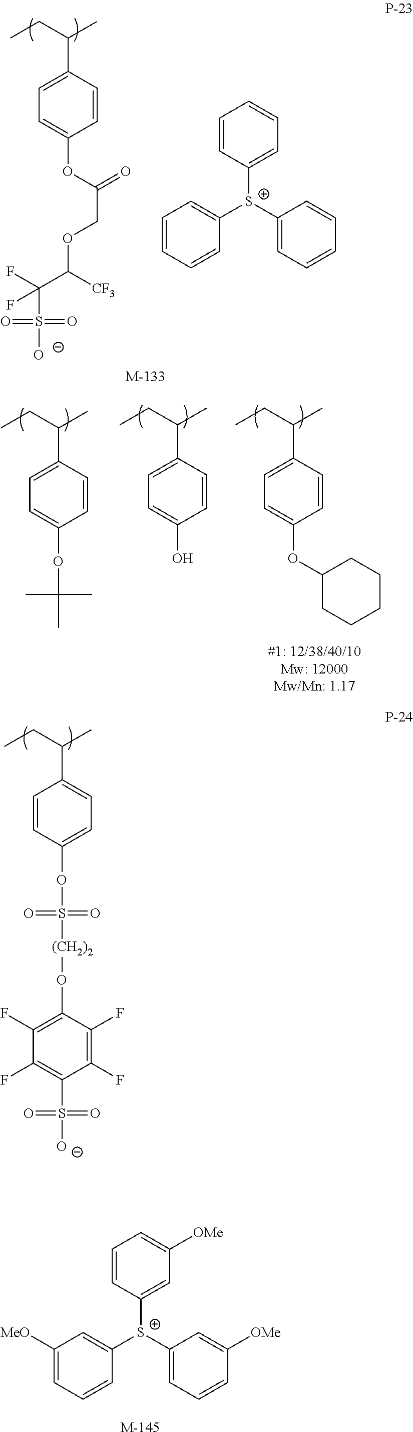

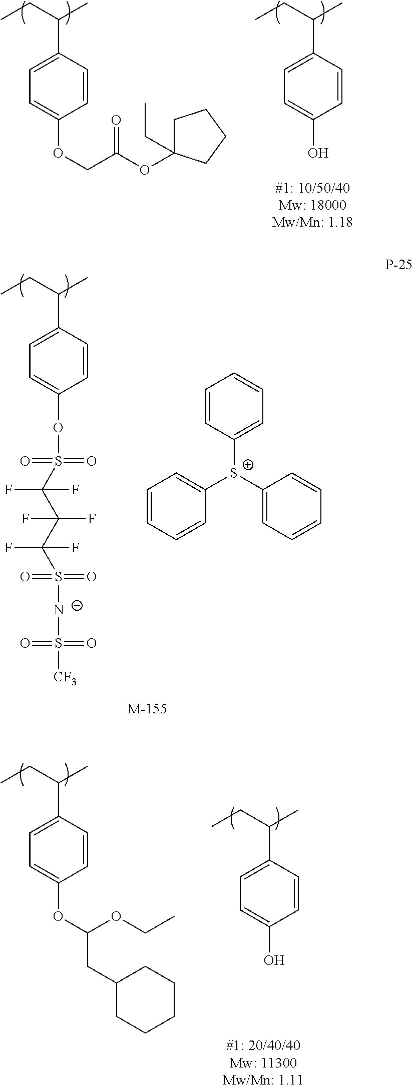

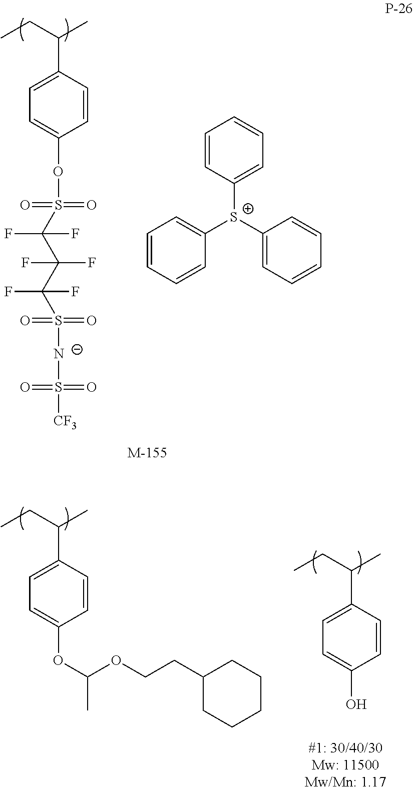

#1 represents compositional ratio.

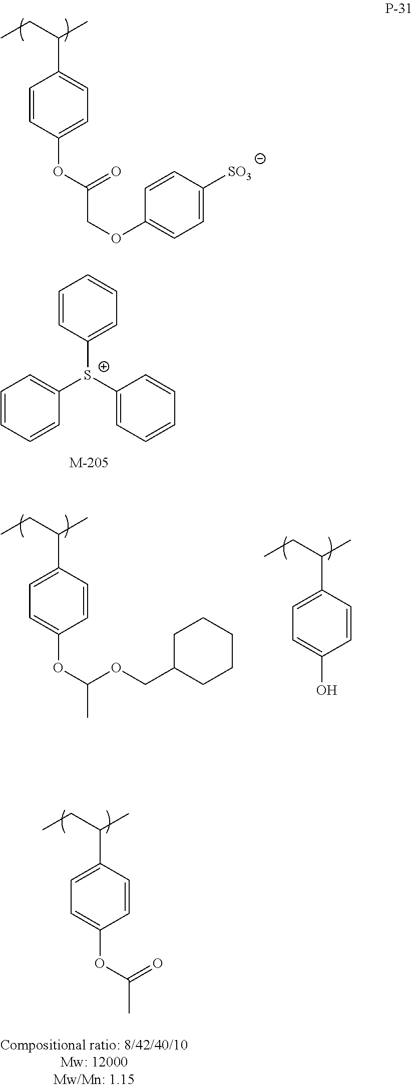

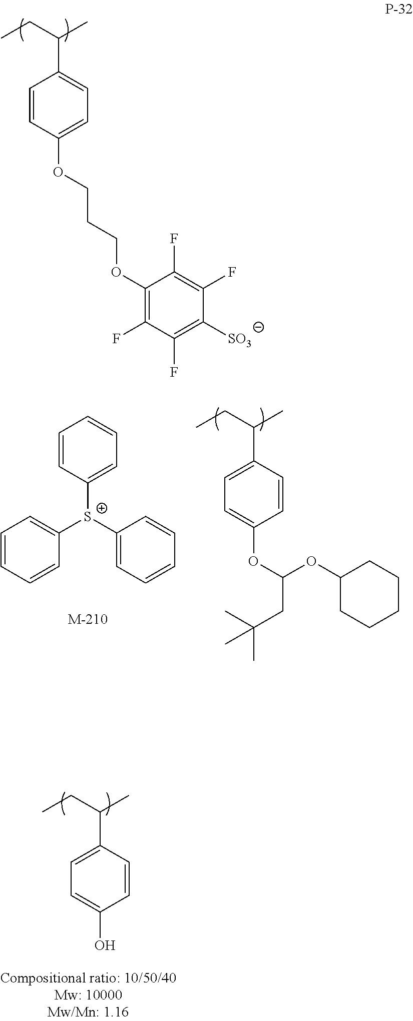

Other resins, photoacid generators, basic compounds, surfactants and solvents used in Examples and Comparative Examples are described below.

### [Resin]

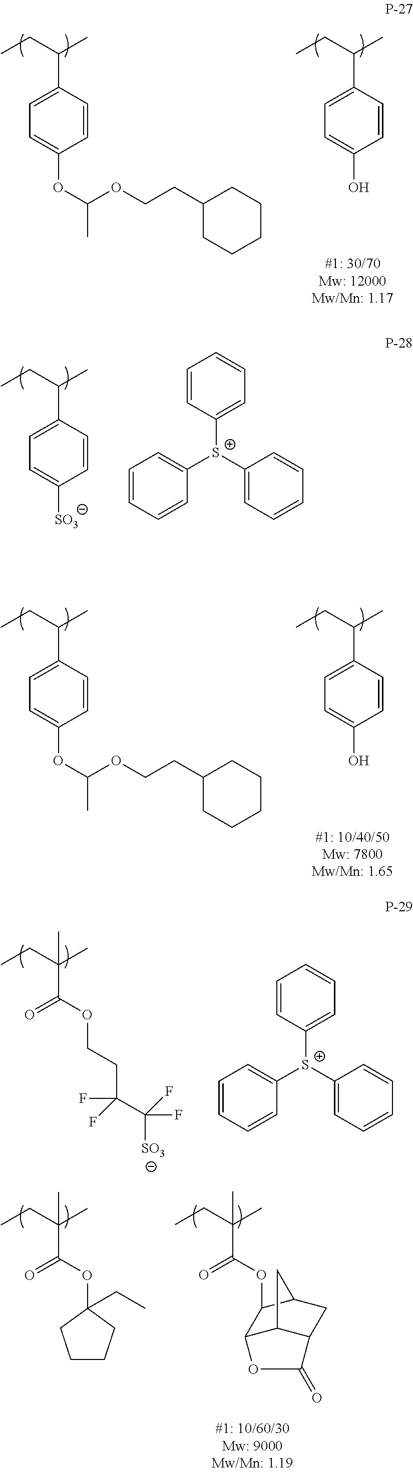

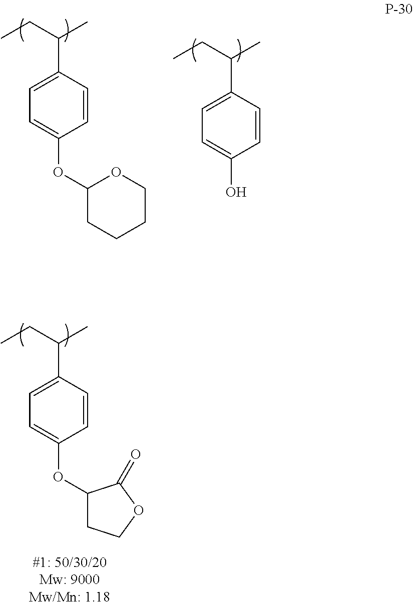

#W-3: represents compositional ratio.

### [Photoacid Generator]

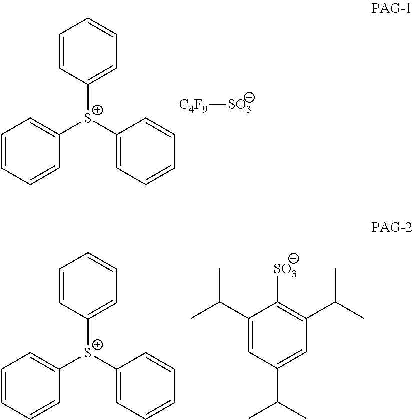

### [Basic Compound]

TBAH: Tetrapbutylammonium hydroxide

### TOA: Tri(n-octyl)amine

### TPI: 2,4,5-Triphenylimidazole

### [Surfactant]

W-1: Megaface F176 (produced by DIC Corp.) (fluorine-containing)
W-2: Megaface R08 (produced by DIC Corp.) (containing fluorine and silicon)
W-3: Polysiloxane Polymer KP-341 (produced by Shin-Etsu Chemical Co., Ltd.) (silicon-containing)
W-4: PF6320 (produced by OMNOVA) (fluorine-containing)

### [Solvent]

S1: propylene glycol monomethyl ether acetate (PGMEA; 1-methoxy-2-acetoxypropane)
S2: Propylene glycol monomethyl ether (PGME; 1-methoxy-2-propanol)

### S3: Cyclohexanone

### S4: γ-Butyrolactone

### <Evaluation of Resist>

The components shown in Tables 2 and 3 below were dissolved in a solvent to prepare a solution having a solid content concentration of 4 mass %, and this solution was filtered through a polytetrafluoroethylene filter having a pore size of 0.10 μm to prepare an actinic ray-sensitive or radiation-sensitive resin composition (resist composition). The actinic ray-sensitive or radiation-sensitive resin composition was evaluated by the following methods, and the results are shown in Tables 2 and 3.

With respect to each of the components in the Tables below, when a plurality of kinds are used, the ratio is the mass ratio.

### Exposure Condition 1: EB (Electron Beam) Exposure

### Examples 1 to 32 and Comparative Examples 1 to 3

The actinic ray-sensitive or radiation-sensitive resin composition prepared was uniformly applied on a hexamethyldisilazane-treated silicon substrate by using a spin coater and dried under heating on a hot plate at 120° C. for 90 seconds to form an actinic ray-sensitive or radiation-sensitive film (resist film) having a thickness of 100 nm. This actinic ray-sensitive or radiation-sensitive film was irradiated with an electron beam by using an electron beam irradiation apparatus (HL750, manufactured by Hitachi, Ltd., accelerating voltage: 50 KeV). Immediately after the irradiation, the resist film was baked on a hot plate at 110° C. over 90 seconds, then developed at 23° C. for 60 seconds by using an aqueous tetramethylammonium hydroxide solution having a concentration of 2.38 mass %, rinsed with pure water for 30 seconds, and spin-dried to obtain a resist pattern.

### Exposure Condition 2: EUV (Extreme-Ultraviolet Ray) Exposure

### Examples 33 to 44 and Comparative Examples 4 to 6

The actinic ray-sensitive or radiation-sensitive resin composition prepared was uniformly coated on a hexamethyldisilazane-treated silicon substrate by using a spin coater and dried under heating on a hot plate at 120° C. for 90 seconds to form an actinic ray-sensitive or radiation-sensitive film (resist film) having a thickness of 100 nm. This actinic ray-sensitive or radiation-sensitive film was irradiated using an EUV exposure apparatus through a reflective mask having a 1:1 line-and-space pattern with a line width of 100 nm. Immediately after the irradiation, the resist film was baked on a hot plate at 110° C. over 90 seconds, then developed at 23° C. for 60 seconds by using an aqueous tetramethylammonium hydroxide solution having a concentration of 2.38 mass %, rinsed with pure water for 30 seconds, and spin-dried to obtain a resist pattern.

### (Evaluation of Sensitivity)

The cross-sectional profile of the obtained pattern was observed using a scanning electron microscope (S-9220, manufactured by Hitachi, Ltd.), and the minimum irradiation energy below which the line-and-space pattern (line:space=1:1) having a line width of 100 nm is not resolved was taken as the sensitivity.

### (Evaluation of Resolution)

The limiting resolution (the minimum line width below which the line and the space were not separated and resolved) at the irradiation dose giving the sensitivity above was taken as the resolution.

### (Evaluation of Pattern Profile)

The cross-sectional profile of the line-and-space pattern (line:space=1:1) with a line width of 100 nm at the irradiation dose giving the sensitivity above was observed using a scanning electron microscope (S-4300, manufactured by Hitachi, Ltd.) and evaluated on a 3-step scale, that is, “rectangular”, “slightly tapered” and “tapered”.

### (Evaluation of Line Edge Roughness (LER))

With respect to arbitrary 30 points in the longitudinal 50 μm region of the line-and-space pattern (line:space=1:1) having a line width of 100 nm at the irradiation dose giving the sensitivity above, the distance from the reference line where the edge should be present was measured using a scanning electron microscope (S-9220, manufactured by Hitachi, Ltd.) and after determining the standard deviation of the distance, 3σ was computed. A smaller value indicates better performance.

### (Evaluation of Scum)

The cross-section of the line-and-space pattern (line:space=1:1) with a line width of 100 nm at the irradiation dose giving the sensitivity above was observed using a scanning electron microscope (S-4300, manufactured by Hitachi, Ltd.), and the presence or absence of scum was evaluated on a 2-step scale of A and B, that is, A when scum was not observed with an eye, and B when scum was observed.

### (Outgas Performance: Percentage Variation in Film Thickness Due to Exposure)

The resist film was irradiated with an electron beam or an extreme-ultraviolet ray at an irradiation dose 2.0 times the irradiation dose giving the sensitivity above, and the film thickness after exposure but before post-baking was measured. The percentage variation based on the film thickness when not exposed was determined according to the following formula. A smaller value indicates better performance.

Percentage variation in film thickness(%)=[(film thickness when not exposed−film thickness after exposure)/film thickness when not exposed]×100

These measurement results are shown in Tables 2 and 3. In Tables 2 and 3, the concentration of each component means “mass %” based on the entire solid content.

TABLE 2
Evaluation Results in EB Exposure

| | | | | | Acid Generator | |
|---|---|---|---|---|---|---|
| | | | | | Used in | |
| | Resin | Concentration | Other Resins | Concentration | Combination | Concentration |
| Example 1 | P-1 | 99.85 | none | | none | |
| Example 2 | P-1 | 99.85 | none | | none | |
| Example 3 | P-2 | 99.85 | none | | none | |
| Example 4 | P-2 | 98.80 | none | | PAG-1 | 1.00 |
| Example 5 | P-3 | 99.85 | none | | none | |
| Example 6 | P-4 | 99.95 | none | | none | |
| Example 7 | P-5 | 99.85 | none | | none | |
| Example 8 | P-6 | 99.85 | none | | none | |
| Example 9 | P-6 | 89.85 | P-30 | 10.00 | none | |
| Example 10 | P-7 | 99.80 | none | | none | |
| Example 11 | P-8 | 99.85 | none | | none | |
| Example 12 | P-9 | 99.85 | none | | none | |
| Example 13 | P-10 | 99.75 | none | | none | |
| Example 14 | P-11 | 99.75 | none | | none | |
| Example 15 | P-12 | 99.85 | none | | none | |
| Example 16 | P-13 | 99.75 | none | | none | |
| Example 17 | P-14 | 99.80 | none | | none | |
| Example 18 | P-15 | 99.75 | none | | none | |
| Example 19 | P-16 | 99.85 | none | | none | |
| Example 20 | P-17 | 99.75 | none | | none | |
| Example 21 | P-1/P-17 (1/1) | 99.75 | none | | none | |
| Example 22 | P-18 | 99.80 | none | | none | |
| Example 23 | P-19 | 99.80 | none | | none | |
| Example 24 | P-20 | 99.85 | none | | none | |
| Example 25 | P-21 | 99.80 | none | | none | |
| Example 26 | P-22 | 99.85 | none | | none | |
| Example 27 | P-23 | 99.85 | none | | none | |
| Example 28 | P-24 | 99.85 | none | | none | |
| Example 29 | P-25 | 99.75 | none | | none | |
| Example 30 | P-26 | 99.65 | none | | none | |
| Example 31 | P-31 | 99.85 | none | | none | |
| Example 32 | P-32 | 99.65 | none | | none | |
| Comparative | P-27 | 89.85 | none | | PAG-2 | 10.00 |
| Example 1 | | | | | | |
| Comparative | P-28 | 99.85 | none | | none | |
| Example 2 | | | | | | |
| Comparative | P-29 | 99.85 | none | | none | |
| Example 3 | | | | | | |

| | Basic Compound | Concentration | Solvent | Mass Ratio | Surfactant | Concentration |
|---|---|---|---|---|---|---|
| Example 1 | TPI | 0.10 | S1/S2 | 40/60 | W-1 | 0.05 |
| Example 2 | TBAH | 0.10 | S1/S2 | 40/60 | W-2 | 0.05 |
| Example 3 | TPI | 0.10 | S1/S2 | 40/60 | W-1 | 0.05 |
| Example 4 | TPI | 0.15 | S1/S2 | 40/60 | W-1 | 0.05 |
| Example 5 | TBAH | 0.10 | S1/S2 | 40/60 | W-2 | 0.05 |
| Example 6 | TPI | 0.05 | S1/S2/S3 | 30/60/10 | None | |
| Example 7 | TPI | 0.10 | S1/S2 | 40/60 | W-1 | 0.05 |
| Example 8 | TPI | 0.10 | S1/S2 | 40/60 | W-1 | 0.05 |
| Example 9 | TBAH | 0.10 | S1/S2 | 40/60 | W-2 | 0.05 |
| Example 10 | TOA | 0.15 | S1/S2 | 40/60 | W-4 | 0.05 |
| Example 11 | TBAH | 0.10 | S1/S2 | 40/60 | W-2 | 0.05 |
| Example 12 | TBAH | 0.10 | S1/S2 | 40/60 | W-1/W-2 (1/1) | 0.05 |
| Example 13 | TBAH | 0.20 | S1/S2 | 40/60 | W-3 | 0.05 |
| Example 14 | TPI | 0.20 | S1/S2 | 40/60 | W-1 | 0.05 |
| Example 15 | TOA | 0.10 | S1/S2 | 40/60 | W-1 | 0.05 |
| Example 16 | TPI | 0.20 | S1/S2/S3 | 30/60/10 | W-2 | 0.05 |
| Example 17 | TPI | 0.15 | S4/S1 | 40/60 | W-3 | 0.05 |
| Example 18 | TBAH | 0.20 | S1/S2 | 40/60 | W-1 | 0.05 |
| Example 19 | TBAH/TPI (1/1) | 0.10 | S1/S2 | 40/60 | W-1 | 0.05 |
| Example 20 | TBAH | 0.20 | S1/S2 | 40/60 | W-1 | 0.05 |
| Example 21 | TPI | 0.20 | S1/S2 | 40/60 | W-1 | 0.05 |
| Example 22 | TBAH | 0.15 | S1/S2/S3 | 30/60/10 | W-3 | 0.05 |
| Example 23 | TPI | 0.15 | S1/S2 | 40/60 | W-2 | 0.05 |
| Example 24 | TOA | 0.10 | S1/S2 | 40/60 | W-1 | 0.05 |
| Example 25 | TBAH | 0.15 | S1/S2 | 40/60 | W-2 | 0.05 |
| Example 26 | TBAH | 0.10 | S1/S2 | 40/60 | W-1 | 0.05 |
| Example 27 | TPI | 0.10 | S1/S2 | 40/60 | W-3 | 0.05 |
| Example 28 | TBAH | 0.10 | S1/S2 | 40/60 | W-1 | 0.05 |
| Example 29 | TBAH | 0.20 | S1/S2 | 40/60 | W-1 | 0.05 |
| Example 30 | TBAH | 0.30 | S1/S2 | 40/60 | W-1 | 0.05 |
| Example 31 | TBAH | 0.10 | S1/S2 | 40/60 | W-1 | 0.05 |
| Example 32 | TBAH | 0.30 | S1/S2 | 40/60 | W-1 | 0.05 |
| Comparative | TBAH | 0.10 | S1/S2 | 40/60 | W-1 | 0.05 |
| Example 1 | | | | | | |
| Comparative | TBAH | 0.10 | S1/S2 | 40/60 | W-1 | 0.05 |
| Example 2 | | | | | | |
| Comparative | TBAH | 0.10 | S1/S2 | 40/60 | W-1 | 0.05 |
| Example 3 | | | | | | |

| | Entire Solid | | | | | | |
|---|---|---|---|---|---|---|---|
| | Content | Sensitivity | Resolution | Pattern | | Outgas | |
| | Concentration | (μC/cm²) | (nm) | Profile | LER (nm) | Performance | Scum |
| Example 1 | 4.0 | 28.5 | 55 | rectangular | 5.5 | 1.5 | A |
| Example 2 | 4.0 | 28.3 | 60 | rectangular | 5.6 | 1.5 | A |
| Example 3 | 4.0 | 28.6 | 70 | rectangular | 5.1 | 3.8 | A |
| Example 4 | 4.0 | 26.5 | 75 | rectangular | 5.3 | 3.2 | A |
| Example 5 | 4.0 | 31.2 | 70 | rectangular | 6.0 | 4.3 | A |
| Example 6 | 4.0 | 32.5 | 70 | rectangular | 5.9 | 4.9 | A |
| Example 7 | 4.0 | 28.1 | 65 | rectangular | 5.5 | 1.6 | A |
| Example 8 | 4.0 | 27.6 | 50 | rectangular | 5.3 | 1.2 | A |
| Example 9 | 4.0 | 27.4 | 55 | rectangular | 5.2 | 1.9 | A |
| Example 10 | 4.0 | 28.3 | 65 | rectangular | 5.1 | 3.4 | A |
| Example 11 | 4.0 | 27.0 | 55 | rectangular | 5.9 | 2.8 | A |
| Example 12 | 4.0 | 33.3 | 70 | rectangular | 6.0 | 1.8 | A |
| Example 13 | 4.0 | 28.9 | 65 | rectangular | 5.3 | 1.4 | A |
| Example 14 | 4.0 | 33.0 | 65 | rectangular | 5.2 | 1.6 | A |
| Example 15 | 4.0 | 31.2 | 70 | rectangular | 5.4 | 1.7 | A |
| Example 16 | 4.0 | 31.3 | 65 | rectangular | 6.2 | 2.3 | A |
| Example 17 | 4.0 | 29.8 | 70 | rectangular | 6.3 | 2.2 | A |
| Example 18 | 4.0 | 27.5 | 70 | rectangular | 5.3 | 1.6 | A |
| Example 19 | 4.0 | 28.6 | 65 | rectangular | 5.8 | 2.3 | A |
| Example 20 | 4.0 | 25.0 | 55 | rectangular | 4.9 | 3.1 | A |
| Example 21 | 4.0 | 25.6 | 50 | rectangular | 5.0 | 3.0 | A |
| Example 22 | 4.0 | 28.9 | 65 | rectangular | 5.1 | 3.6 | A |
| Example 23 | 4.0 | 30.6 | 70 | rectangular | 5.2 | 1.1 | A |
| Example 24 | 4.0 | 29.0 | 75 | rectangular | 5.6 | 1.6 | A |
| Example 25 | 4.0 | 27.9 | 70 | rectangular | 5.2 | 1.9 | A |
| Example 26 | 4.0 | 28.9 | 75 | rectangular | 5.4 | 1.8 | A |
| Example 27 | 4.0 | 30.0 | 65 | rectangular | 5.8 | 5.2 | A |
| Example 28 | 4.0 | 32.3 | 60 | rectangular | 5.8 | 4.9 | A |
| Example 29 | 4.0 | 27.0 | 60 | rectangular | 5.3 | 3.0 | A |
| Example 30 | 4.0 | 27.3 | 65 | rectangular | 5.2 | 4.5 | A |
| Example 31 | 4.0 | 27.8 | 70 | rectangular | 5.2 | 4.5 | A |
| Example 32 | 4.0 | 27.9 | 70 | rectangular | 5.2 | 4.5 | A |
| Comparative | 4.0 | 35.8 | 90 | tapered | 8.0 | 8.5 | A |
| Example 1 | | | | | | | |
| Comparative | 4.0 | 35.5 | 85 | rectangular | 7.0 | 4.5 | B |
| Example 2 | | | | | | | |
| Comparative | 4.0 | 45.8 | 85 | rectangular | 7.1 | 4.5 | A |
| Example 3 | | | | | | | |

The concentration of each component indicates the concentration (mass %) based on the entire solid content concentration.

TABLE 3
Evaluation Results in EUV Exposure

| | | | | | Acid | | | | | |
|---|---|---|---|---|---|---|---|---|---|---|
| | | | | | Generator | | Basic | | | |
| | | Concen- | Other | Concen- | Used in | Concen- | Com- | Concen- | | Mass |
| | Resin | tration | Resins | tration | Combination | tration | pound | tration | Solvent | Ratio |
| Example 33 | P-1 | 99.85 | none | | none | | TPI | 0.10 | S1/S2 | 40/60 |
| Example 34 | P-2 | 99.85 | none | | none | | TPI | 0.10 | S1/S2 | 40/60 |
| Example 35 | P-3 | 99.85 | none | | none | | TBAH | 0.10 | S1/S2 | 40/60 |
| Example 36 | P-6 | 99.85 | none | | none | | TPI | 0.10 | S1/S2 | 40/60 |
| Example 37 | P-6 | 89.85 | P-30 | 10.0 | none | | TBAH | 0.10 | S1/S2 | 40/60 |
| Example 38 | P-12 | 99.85 | none | | none | | TOA | 0.10 | S1/S2 | 40/60 |
| Example 39 | P-15 | 99.75 | none | | none | | TBAH | 0.20 | S1/S2 | 40/60 |
| Example 40 | P-16 | 99.85 | none | | none | | TBAH | 0.10 | S1/S2 | 40/60 |
| Example 41 | P-17 | 99.75 | none | | none | | TBAH | 0.20 | S1/S2 | 40/60 |
| Example 42 | P-17 | 99.75 | none | | none | | TPI | 0.20 | S1/S2 | 40/60 |
| Example 43 | P-25 | 99.75 | none | | none | | TBAH | 0.20 | S1/S2 | 40/60 |
| Example 44 | P-31 | 99.85 | none | | none | | TBAH | 0.10 | S1/S2 | 40/60 |
| Comparative | P-27 | 89.85 | none | | PAG-2 | 10.00 | TBAH | 0.10 | S1/S2 | 40/60 |
| Example 4 | | | | | | | | | | |
| Comparative | P-28 | 99.85 | none | | none | | TBAH | 0.10 | S1/S2 | 40/60 |
| Example 5 | | | | | | | | | | |
| Comparative | P-29 | 99.85 | none | | none | | TBAH | 0.10 | S1/S2 | 40/60 |
| Example 6 | | | | | | | | | | |

| | | | Entire Solid | | | | | | |
|---|---|---|---|---|---|---|---|---|---|
| | | | Content | | Reso- | | | Outgas | |
| | Sur- | Concen- | Concen- | Sensitivity | lution | Pattern | LER | Per- | |
| | factant | tration | tration | (mJ/cm²) | (nm) | Profile | (nm) | formance | Scum |
| Example 33 | W-1 | 0.05 | 4.0 | 25.3 | 55.0 | rectangular | 5.0 | 2.0 | A |
| Example 34 | W-1 | 0.05 | 4.0 | 28.8 | 50.0 | rectangular | 5.5 | 4.5 | A |
| Example 35 | W-2 | 0.05 | 4.0 | 25.5 | 65.0 | rectangular | 6.5 | 5.0 | A |
| Example 36 | W-1 | 0.05 | 4.0 | 23.9 | 50.0 | rectangular | 5.0 | 1.2 | A |
| Example 37 | W-2 | 0.05 | 4.0 | 24.7 | 55.0 | rectangular | 6.5 | 2.2 | A |
| Example 38 | W-1 | 0.05 | 4.0 | 26.3 | 65.0 | rectangular | 7.0 | 2.0 | A |
| Example 39 | W-1 | 0.05 | 4.0 | 27.3 | 65.0 | rectangular | 6.5 | 2.2 | A |
| Example 40 | W-1 | 0.05 | 4.0 | 26.0 | 65.0 | rectangular | 6.5 | 3.5 | A |
| Example 41 | W-1 | 0.05 | 4.0 | 25.0 | 55.0 | rectangular | 5.5 | 3.5 | A |
| Example 42 | W-1 | 0.05 | 4.0 | 25.5 | 55.0 | rectangular | 7.0 | 4.0 | A |
| Example 43 | W-1 | 0.05 | 4.0 | 27.3 | 55.0 | rectangular | 6.0 | 3.2 | A |
| Example 44 | W-1 | 0.05 | 4.0 | 27.8 | 60.0 | rectangular | 6.0 | 3.0 | A |
| Comparative | W-1 | 0.05 | 4.0 | 30.0 | 75.0 | tapered | 8.0 | 9.0 | A |
| Example 4 | | | | | | | | | |
| Comparative | W-1 | 0.05 | 4.0 | 28.0 | 70.0 | rectangular | 7.5 | 5.5 | B |
| Example 5 | | | | | | | | | |
| Comparative | W-1 | 0.05 | 4.0 | 40.0 | 70.5 | rectangular | 7.5 | 6.6 | A |
| Example 6 | | | | | | | | | |

The concentration of each component indicates the concentration (mass %) based on the entire solid content concentration.

As apparent from the results in the Tables above, in the EB exposure, the actinic ray-sensitive or radiation-sensitive resin composition of the present invention satisfies all of high sensitivity, high resolution, good pattern profile, scum reduction, improved line edge roughness and good outgas performance at the same time as compared with Comparative Example 1 using Resin P-27 not containing the repeating unit (A), Comparative Example 2 using Resin P-28 having a polydispersity of more than 1.20, and Comparative Example 3 using Resin P-29 not containing the repeating unit (C).

Furthermore, it is apparent that also in the EUV exposure, the actinic ray-sensitive or radiation-sensitive resin composition of the present invention satisfies all of high sensitivity, high resolution, good pattern profile, scum reduction, improved line edge roughness and good outgas performance at the same time as compared with Comparative Example 4 using Resin P-27 not containing the repeating unit (A), Comparative Example 5 using Resin P-28 having a polydispersity of more than 1.20, and Comparative Example 6 using Resin P-29 not containing the repeating unit (C).

### INDUSTRIAL APPLICABILITY

According to the present invention, an actinic ray-sensitive or radiation-sensitive resin composition not only satisfying, at a high level, all of high sensitivity, high resolution, good pattern profile, scum reduction and improved line edge roughness at the same time but also exhibiting sufficiently high performance in terms of outgas during exposure, can be provided. Also, according to the present invention, a resist film and a pattern forming method each using the composition, a manufacturing method of a semiconductor device, a semiconductor device, and a production method of a resin, can be provided.

This application is based on Japanese patent application No. JP 2011-215625 filed on Sep. 29, 2011, the entire content of which is hereby incorporated by reference, the same as if set forth at length.

1. An actinic ray-sensitive or radiation-sensitive resin composition, comprising:
(P) a resin that contains (A) a repeating unit capable of decomposing upon irradiation with an actinic ray or radiation to generate an acid in a side chain of the resin (P) and (C) a repeating unit represented by the following formula (I), wherein a polydispersity of the resin (P) is 1.20 or less: 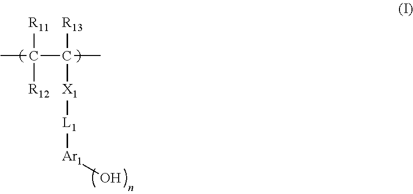
wherein in formula (1), each of R₁₁, R₁₂ and R₁₃ independently represents a hydrogen atom, an alkyl group, a cycloalkyl group, a halogen atom, a cyano group or an alkoxycarbonyl group, R₁₂ may combine with Ar₁ to form a ring, and in this case, R₁₂ represents an alkylene group;
X₁ represents a single bond, —COO— or —CONR₁₄—, and R₁₄ represents a hydrogen atom or an alkyl group;
L₁ represents a single bond or an alkylene group;
Ar₁ represents an (n+1)-valent aromatic ring group, provided that when Ar₁ combines with R₁₂, Ar₁ represents an (n+2)-valent aromatic ring group; and
n represents an integer of 1 or more.

2. The actinic ray-sensitive or radiation-sensitive resin composition according to claim 1,
wherein the repeating unit (C) is represented by the following formula (II): 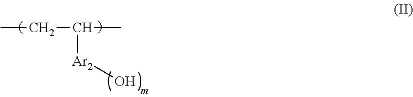
wherein Ar₂ represents an (m+1)-valent aromatic ring group; and
m represents an integer of 1 or more.

3. The actinic ray-sensitive or radiation-sensitive resin composition according to claim 1,
wherein the resin (P) further contains (B) a repeating unit capable of decomposing by an action of an acid to generate an alkali-soluble group.

4. The actinic ray-sensitive or radiation-sensitive resin composition according to claim 3,
wherein the repeating unit (B) is represented by the following formula (III): 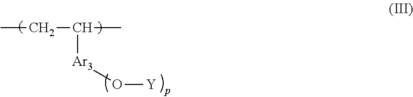
wherein Ar₃ represents a (p+1)-valent aromatic ring group;
Y represents a hydrogen atom or a group capable of leaving by an action of an acid, and when a plurality of Y's are present, each Y may be the same as or different from every other Y, provided that at least one Y represents a group capable of leaving by an action of an acid; and
p represents an integer of 1 or more.

5. The actinic ray-sensitive or radiation-sensitive resin composition according to claim 1,
wherein the repeating unit (A) is represented by the following formula (IV): 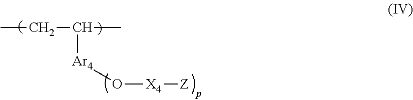
wherein Ar₄ represents a (q+1)-valent aromatic ring group;
X₄ represents a divalent linking group;
Z represents a moiety working out to a sulfonic acid group, an imide acid group or a methide acid group upon irradiation with an actinic ray or radiation; and
q represents an integer of 1 or more.

6. The actinic ray-sensitive or radiation-sensitive resin composition according to claim 5,
wherein in formula (IV), X₄ represents an aromatic ring group, —CO— or a group formed by a combination thereof.

7. The actinic ray-sensitive or radiation-sensitive resin composition according to claim 1,
wherein the resin (P) is synthesized from poly(hydroxystyrene)s.

8. The actinic ray-sensitive or radiation-sensitive resin composition according to claim 1, which is exposed to an electron beam, an X-ray or a soft X-ray.

9. A resist film, which is formed using the actinic ray-sensitive or radiation-sensitive resin composition according to claim 1.

10. A pattern forming method, comprising:
exposing and developing the resist film according to claim 9.

11. The pattern forming method according to claim 10,
wherein the exposing of the resist film is performed using an electron beam, an X-ray or a soft X-ray.

12. A manufacturing method of a semiconductor device, comprising:
the pattern forming method according to claim 10.

13. A semiconductor device, which is manufactured by the manufacturing method of a semiconductor device according to claim 12.

14. A production method of (P) a resin, comprising:
synthesizing (P) a resin that contains (A) a repeating unit capable of decomposing upon irradiation with an actinic ray or radiation to generate an acid in a side chain of the resin (P) and (C) a repeating unit represented by the following formula (I) and has a polydispersity of 1.20 or less, from poly(hydroxystyrene)s: 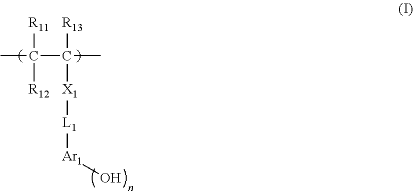
wherein in formula (I), each of R₁₁, R₁₂ and R₁₃ independently represents a hydrogen atom, an alkyl group, a cycloalkyl group, a halogen atom, a cyano group or an alkoxycarbonyl group, R₁₂ may combine with Ar₁ to form a ring, and in this case, R₁₂ represents an alkylene group,
X₁ represents a single bond, —COO— or —CONR₁₄—, and R₁₄ represents a hydrogen atom or an alkyl group;
L₁ represents a single bond or an alkylene group;
Ar₁ represents an (n+1)-valent aromatic ring group, provided that when Ar₁ combines with R₁₂, Ar₁ represents an (n+2)-valent aromatic ring group; and
n represents an integer of 1 or more.
